(19) United States
(12) Patent Application Publication
(10) Pub. No.: US 2026/0362909 A1
(43) Pub. Date: Nov. 12, 2026

(54) DISPLAY APPARATUS

(71) Applicant: SEMICONDUCTOR ENERGY LABORATORY CO., LTD., Atsugi-shi (JP)

(72) Inventors: Satoru IDOJIRI, Tochigi (JP); Kenichi OKAZAKI, Atsugi (JP); Rai SATO, Tochigi (JP); Yasutaka NAKAZAWA, Tochigi (JP); Shingo EGUCHI, Atsugi (JP); Nobuharu OHSAWA, Zama (JP); Daisuke KUBOTA, Atsugi (JP); Sachiko KAWAKAMI, Atsugi (JP); Koji KUSUNOKI, Isehara (JP); Taisuke KAMADA, Niiza (JP)

(21) Appl. No.: 19/668,272

(22) Filed: May 5, 2026

(30) Foreign Application Priority Data
May 9, 2025 (JP) 2025-078996
Aug. 8, 2025 (JP) 2025-133780

(51) Int. Cl. H10K 59/122

(52) U.S. Cl. CPC H10K 59/122

(57) ABSTRACT

A display apparatus that can easily have a high resolution is provided. A display apparatus having high display quality is provided. Each of the display apparatuses includes two light-emitting devices and a partition over an insulating surface. Each of the light-emitting devices includes a pixel electrode, an organic compound layer, and an upper electrode. An insulating layer is provided between the two pixel electrodes, and the partition is provided over the insulating layer. The upper portion of the partition has a larger width than the lower portion of the partition. The same material as the organic compound layer of each light-emitting device is present at part of each of the top surface and the side surface in contact with the top surface of the partition.

### BACKGROUND OF THE INVENTION

### 1. Field of the Invention

One embodiment of the present invention relates to a display apparatus.

Note that one embodiment of the present invention is not limited to the above technical field. Examples of the technical field of one embodiment of the present invention disclosed in this specification and the like include a semiconductor apparatus, a display apparatus, a light-emitting apparatus, a power storage device, a memory device, an electronic appliance, a lighting device, an input device, an input/output device, driving methods thereof, and manufacturing methods thereof. The semiconductor apparatus generally means an apparatus that can function by utilizing semiconductor characteristics.

### 2. Description of the Related Art

In recent years, higher-resolution display panels have been required. Examples of appliances that require high-resolution display panels include a smartphone, a tablet terminal, and a laptop computer. Furthermore, a higher resolution has been required for a stationary display apparatus such as a television apparatus or a monitor apparatus along with an increase in definition. An appliance absolutely required to have a high-pixel-density display panel is an appliance for virtual reality (VR) or augmented reality (AR).

Typical examples of the display apparatus that can be used for a display panel include a liquid crystal display apparatus, a light-emitting apparatus including a light-emitting device (also referred to as a light-emitting element) such as an organic electroluminescent (EL) element or a light-emitting diode (LED), and electronic paper performing display by an electrophoretic method or the like.

The organic EL element generally has a structure in which a layer containing a light-emitting substance is provided between a pair of electrodes. By voltage application to this element, light emission can be obtained from the light-emitting substance. A display apparatus using such an organic EL element does not need a backlight that is necessary for a liquid crystal display apparatus or the like; thus, a thin, lightweight, high-contrast, and low-power-consumption display apparatus can be obtained. Patent Document 1, for example, discloses an example of a display apparatus using an organic EL element.

### Reference

[Patent Document 1] Japanese Published Patent Application No. 2002-324673

### SUMMARY OF THE INVENTION

An object of one embodiment of the present invention is to provide a display apparatus that can easily have a high resolution and a method for manufacturing the display apparatus. An object of one embodiment of the present invention is to provide a display apparatus having both high display quality and high pixel density. An object of one embodiment of the present invention is to provide a high-contrast display apparatus. An object of one embodiment of the present invention is to provide a highly reliable display apparatus.

An object of one embodiment of the present invention is to provide a display apparatus having a novel structure or a method for manufacturing the display apparatus. An object of one embodiment of the present invention is to provide a method for manufacturing the above display apparatus with high yield. An object of one embodiment of the present invention is to at least alleviate at least one of the issues of the conventional art.
(1) One embodiment of the present invention is a display apparatus including a first light-emitting device, a second light-emitting device, and a partition over an insulating surface. The first light-emitting device includes a first pixel electrode in contact with the insulating surface, a first organic compound layer over the first pixel electrode, and a first upper electrode over the first organic compound layer. The second light-emitting device includes a second pixel electrode in contact with the insulating surface, a second organic compound layer over the second pixel electrode, and a second upper electrode over the second organic compound layer. A first insulating layer is between the first pixel electrode and the second pixel electrode and covers an end portion of each of the first pixel electrode and the second pixel electrode. The partition is over the first insulating layer. A width of an upper portion of the partition is larger than a width of a lower portion of the partition in a cross-sectional view. A material of the first organic compound layer and a material of the second organic compound layer are present at side surfaces of the partition.
(2) Another embodiment of the present invention is a display apparatus including a first light-emitting device, a second light-emitting device, and a partition over an insulating surface. The first light-emitting device includes a first pixel electrode in contact with the insulating surface, a first organic compound layer over the first pixel electrode, and a first upper electrode over the first organic compound layer. The second light-emitting device includes a second pixel electrode in contact with the insulating surface, a second organic compound layer over the second pixel electrode, and a second upper electrode over the second organic compound layer. A first insulating layer is between the first pixel electrode and the second pixel electrode and covers an end portion of each of the first pixel electrode and the second pixel electrode. The partition is over the first insulating layer. The partition includes a first conductive layer over and in contact with the first insulating layer, a second insulating layer over and in contact with the first conductive layer, and a third insulating layer over and in contact with the second insulating layer. A width of the third insulating layer is larger than a width of the second insulating layer in a cross-sectional view. A material of the first organic compound layer and a material of the second organic compound layer are present at side surfaces of the partition.
(3) Another embodiment of the present invention is a display apparatus including a first light-emitting device, a second light-emitting device, and a partition over an insulating surface. The first light-emitting device includes a first pixel electrode in contact with the insulating surface, a first organic compound layer over the first pixel electrode, and a first upper electrode over the first organic compound layer. The second light-emitting device includes a second pixel electrode in contact with the insulating surface, a second organic compound layer over the second pixel electrode, and a second upper electrode over the second organic compound layer. A first insulating layer is between the first pixel electrode and the second pixel electrode and covers an end portion of each of the first pixel electrode and the second pixel electrode. The partition is over the first insulating layer. The partition includes a fourth insulating layer over and in contact with the first insulating layer and a second conductive layer over and in contact with the fourth insulating layer. A width of a top surface of the second conductive layer is larger than a width of the fourth insulating layer at an interface between the fourth insulating layer and the second conductive layer in a cross-sectional view. A material of the first organic compound layer and a material of the second organic compound layer are present at side surfaces of the partition.
(4) Another embodiment of the present invention is a display apparatus including a first light-emitting device, a second light-emitting device, and a partition over an insulating surface. The first light-emitting device includes a first pixel electrode in contact with the insulating surface, a first organic compound layer over the first pixel electrode, and a first upper electrode over the first organic compound layer. The second light-emitting device includes a second pixel electrode in contact with the insulating surface, a second organic compound layer over the second pixel electrode, and a second upper electrode over the second organic compound layer. A first insulating layer is between the first pixel electrode and the second pixel electrode and covers an end portion of each of the first pixel electrode and the second pixel electrode. The partition is over the first insulating layer. The partition includes a third conductive layer in contact with the first insulating layer. A width of a bottom surface of the third conductive layer is smaller than a width of a top surface of the third conductive layer in a cross-sectional view. A material of the first organic compound layer and a material of the second organic compound layer are present at side surfaces of the partition.
(5) In any one of (1) to (4), the first upper electrode is preferably electrically connected to the partition.
(6) In any one of (1) to (4), the first upper electrode and the second upper electrode preferably have a light-transmitting property.
(7) In any one of (1) to (4), the first organic compound layer preferably includes a first layer containing a substance having an electron-accepting property over the first pixel electrode and a second layer containing a light-emitting substance over the first layer. The second organic compound layer preferably includes a third layer containing a substance having an electron-accepting property over the second pixel electrode and a fourth layer containing a light-emitting substance over the third layer. The second layer preferably covers an end portion of the first layer. The first upper electrode preferably covers the second layer. The fourth layer preferably covers an end portion of the third layer. The second upper electrode preferably covers the fourth layer.
(8) In (3), the first organic compound layer preferably includes a first layer containing a substance having an electron-accepting property over the first pixel electrode and a second layer containing a light-emitting substance over the first layer. The second organic compound layer preferably includes a third layer containing a substance having an electron-accepting property over the second pixel electrode and a fourth layer containing a light-emitting substance over the third layer. It is preferable that the second layer cover an end portion of the first layer and be in contact with a side surface of the fourth insulating layer. It is preferable that the fourth layer cover an end portion of the third layer and be in contact with a side surface of the fourth insulating layer.
(9) In (7), the first layer and the third layer preferably contain any of an oxide of a metal belonging to Group 4 to Group 8 of the periodic table, a quinodimethane derivative, a chloranil derivative, and a hexaazatriphenylene derivative. The light-emitting substance of the second layer is preferably different from the light-emitting substance of the fourth layer.
(10) In any one of (1) to (4), the partition preferably contains molybdenum.
(11) In (2), the first conductive layer preferably contains molybdenum. The second insulating layer preferably contains silicon and one or more selected from oxygen and nitrogen. The third insulating layer preferably contains silicon and one or more selected from oxygen and nitrogen. A composition of the second insulating layer is preferably different from a composition of the third insulating layer.

According to one embodiment of the present invention, a display apparatus that can easily have a high resolution and a method for manufacturing the display apparatus can be provided. A display apparatus having both high display quality and high pixel density can be provided. A high-contrast display apparatus can be provided. A highly reliable display apparatus can be provided.

According to one embodiment of the present invention, a display apparatus having a novel structure or a method for manufacturing the display apparatus can be provided. A method for manufacturing the above display apparatus with high yield can be provided. According to one embodiment of the present invention, at least one of the issues of the conventional art can be at least alleviated.

Note that the description of these effects does not preclude the existence of other effects. One embodiment of the present invention does not necessarily need to have all of these effects. Other effects can be derived from the description of the specification, the drawings, the claims, and the like.

### BRIEF DESCRIPTION OF THE DRAWINGS

FIGS. 1A - 1C illustrate structure examples of a display apparatus.

FIGS. 2A and 2B illustrate a structure example of the display apparatus.

FIG. 3 illustrates a structure example of the display apparatus.

FIGS. 4A - 4E illustrate structure examples of the display apparatus.

FIGS. 5A and 5B illustrate structure examples of the display apparatus.

FIG. 6 illustrates a structure example of the display apparatus.

FIGS. 7A - 7I illustrate structure examples of the display apparatus.

FIGS. 8A and 8B illustrate a structure example of a display apparatus.

FIGS. 9A and 9B illustrate a structure example of a display apparatus.

FIGS. 10A - 10C illustrate an example of a method for manufacturing the display apparatus.

FIGS. 11A - 11C illustrate the example of the method for manufacturing the display apparatus.

FIGS. 12A - 12C illustrate the example of the method for manufacturing the display apparatus.

FIGS. 13A and 13B illustrate the example of the method for manufacturing the display apparatus.

FIGS. 14A - 14C illustrate the example of the method for manufacturing the display apparatus.

FIGS. 15A - 15E illustrate examples of the method for manufacturing the display apparatus.

FIGS. 16A and 16B illustrate structure examples of manufacturing apparatuses for display apparatuses.

FIG. 17 illustrates a structure example of a manufacturing apparatus for a display apparatus.

FIG. 18 is a perspective view illustrating a structure example of a display apparatus.

FIG. 19 illustrates the structure example of the display apparatus.

FIGS. 20A and 20B illustrate a structure example of a display apparatus.

FIGS. 21A and 21B are perspective views illustrating a structure example of a display apparatus.

FIG. 22 illustrates a structure example of the display apparatus.

FIG. 23 illustrates a structure example of a display apparatus.

FIG. 24 illustrates a structure example of a display apparatus.

FIG. 25 illustrates a structure example of a display apparatus.

FIGS. 26A - 26F illustrate structure examples of light-emitting devices.

FIGS. 27A - 27C illustrate structure examples of light-emitting devices.

FIGS. 28A - 28D illustrate structure examples of electronic appliances.

FIGS. 29A - 29F illustrate structure examples of electronic appliances.

FIGS. 30A - 30G illustrate structure examples of electronic appliances.

FIGS. 31A and 31B illustrate a structure example of an electronic appliance. FIG. 31C illustrates a state where the electronic appliance is in use.

FIGS. 32A - 32C illustrate an example of a method for manufacturing a display apparatus.

FIGS. 33A and 33B illustrate the example of the method for manufacturing the display apparatus.

FIGS. 34A and 34B illustrate the example of the method for manufacturing the display apparatus.

### DETAILED DESCRIPTION OF THE INVENTION

Embodiments will be described below with reference to the drawings. Note that the embodiments can be implemented in many different modes, and it will be readily understood by those skilled in the art that modes and details thereof can be changed in various ways without departing from the spirit and scope thereof. Therefore, the present invention should not be construed as being limited to the description of the embodiments below.

Note that in structures of the invention described below, the same portions or portions having similar functions are denoted by the same reference numeral in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as "first" and "second" in this specification and the like are used in order to avoid confusion among components and do not limit the number of components.

In this specification and the like, the expression "having substantially the same top surface shape" means that the outlines of stacked layers at least partly overlap with each other. For example, the expression includes the case of processing upper and lower layers with use of the same mask pattern or mask patterns that are partly the same. The expression "having substantially the same top surface shape" also sometimes includes the case where the outlines do not completely overlap with each other; for instance, the outline of the upper layer may be positioned inward or outward from the outline of the lower layer.

Note that in this specification and the like, the top surface shape of a component means the outline shape of the component in a plan view. The plan view means that the component is observed from a direction normal to a surface where the component is formed or from a direction normal to a surface of a support (e.g., a substrate) where the component is formed.

Note that the expressions indicating directions such as "over" and "under" are basically used to correspond to the directions in drawings. However, in some cases, the term "over" or "under" in the specification indicates a direction that does not correspond to the apparent direction in the drawings, for the purpose of easy description or the like. For example, in the description of the stacking order (or formation order) of a stack or the like, the case where a surface on which the stack is provided (e.g., a formation surface, a support surface, a bonding surface, or a planar surface) is positioned above the stack in drawings is sometimes expressed such that the formation surface is on the lower side and the stack is on the upper side.

In this specification and the like, the terms "film" and "layer" can be interchanged with each other. For example, in some cases, the term "insulating layer" can be interchanged with the term "insulating film".

Note that in this specification, an organic compound layer (also referred to as an EL layer) means a layer containing at least a light-emitting substance (also referred to as a light-emitting layer) or a stack including the light-emitting layer provided between a pair of electrodes of a light-emitting device.

In this specification and the like, a device formed using a metal mask or a fine metal mask (FMM, a high-resolution metal mask) is sometimes referred to as a device having a metal mask (MM) structure. In this specification and the like, a device formed without using a metal mask or an FMM is sometimes referred to as a device having a metal maskless (MML) structure.

In this specification and the like, the term "island shape" refers to a state where two or more layers formed using the same material in the same step are physically separated from each other. For example, the term "island-shaped metal oxide layer" refers to a state where the metal oxide layer and the adjacent metal oxide layer are physically separated from each other.

In this specification and the like, a structure in which a connector such as a flexible printed circuit (FPC) or a tape carrier package (TCP) is attached to a substrate of a display panel, or a structure in which an IC is mounted on the substrate by a chip on glass (COG) method or the like is referred to as a display panel module or a display module, or simply referred to as a display panel or the like in some cases.

(Embodiment 1)

In this embodiment, structure examples and manufacturing method examples of a display apparatus according to one embodiment of the present invention will be described.

One embodiment of the present invention is a display apparatus including a light-emitting device. The display apparatus includes two or more light-emitting devices that emit light of different colors. The light-emitting devices each include a pair of electrodes and an organic compound layer therebetween. The light-emitting devices are preferably organic electroluminescent devices (organic EL devices). The two or more light-emitting devices that emit light of different colors include respective organic compound layers containing different materials. For example, the display apparatus can perform full-color display when it includes three kinds of light-emitting devices that emit red (R), green (G), and blue (B) light.

The light-emitting devices can each include the organic compound layer between the pair of electrodes. Here, one of the pair of electrodes is a pixel electrode to which a potential can be individually supplied. The other of the pair of electrodes is a common electrode to which a potential common to a plurality of light-emitting devices is supplied. When the potential of the pixel electrode is controlled by a circuit including a transistor or the like, the emission luminance of the light-emitting device can be individually controlled for image display.

In the case where some or all of organic compound layers are separately formed for adjacent light-emitting devices that emit light of different colors, the organic compound layers can be formed by an evaporation method using a high-resolution shadow mask such as a metal mask or a fine metal mask (FMM). In this specification and the like, such a formation method is referred to as a shadow mask method in some cases. A method for separately forming some or all of organic compound layers without using a shadow mask such as a metal mask is referred to as a metal maskless (MML) method in some cases.

The shadow mask method is a method for forming layers by using a shadow mask provided with opening portions and placed near a surface on the evaporation source side of an object where the layers are to be formed. This method enables island-like films with a shape corresponding to the shape of the opening portions to be formed on the surface of the object. Accordingly, a display apparatus having high display quality can be obtained.

Formation of light-emitting devices by the shadow mask method may cause a deviation from the designed shape and position of an island-shaped organic film due to various influences such as a low accuracy of the metal mask, a positional deviation between the metal mask and a substrate, a warp of the metal mask, and an expansion of the outline of the film to be formed due to vapor scattering or the like. In such a case, it is difficult to achieve a high resolution and a high aperture ratio of the display apparatus.

By contrast, formation of light-emitting devices by the MML method enables organic compound layers to be formed in a fine pattern. Accordingly, a display apparatus with a high pixel density and a high aperture ratio can be obtained. Moreover, organic compound layers can be formed separately, enabling the display apparatus to perform extremely clear display with high contrast and high display quality. However, this method, specifically the separate pattern formation of organic compound layers for each emission color, causes the number of steps to increase as the number of emission colors increases. After the pattern formation, it is preferable to cover the organic compound layers with a protective film. However, the limitation of a manufacturing apparatus that can be used for a large-area substrate may make it highly difficult or expensive to form an appropriate protective film over a large-area substrate. In this manner, the MML method may induce a more severe limitation on a manufacturing apparatus than the shadow mask method, depending on the substrate size. Moreover, the increase in the number of steps may cause difficulty in reducing the manufacturing cost.

In view of the above, one embodiment of the present invention provides a display apparatus that has a high pixel density and a high aperture ratio and that can be manufactured using a shadow mask even over a substrate of a size that is too large for the MML method. A component that separates adjacent light-emitting devices (also referred to as a partition in this specification and the like) can be provided. This partition functions as a step over the formation surface of organic compound layers. The partition has a shape such that its upper portion overhangs its lower portion in the lateral direction (such an overhang portion is also referred to as a protruding portion). The organic compound layers are formed separately for the light-emitting devices using, for example, a shadow mask such as an FMM. With the use of the partition whose upper portion overhangs the lower portion in the lateral direction, an organic compound layer can be divided (also referred to as disconnected) between adjacent light-emitting devices. When organic compound layers of adjacent light-emitting devices are separately formed and when the organic compound layers are disconnected by the partition, a leakage current between the adjacent light-emitting devices (sometimes referred to as a lateral leakage current, a horizontal leakage current, a lateral leak current, or a horizontal leak current) can be reduced. Owing to such a structure, a leakage current can be reduced even when a space between adjacent light-emitting devices is narrowed; thus, a display apparatus with high resolution, high contrast, and high display quality can be obtained through a shorter manufacturing process.

In one embodiment of the present invention, the above-described partition includes a first conductive layer over and in contact with a first insulating layer, a second insulating layer over and in contact with the first conductive layer, and a third insulating layer over and in contact with the second insulating layer. The third insulating layer has a larger width than the second insulating layer; thus, the partition has a shape such that its upper portion overhangs its lower portion in the lateral direction (such an overhang portion is also referred to as a protruding portion). An organic compound layer of a first light-emitting device is deposited by evaporation using a shadow mask such as an FMM. The organic compound layer is disconnected by the partition. The organic compound layer is thus formed over a pixel electrode and the first insulating layer, at part of the top surface of the partition, and at the side surface of the protruding portion of the partition.

In this specification and the like, disconnection refers to a phenomenon in which a layer, a film, an electrode, or the like is divided because of the shape of its formation surface (e.g., a step). Specifically, films or the like formed by disconnection may have discontinuous surfaces, reflecting the shape of the formation surface. In addition, end portions of the films or the like formed by disconnection may have a certain shape or a change in size.

In a plan view, it is preferable that the partition provided between the light-emitting devices not overlap with light-emitting regions of the light-emitting devices. When the partition is positioned so as not to block light emitted from the light-emitting devices, a high aperture ratio can be achieved.

The organic compound layer includes a first layer containing a substance having an electron-accepting property over the pixel electrode. The organic compound layer also includes a second layer containing a light-emitting substance over the first layer. The second layer is formed to cover an end portion of the first layer. Such a structure can prevent leakage between the lower layer of the organic compound layer and an upper electrode.

A film that can be shared by the organic compound layers (also referred to as common layer) is not necessarily formed separately using a shadow mask. The common layer can be disconnected by the partition; thus, current leakage between adjacent light-emitting devices through the common layer can be prevented even when the distance between the adjacent light-emitting devices is short.

Next, the upper electrode is formed to cover the organic compound layer and the partition. The upper electrode is formed by a film formation method which provides higher step coverage than a film formation method used for the organic compound layer. This enables part of the upper electrode to cover the end portion of the organic compound layer and to be in contact with part of the partition. In the case where the upper electrode is disconnected by the partition, part of the side surface of the partition is sometimes not covered with the upper electrode.

Note that the partition is partly or entirely formed using a conductive material so that the upper electrode can be electrically connected to the partition. Through this conductive layer of the partition, the upper electrodes of two adjacent light-emitting devices can be electrically connected to each other.

Next, a protective layer is formed to cover the light-emitting devices and the partition. The protective layer preferably includes few defects such as pinholes. For example, the protective layer can be formed by a chemical vapor deposition (CVD) method which provides high step coverage. In the case where the size of the substrate is large, the protective layer is preferably formed by a CVD method. Thus, a film which includes few defects such as pinholes and is suitable for a protective film can be obtained.

It is difficult to set the distance between organic compound layers of different emission colors to be less than 10 μm by a formation method using only a metal mask, for example. By the above method of using both the shadow mask and the partition provided between two adjacent light-emitting devices (the first light-emitting device and a second light-emitting device), the distance can be decreased to be less than or equal to 3 μm, less than or equal to 2 μm, or less than or equal to 1 μm. Accordingly, the area of a non-light-emitting region that may exist between two light-emitting devices can be significantly reduced, and the aperture ratio can be increased.

More specific examples will be described below with reference to drawings.

### Structure example

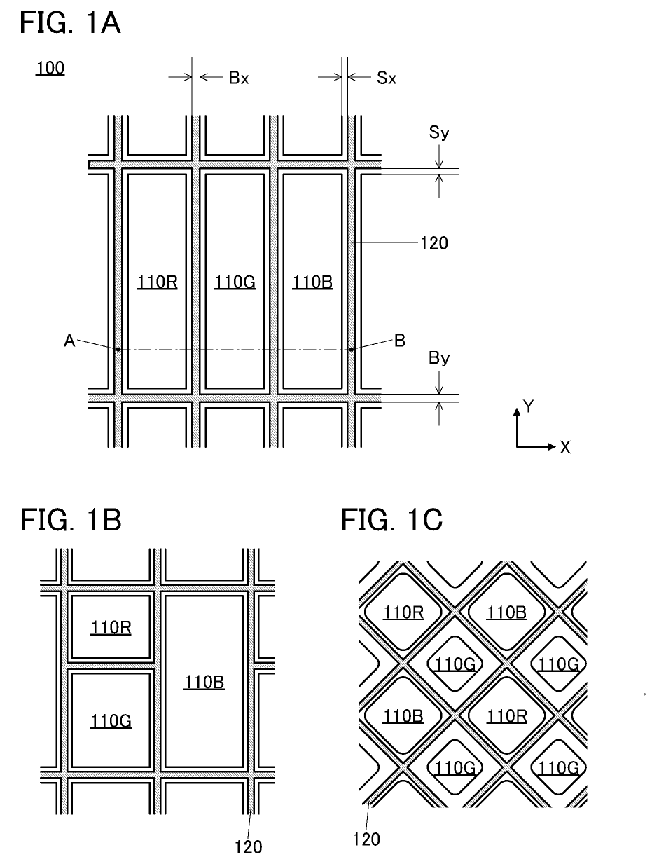

FIG. 1A is a schematic top view of a display apparatus 100. The display apparatus 100 includes a plurality of light-emitting devices 110R that emit red light, a plurality of light-emitting devices 110G that emit green light, and a plurality of light-emitting devices 110B that emit blue light. In FIG. 1A, the X direction and the Y direction that are orthogonal to each other are indicated by arrows.

The light-emitting devices 110R, 110G, and 110B are arranged in matrices. FIG. 1A illustrates what is called a stripe arrangement, in which light-emitting devices that emit light of the same color are arranged in the Y direction. Note that the arrangement of the light-emitting devices is not limited thereto; another arrangement such as an S-stripe, delta, zigzag, or PenTile pattern may also be used. FIG. 1B illustrates an example in which the S-stripe pattern is used. FIG. 1C illustrates an example in which the PenTile pattern is used.

As each of the light-emitting devices 110R, 110G, and 110B, an EL element such as an organic light-emitting diode (OLED) or a quantum-dot light-emitting diode (QLED) is preferably used. Examples of a light-emitting substance contained in the EL element include a substance that emits fluorescent light (a fluorescent material), a substance that emits phosphorescent light (a phosphorescent material), and a substance that exhibits thermally activated delayed fluorescence (a thermally activated delayed fluorescent (TADF) material). Examples of the light-emitting substance contained in the EL element include not only organic compounds but also inorganic compounds (e.g., quantum dot materials).

In this embodiment, a matter common to components distinguished by alphabet letters or numbers added to a reference numeral (e.g., an organic compound layer 112R and an organic compound layer 112G) is sometimes described using the reference numeral excluding the alphabet letters or numbers (e.g., an organic compound layer 112) without any explanation.

A partition 120 is provided between the light-emitting devices 110. The partition 120 has a lattice-like top surface shape. It can be said that the light-emitting devices 110 are provided in regions surrounded by the partition 120.

As illustrated in FIG. 1A, a gap is provided between the partition 120 and the light-emitting device 110 in a plan view. FIG. 1A illustrates a gap Sx in the X direction and a gap Sy in the Y direction between the partition 120 and the light-emitting device 110.

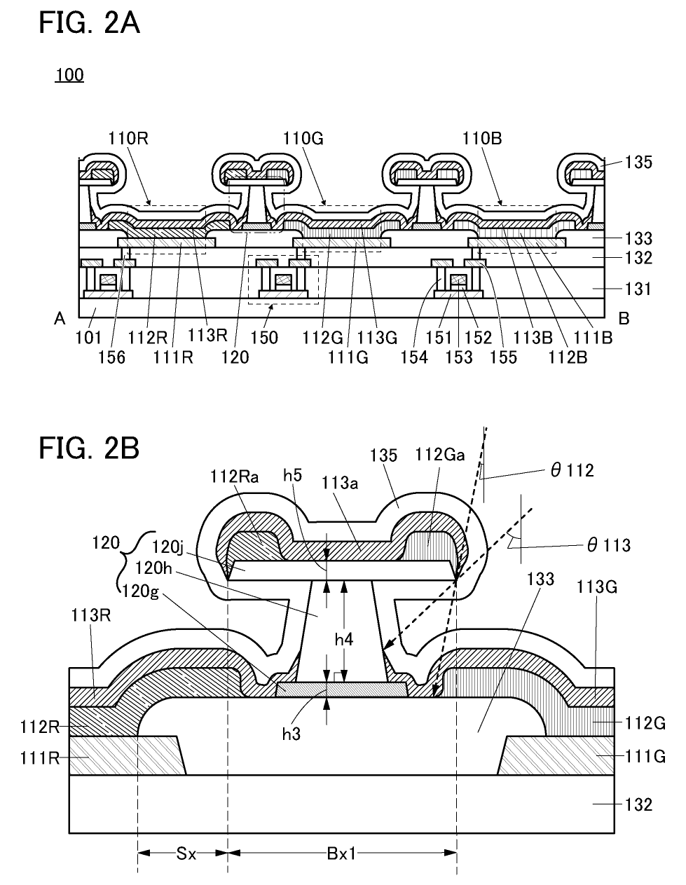

FIG. 2A is a schematic cross-sectional view of the display apparatus 100 along the cutting line A–B in FIG. 1A. The display apparatus 100 includes a plurality of transistors 150, the plurality of light-emitting devices 110R, the plurality of light-emitting devices 110G, and the plurality of light-emitting devices 110B.

The transistors 150 are provided over a substrate 101. The transistors 150 each include a semiconductor layer 151 in which a channel is formed, an insulating layer 152 functioning as a gate insulating layer, a conductive layer 153 functioning as a gate electrode, and a pair of conductive layers 154 functioning as a source electrode and a drain electrode. Conductive layers 155 are provided over an insulating layer 131 covering the semiconductor layer 151, the insulating layer 152, and the conductive layer 153 and are in contact with the conductive layers 154 in opening portions provided in the insulating layer 131.

A metal oxide having semiconductor properties (also referred to as an oxide semiconductor) is preferably used for the semiconductor layer 151. As the oxide semiconductor, an oxide semiconductor typified by indium oxide or In-Ga-Zn oxide (IGZO) can be used. Alternatively, the semiconductor layer of the transistor may contain silicon. Examples of silicon include amorphous silicon and crystalline silicon (e.g., low-temperature polysilicon or single crystal silicon).

Other examples of the metal oxide that can be used for the semiconductor layer 151 include tin oxide, zinc oxide, indium tin oxide, indium titanium oxide, indium gallium oxide, indium tungsten oxide, indium zinc oxide, indium gallium aluminum oxide, indium gallium tin oxide, gallium zinc oxide, aluminum zinc oxide, indium aluminum zinc oxide, indium tin zinc oxide, indium titanium zinc oxide, indium gallium zinc oxide, indium gallium tin zinc oxide, and indium gallium aluminum zinc oxide. Other examples include indium tin oxide containing silicon, gallium tin oxide, and aluminum tin oxide.

Although what is called a top-gate transistor, in which a gate electrode is positioned above a semiconductor layer, is given here as an example of the transistor 150, one embodiment of the present invention is not limited thereto. For example, a bottom-gate transistor, in which a gate electrode is positioned below a semiconductor layer, can also be used.

An insulating layer 132 is provided to cover the conductive layers 155 and the insulating layer 131, and the light-emitting devices 110R, 110G, and 110B are provided over a surface of the insulating layer 132 (also referred to as an insulating surface).

The light-emitting device 110R includes the organic compound layer 112R between a pixel electrode 111R and an upper electrode 113R. The light-emitting device 110G includes the organic compound layer 112G between a pixel electrode 111G and an upper electrode 113G. The light-emitting device 110B includes an organic compound layer 112B between a pixel electrode 111B and an upper electrode 113B.

Each of the pixel electrodes 111 is provided over the insulating layer 132 and is in contact with a conductive layer 156 in an opening portion provided in the insulating layer 132. The conductive layer 155 is in contact with the conductive layer 156 in the opening portion provided in the insulating layer 132. The conductive layer 155 is in contact with the conductive layer 154 functioning as one of the source electrode and the drain electrode. Thus, each of the pixel electrodes 111 is electrically connected to the one of the source electrode and the drain electrode of the transistor 150.

The organic compound layer 112R of the light-emitting device 110R contains at least a light-emitting organic compound that emits red light. The organic compound layer 112G of the light-emitting device 110G contains at least a light-emitting organic compound that emits green light. The organic compound layer 112B of the light-emitting device 110B contains at least a light-emitting organic compound that emits blue light.

The organic compound layers 112R, 112G, and 112B may each include one or more of an electron-injection layer, an electron-transport layer, an electron-blocking layer, a hole-injection layer, a hole-transport layer, and a hole-blocking layer in addition to the layer containing a light-emitting substance (the light-emitting layer). It is also possible to form a light-emitting device having what is called a tandem structure, which includes a plurality of light-emitting layers with a charge-generation layer(s) therebetween.

A conductive film that transmits visible light is used for one of the pixel electrode 111 and the upper electrode 113, and a reflective conductive film is used for the other. When the pixel electrode 111 is a light-transmitting electrode and the upper electrode 113 is a reflective electrode, a bottom-emission display apparatus is obtained. When the pixel electrode 111 is a reflective electrode and the upper electrode 113 is a light-transmitting electrode, a top-emission display apparatus is obtained. Note that when both the pixel electrode 111 and the upper electrode 113 transmit light, a dual-emission display apparatus is obtained.

A protective layer 135 is provided to cover the upper electrodes 113R, 113G, and 113B and the partition 120.

The protective layer 135 can have, for example, a single-layer structure or a stacked-layer structure at least including an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide may be used for the protective layer 135. Aluminum oxide and silicon nitride are particularly preferable because of their high barrier property against water.

As the protective layer 135, a stacked film of an inorganic insulating film and an organic insulating film can be used. For example, a structure in which an organic insulating film is sandwiched between a pair of inorganic insulating films is preferable.

An insulating layer 133 is provided to cover the end portion of the pixel electrode 111. A portion where the insulating layer 133 is not provided over the pixel electrode 111 functions as a light-emitting region of the light-emitting device 110. The end portion of the insulating layer 133 preferably has a tapered shape. Note that the insulating layer 133 is not necessarily provided.

In this specification and the like, the expression "an object has a tapered shape" indicates that the object has a cross-sectional shape in which the angle between a side surface of the object and a contact surface of the object with a formation surface (also referred to as a taper angle) is greater than 0° and less than 90°, and the thickness continuously increases from the end portion. Meanwhile, the expression "an object has an inverse tapered shape" indicates that the angle between a side surface of the object and a contact surface of the object with a formation surface is greater than 90° and less than 180°.

The insulating layer 133 preferably contains an organic resin. Using an organic resin for the insulating layer 133 can increase adhesion between the insulating layer 133 and the organic compound layer 112, so that the manufacturing yield can be improved.

When an organic resin is used for the insulating layer 133, the insulating layer 133 can have a flat surface and a gently curved surface. Thus, coverage with a film formed over the insulating layer 133 can be improved.

Examples of materials that can be used for the insulating layer 133 include an acrylic resin, a polyimide resin, an epoxy resin, a polyamide resin, a polyimide-amide resin, a siloxane resin, a benzocyclobutene-based resin, a phenol resin, and precursors of these resins.

FIG. 2B is an enlarged view of the light-emitting device 110R, the light-emitting device 110G, the partition 120 positioned therebetween, and the vicinity thereof.

The partition 120 is provided over the insulating layer 133. The partition 120 includes a layer 120g, a layer 120h, and a layer 120j. Specifically, the layer 120g, the layer 120h, and the layer 120j are stacked in this order over the insulating layer 133, as illustrated in FIG. 2B. Each of the plurality of layers has an insulating or conductive property. It is preferable that one or more of the plurality of layers included in the partition 120 have a conductive property.

The end portions of the organic compound layers 112R and 112G are positioned over the insulating layer 133. The position of the end portion of each of the organic compound layers 112 can be adjusted by the position of a laterally overhanging portion of the layer 120j of the partition 120, the traveling direction of a film material, or the like. In that case, the end portion of a hole (also referred to as an opening portion) in a shadow mask for forming the organic compound layer 112 is positioned to overlap with the partition 120. Thus, the shadow mask covers light-emitting devices that do not need film formation. The accuracy of alignment of the shadow mask with the substrate allows an error range roughly corresponding to the width of the partition 120, particularly the layer 120j (a width Bx1 in FIG. 2B or a width Bx or By in FIG. 1A). The use of the partition 120 in such a manner can expand the manufacturable area required for separate formation of the organic compound layers 112 in adjacent pixels.

Over the partition 120, an organic compound layer 112Ra and an organic compound layer 112Ga are sometimes provided between the partition 120 and a layer 113a. The organic compound layer 112Ra is a film obtained by disconnection of the same film as the organic compound layer 112R due to the shape of the partition 120. Similarly, the organic compound layer 112Ga is a film obtained by disconnection of the same film as the organic compound layer 112G due to the shape of the partition 120. The organic compound layer 112Ra, the organic compound layer 112Ga, an organic compound layer 112Ba (not illustrated), and the like are also referred to as EL layers. The organic compound layer 112Ra is formed over the partition 120 when the organic compound layer 112R is formed by an evaporation method using a shadow mask. Specifically, the organic compound layer 112Ra is formed by disconnection of the organic compound layer 112R by the partition 120. Similarly, the organic compound layer 112Ga is formed over the partition 120 when the organic compound layer 112G is formed by an evaporation method using a shadow mask. Specifically, the organic compound layer 112Ga is formed by disconnection of the organic compound layer 112G by the partition 120.

Without limitation to the illustrated structure, a region containing materials of the organic compound layers of adjacent light-emitting devices is sometimes provided over the partition 120. This region can be provided over the partition 120 between two light-emitting devices that emit light of different colors (e.g., the light-emitting devices 110R and 110G, the light-emitting devices 110R and 110B, or the light-emitting devices 110G and 110B). In some cases, a similar region is provided over the partition 120 between the three light-emitting devices that emit light of different colors (e.g., the light-emitting devices 110R, 110G, and 110B).

Specifically, in some cases, the same film as the organic compound layer 112R is formed at the side surface of the partition 120 surrounding the light-emitting device 110R; the same film as the organic compound layer 112G is formed at the side surface of the partition 120 surrounding the light-emitting device 110G; and the same film as the organic compound layer 112B is formed at the side surface of the partition 120 surrounding the light-emitting device 110B. In other cases, a region containing materials of two organic compound layers of different emission colors or a region containing materials of three organic compound layers of different emission colors is provided over the partition 120.

In this specification and the like, the organic compound layer of the light-emitting device 110 and the organic compound layer formed at the side surface of the partition 120 being "the same film" means that the layers contain the same substance but do not necessarily have the same thickness.

As illustrated in FIG. 2B, the same film as the organic compound layer of the light-emitting device surrounded by the partition 120 is formed at part of each of the top and side surfaces of the protruding portion of the partition 120. Specifically, in some cases, the same film as the organic compound layer 112R is formed at part of each of the top and side surfaces of the partition 120 surrounding the light-emitting device 110R. In some cases, the same film as the organic compound layer 112G is formed at part of each of the top and side surfaces of the partition 120 surrounding the light-emitting device 110G. In some cases, the same film as the organic compound layer 112B is formed at part of each of the top and side surfaces of the partition 120 surrounding the light-emitting device 110B, although not illustrated in FIG. 2B. In other cases, a region containing materials of the organic compound layers 112 of two or more light-emitting devices 110 that emit light of different colors is provided over the partition 120.

A region over the partition 120 contains two or more selected from the light-emitting substance of the organic compound layer 112R, the light-emitting substance of the organic compound layer 112G, and the light-emitting substance of the organic compound layer 112B. A region at the side surface of the partition 120 surrounding a first light-emitting device contains one selected from the light-emitting substance of the organic compound layer 112R, the light-emitting substance of the organic compound layer 112G, and the light-emitting substance of the organic compound layer 112B.

A region at the side surface of the partition 120 surrounding a second light-emitting device whose emission color is different from that of the first light-emitting device contains one selected from the light-emitting substance of the organic compound layer 112R, the light-emitting substance of the organic compound layer 112G, and the light-emitting substance of the organic compound layer 112B.

A region at the side surface of the partition 120 surrounding a third light-emitting device whose emission color is different from those of the first and second light-emitting devices contains one selected from the light-emitting substance of the organic compound layer 112R, the light-emitting substance of the organic compound layer 112G, and the light-emitting substance of the organic compound layer 112B.

The upper electrode 113R covers the end portion of the organic compound layer 112R and is in contact with part of the top surface of the insulating layer 133 and part of the side surface of the partition 120. Similarly, the upper electrode 113G covers the end portion of the organic compound layer 112G and is in contact with part of the top surface of the insulating layer 133 and part of the side surface of the partition 120. Similarly, the upper electrode 113B covers the end portion of the organic compound layer 112B and is in contact with part of the top surface of the insulating layer 133 and part of the side surface of the partition 120.

When the upper electrode 113 is formed, the layer 113a is provided to cover the organic compound layer 112Ra, the organic compound layer 112Ga, and the like provided over the partition 120. The layer 113a is a conductive film obtained by disconnection of the same conductive film as the upper electrode 113 due to the shape of the partition 120. The layer 113a is also referred to as a conductive layer. In some cases, the upper electrode 113 is not divided into a portion that covers the end portion of the organic compound layer 112 and is in contact with the layer 120g and the layer 113a that is in contact with part of each of the top and side surfaces of the layer 120j. In the case where the upper electrode 113 is formed without disconnection to the layer 113a, it can be said that the upper electrode 113 is provided to cover the light-emitting device 110 and the partition 120.

The protective layer 135 can cover the partition 120. The protective layer 135 may include a portion in contact with the side surface of the partition 120. With such a structure, the upper electrode 113 can be covered with the protective layer 135. This can prevent diffusion of water or the like into the light-emitting device 110 from the outside through the upper electrode 113 and deterioration of the upper electrode 113 itself.

The layer 120g preferably has a conductive property. The layer 120g is preferably in contact with the upper electrodes 113 of two light-emitting devices 110 adjacent to each other with the partition 120 therebetween. When the layer 120g has a conductive property, the upper electrodes of the two adjacent light-emitting devices 110 can be connected to each other through the layer 120g of the partition 120.

A variety of conductive materials can be used for the layer 120g. For example, a metal, an alloy, an oxide conductive material, a nitride conductive material, or the like can be used. Other examples of conductive materials include metal materials such as gold, silver, platinum, magnesium, nickel, tungsten, chromium, molybdenum, iron, cobalt, copper, palladium, titanium, aluminum, yttrium, zirconium, and tantalum and alloy materials containing the metal materials.

The layer 120g preferably contains an oxide conductive material containing indium because its contact resistance with the upper electrode 113 can be reduced. For example, an oxide conductive material typified by indium tin oxide can be used. Alternatively, indium oxide, indium zinc oxide, indium titanium oxide, indium gallium zinc oxide, indium tin zinc oxide, indium titanium zinc oxide, indium gallium tin zinc oxide, or the like can be used. Alternatively, indium tin oxide containing silicon can be used, for example. Alternatively, an oxide conductive material not containing indium, such as zinc oxide, may be used.

An inorganic insulating film is preferably used for each of the layers 120h and 120j. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Two or more of the above insulating films may also be stacked.

The layers 120h and 120j can be formed using insulating films containing the same combination of elements. Furthermore, these layers can be formed using insulating films with different compositions. Accordingly, the wet etching rate can be controlled. Specifically, it is preferable to use insulating films with different compositions so that the etching rate of the layer 120h becomes high and that of the layer 120j becomes low.

The layers 120h and 120j can be formed using insulating films containing silicon, oxygen, and nitrogen. For example, the layer 120h can be formed using a silicon oxynitride film, and the layer 120j can be formed using a silicon nitride oxide film. The compositions of these films can be controlled by adjusting the ratio of oxygen to nitrogen.

Such a stacked-layer structure of an oxide and a nitride can provide high etching selectivity. Specifically, the layers 120h and 120j having different shapes can be formed using an etchant having high selectivity between the oxide and the nitride.

In order to form the partition 120 thick, an organic insulating film is suitable for the layer 120h. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. An organic insulating film can also be used for the layer 120j. Note that an inorganic insulating film is preferably used for the layer 120j. A resist is formed and removed over a film to be the layer 120j; thus, the layer 120j is preferably formed using a material with physical or chemical strength.

As illustrated in FIG. 1A and the like, the partition 120 is provided in a lattice-like shape so as to extend among the light-emitting devices 110; thus, the upper electrodes 113 of all the light-emitting devices 110 are connected to each other through the partition 120 (specifically, the layer 120g). The partition 120 also functions as a wiring for supplying potentials to the upper electrodes 113 of the light-emitting devices 110.

In some cases, the organic compound layer 112Ra between the layer 120j and the layer 113a and the organic compound layer 112Ga between the layer 120j and the layer 113a are provided at the top and side surfaces of the layer 120j.

It is preferable that the upper electrode 113 of the light-emitting device 110 be in contact with the layer 120g and the organic compound layer 112 thereof not be in contact with the layer 120g. Such a structure can prevent leakage between the upper electrode 113 and the lower layer side of the organic compound layer 112 due to contact of the organic compound layer 112 with the layer 120g.

The partition 120 preferably has a shape such that the layer 120j overhangs the end portion of the layer 120h. It can be expressed that the side surface of the layer 120j is positioned outward from the side surface of the layer 120h. Such a structure enables disconnection of an organic compound layer.

The layer 120j includes a portion positioned above the organic compound layer 112 and the upper electrode 113.

The layer 120j can function as a mask when the organic compound layer 112 is formed. In the case where the film material of the organic compound layer 112 travels perpendicularly or substantially perpendicularly to the substrate, the film material is less likely to reach a region inward from the end portion of the layer 120j. Thus, the formation region of the organic compound layer 112 can be controlled.

In the case where the film material of the organic compound layer 112 travels in a direction at an angle 112 with the perpendicular direction as illustrated in FIG. 2B, the organic compound layer 112 is formed also in the region inward from the end portion of the layer 120j.

It is preferable that the end portion of the organic compound layer 112 be positioned outward from the end portion of the layer 120g and not be in contact with the layer 120g. The upper electrode 113 is preferably in contact with the layer 120g. When the material of the upper electrode 113 travels in a direction at an angle 113 with the perpendicular direction and the angle 113 is larger than the angle 112 as illustrated in FIG. 2B, the upper electrode 113 can be in contact with the layer 120g and the organic compound layer 112 can be prevented from being in contact with the layer 120g.

The layers 120h and 120j can each have an insulating property. The sum of a thickness h3 of the layer 120g and a thickness h4 of the layer 120h (h3 + h4) preferably exceeds the thickness of the organic compound layer 112.

The side surface of the layer 120g is preferably positioned outward from the side surface of the layer 120h. In other words, the width of the top surface of the layer 120g is preferably larger than the width of the interface between the layers 120g and 120h in a cross-sectional view. The upper electrode 113 is preferably provided in contact with at least the layer 120g. The upper electrode 113 is sometimes also in contact with the side surface of the layer 120h. Such a structure can improve the adhesion between the upper electrode 113 and the partition 120.

The organic compound layer 112 can include functional layers such as a light-emitting layer, an electron-injection layer, an electron-transport layer, an electron-blocking layer, a hole-injection layer, a hole-transport layer, a hole-blocking layer, and a charge-generation layer. In the case where the side surface of the organic compound layer 112 is in contact with the upper electrode 113, leakage may occur from the pixel electrode to the upper electrode 113 through the side surface of a lower functional layer (e.g., the hole-injection layer) of the organic compound layer 112, not through an upper functional layer of the organic compound layer 112.

A functional layer such as the hole-injection layer or the charge-generation layer has a high conductive property and thus leads to an increase in leakage current in some cases.

In the case where the organic compound layer includes a hole-injection layer, a hole-transport layer, a light-emitting layer, an electron-transport layer, and an electron-injection layer which are stacked in this order over the pixel electrode 111, contact of the side surface of the hole-injection layer with the upper electrode 113 may cause formation of a leakage path from the pixel electrode 111 through the hole-injection layer. This leakage path does not pass through the functional layers above the hole-injection layer, which might hinder the operation of the light-emitting device 110.

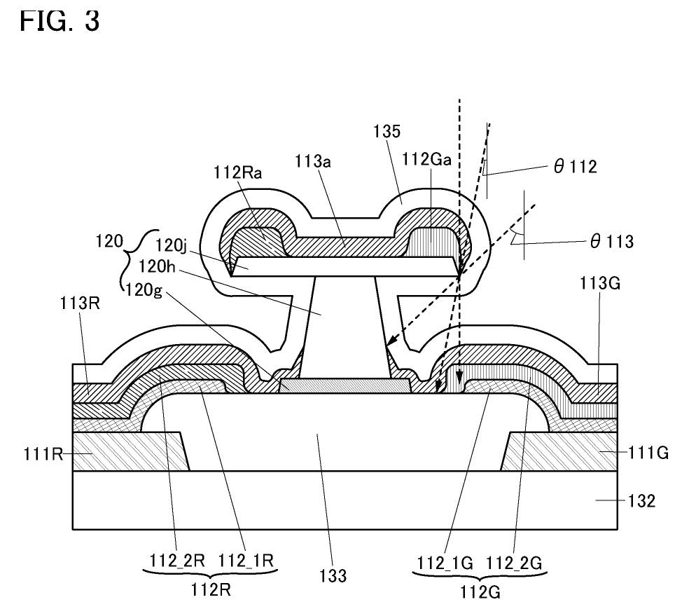

In view of the above, it is preferable that the organic compound layer 112 have a stacked-layer structure and an upper layer cover the end portion of a lower layer. In FIG. 3, the organic compound layer 112R of the light-emitting device 110R includes a layer 112_1R as a lower layer and a layer 112_2R as an upper layer. The organic compound layer 112G of the light-emitting device 110G includes a layer 112_1G as a lower layer and a layer 112_2G as an upper layer. Although not illustrated, the organic compound layer 112B of the light-emitting device 110B similarly includes a layer 112_1B as a lower layer and a layer 112_2B as an upper layer.

In forming the layer 112_2R, the traveling direction of the film material is preferably adjusted to control the film material so as to reach a region closer to the partition 120 than the end portion of the layer 112_1R is. As an example, FIG. 3 illustrates that the film material of the layer 112_1R travels in the direction perpendicular to the substrate and the film material of the layer 112_2R travels in the direction at the angle 112 with the direction perpendicular to the substrate. In that case, the layer 112_2R can be formed such that its end portion is closer to the partition 120 than the end portion of the layer 112_1R is. Thus, the layer 112_2R can cover the side surface of the layer 112_1R.

Similarly, the layer 112_2G can cover the side surface of the layer 112_1G. Similarly, the layer 112_2B can cover the side surface of the layer 112_1B.

The organic compound layer 112R can have a structure in which the lower layer (the layer 112_1R) includes the hole-injection layer and the upper layer (the layer 112_2R) includes the hole-transport layer, the light-emitting layer, the electron-transport layer, and the electron-injection layer, for example. Similarly, the organic compound layer 112G can have a structure in which the lower layer (the layer 112_1G) includes the hole-injection layer and the upper layer (the layer 112_2G) includes the hole-transport layer, the light-emitting layer, the electron-transport layer, and the electron-injection layer. Similarly, the organic compound layer 112B can have a structure in which the lower layer (the layer 112_1B) includes the hole-injection layer and the upper layer (the layer 112_2B) includes the hole-transport layer, the light-emitting layer, the electron-transport layer, and the electron-injection layer.

When the organic compound layer has a stacked-layer structure of a first unit including a first light-emitting layer, a second unit including a second light-emitting layer, and a charge-generation layer between the first unit and the second unit, contact of the side surface of the charge-generation layer with the upper electrode 113 may cause leakage, which might hinder the operation of the light-emitting device 110. In such a case, the organic compound layer can have a structure in which the charge-generation layer is positioned inward from the other layers and the side surface of the charge-generation layer is covered with the upper functional layers.

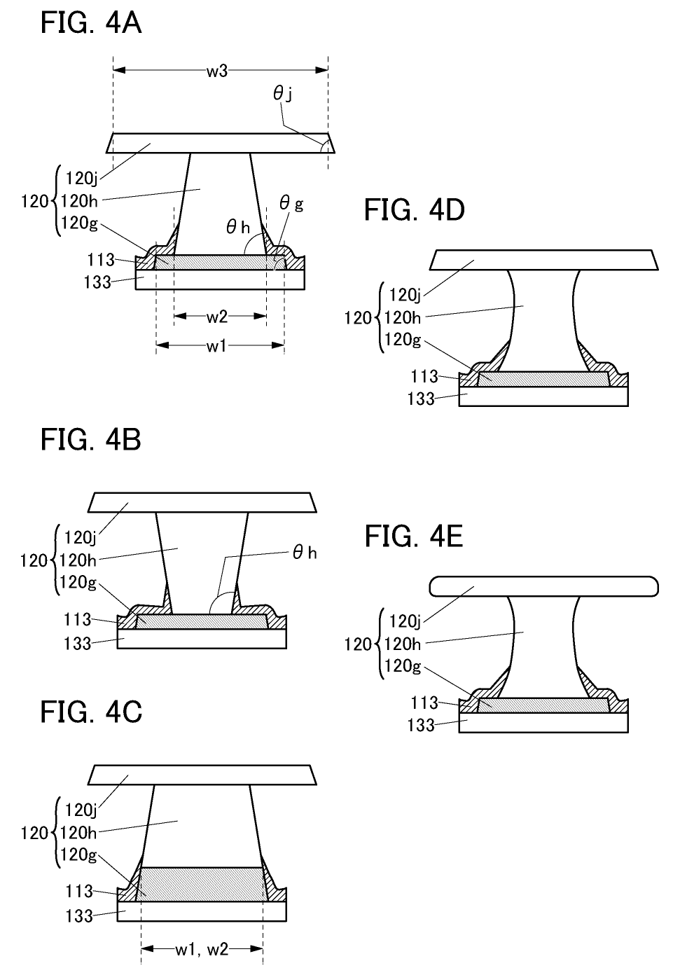

FIGS. 4A - 4E illustrate various structure examples of the partition 120 including the layer 120g, the layer 120h, and the layer 120j.

FIG. 4A selectively illustrates the partition 120, the upper electrode 113, and the insulating layer 133 in FIG. 2B.

In a cross section illustrated in FIG. 4A, a width w1 of the layer 120g exceeds a width w2 of the layer 120h, and a width w3 of the layer 120j exceeds the width w1 of the layer 120g. In other words, the width of the upper portion (the layer 120j) of the partition 120 is larger than the width of the lower portion (the layer 120g and the layer 120h) of the partition 120.

In one embodiment of the present invention, the taper angles of the side surfaces of the layers 120g, 120h, and 120j are referred to as taper angles g, h, and j, respectively.

The taper angles g, h, and j can be, for example, angles between the bottom and side surfaces of the layers 120g, 120h, and 120j, respectively. Alternatively, the taper angles g, h, and j can be angles between the side surfaces of these layers and a reference surface. Here, the reference surface can be the top surface of the insulating layer 133, the top surface of the substrate, or the like, for example.

FIG. 4A illustrates an example in which the taper angles g, h, and j are each less than 90°. The taper angles may each be greater than 90°. FIG. 4B illustrates an example in which the taper angle h is greater than 90°.

In the case where the side surface of the layer 120h is substantially aligned with the side surface of the layer 120g, or in the case where the side surface of the layer 120h is positioned outward from the side surface of the layer 120g, the top surface of the layer 120g is covered with the layer 120h, and it is thus difficult for the upper electrode 113 to be in contact with the top surface of the layer 120g. For example, in the case where the width w1 of the layer 120g is substantially equal to or greater than the width w2 of the layer 120h, the top surface of the layer 120g is covered with the layer 120h as illustrated in FIG. 4C. In that case, the upper electrode 113 can be in contact with only the side surface of the layer 120g. The thickness of the layer 120g can be increased to enlarge the area of the side surface and the contact area between the upper electrode 113 and the layer 120g.

FIGS. 4D and 4E illustrate modification examples of FIG. 4A.

The shape of the side surface of the partition 120, for example, may vary depending on the method and conditions of etching for forming the partition 120. FIG. 4D illustrates an example in which the width of the side surface of the layer 120h is smaller than the width of each of its top and bottom surfaces and the side surface is curved inward. In this specification and the like, a side surface curved inward may be referred to as a side surface having a concave portion. Such a side surface having a concave portion is sometimes formed when isotropic etching conditions are employed, for example.

FIG. 4E illustrates an example in which the side surface of the layer 120j is rounded. The side surface of the layer 120j tends to have rounded corners, particularly when the partition 120 is formed by an isotropic etching method such as wet etching.

The partition 120 (specifically, the layer 120h or the layer 120j) or part of the partition 120 can function as a light-blocking layer when formed using a material with low reflectance and low light transmittance or when blackened by surface treatment. The partition 120 provided between adjacent light-emitting devices 110 can improve display quality when it has a function of preventing color mixture of light between the light-emitting devices 110.

With the above-described structure, organic compound layers can be formed separately for adjacent light-emitting devices. Thus, generation of leakage current through an organic compound layer can be practically eliminated, unlike in the case where organic compound layers are in contact with each other or a common organic compound layer is used. This structure can prevent unintended light emission, so that a display apparatus with high contrast and high display quality can be obtained.

Furthermore, since the organic compound layer 112 in this structure is covered with the upper electrode 113 and the protective layer 135 in a region surrounded by the partition 120, diffusion of impurities such as moisture into the organic compound layer 112 can be prevented, so that a highly reliable display apparatus can be obtained. Moreover, this structure enables the organic compound layers 112 to be separately formed using metal masks and the partition without a photolithography method. Thus, a simple process and a large area of the display apparatus can be achieved easily as compared with the case of not using metal masks.

The above is the description of the structure examples.

[Modification example 1]

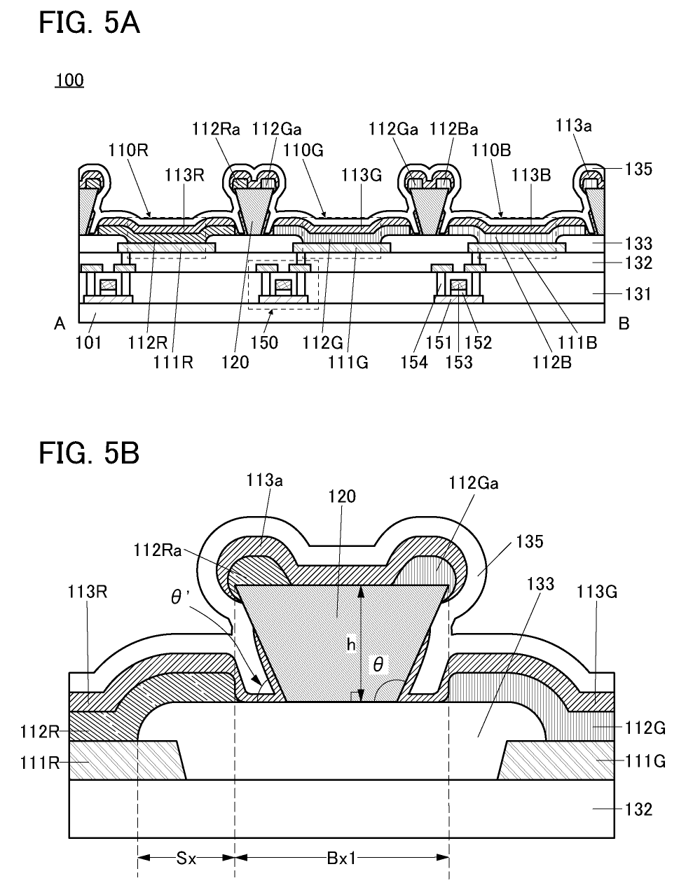

Although FIG. 2A and the like illustrate the examples in which the partition 120 has a structure in which the layers 120g, 120h, and 120j are stacked in this order and the layer 120j overhangs in the lateral direction, the partition 120 may have a conductive property and an inverse tapered shape. FIG. 5A illustrates such an example of the partition 120 having a conductive property and an inverse tapered shape. In FIG. 5A, the partition 120 is provided in contact with the top surface of the insulating layer 133. The end portion of the organic compound layer 112 is positioned over the insulating layer 133. The upper electrode 113 covers the end portion of the organic compound layer 112 and is in contact with part of the top surface of the insulating layer 133 and part of the side surface of the partition 120. FIG. 5B illustrates an example in which the organic compound layer 112 and the upper electrode 113 are each disconnected.

FIG. 5B is an enlarged view of the light-emitting device 110R, the light-emitting device 110G, the partition 120 positioned therebetween, and the vicinity thereof. The organic compound layers 112Ra and 112Ga are provided over the partition 120, and the layer 113a is provided to cover the partition 120 and the organic compound layers 112Ra and 112Ga. The layer 113a is a conductive layer containing the same material as the upper electrode 113R and the upper electrode 113G.

One end portion of each of the organic compound layer 112Ra, the organic compound layer 112Ga, and the organic compound layer 112Ba (not illustrated) is formed by disconnection by the partition 120, and the other end portion of each of the organic compound layer 112Ra, the organic compound layer 112Ga, and the organic compound layer 112Ba (not illustrated) is formed using a shadow mask positioned over the partition 120. Depending on the position of the shadow mask overlapping with the partition 120, there may be a region where parts of the organic compound layer 112Ra, the organic compound layer 112Ga, and the organic compound layer 112Ba (not illustrated) are formed to overlap with each other.

Although the taper angle is shown here as the angle between the bottom surface and the side surface of the partition 120, an angle (a taper angle ') between the side surface of the partition 120 and a top surface of a base film (here, the insulating layer 133) under the partition 120 in a region not in contact with the partition 120 can also be used as illustrated in FIG. 5B.

In that case, ' = 180° - (each of and ' is greater than 0° and less than 180°) is satisfied. In other words, the preferable range of the taper angle ' can be greater than or equal to 30° and less than or equal to 85°, further preferably greater than or equal to 45° and less than or equal to 80°, or can be greater than or equal to 5° and less than or equal to 75°, further preferably greater than or equal to 10° and less than or equal to 60°. As for which angle is used to express the taper angle, the one that is easier to measure can be selected in consideration of the surface shape of the base film (e.g., the insulating layer 133).

### Modification example 2

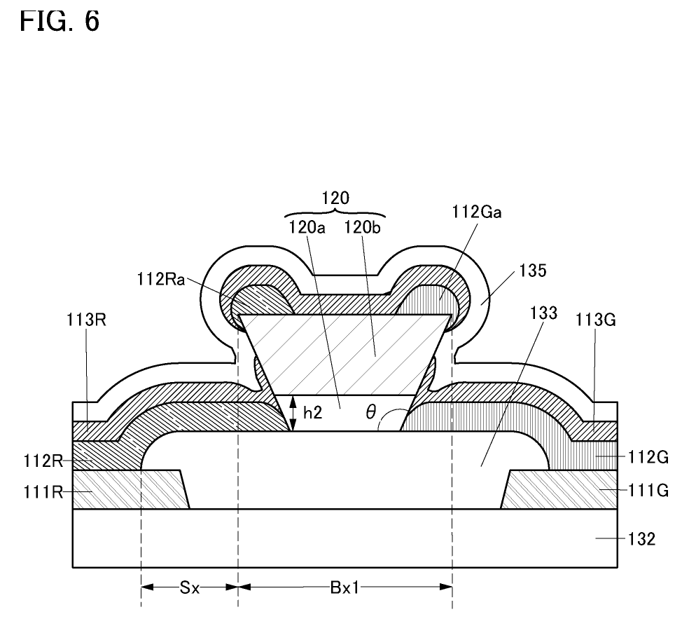

Although FIG. 5A and the like illustrate the example in which the partition has a conductive property and an inverse tapered shape, the partition 120 may have an inverse tapered shape with a stacked structure of a layer 120a having an insulating property as a lower layer and a layer 120b having a conductive property as an upper layer. FIG. 6 illustrates such an example of the partition 120 having an inverse tapered shape and including the layer 120a and the layer 120b.

In FIG. 6, the layer 120a is provided in contact with the top surface of the insulating layer 133. The end portion of the organic compound layer 112 is positioned over the insulating layer 133. The end portion of the organic compound layer 112 is in contact with the layer 120a having an insulating property. The upper electrode 113 covers the organic compound layer 112 and is in contact with part of each of the side surfaces of the layer 120a and the layer 120b. The organic compound layer 112Ra, the organic compound layer 112Ga, the organic compound layer 112Ba (not illustrated), and the protective layer 135 can be provided as in FIG. 5A and the like.

The use of an insulating material for the layer 120a can prevent leakage from the pixel electrode to the upper electrode 113 through the side surface of a lower functional layer (e.g., the hole-injection layer) of the organic compound layer 112, not through an upper functional layer of the organic compound layer 112, even when the side surface of the organic compound layer 112 is in contact with the partition 120. A thickness h2 of the layer 120a preferably exceeds the thickness of the organic compound layer 112, which is the thickest in the light-emitting device 110. Such a structure can prevent a plane formed by the side surfaces of the layers 120a and 120b from being covered with the organic compound layer 112 in a cross-sectional view. Accordingly, the organic compound layer 112 can be formed under conditions where leakage to the upper electrode 113 does not occur through the side surface of the organic compound layer 112. This facilitates the manufacturing process and improves the manufacturing yield.

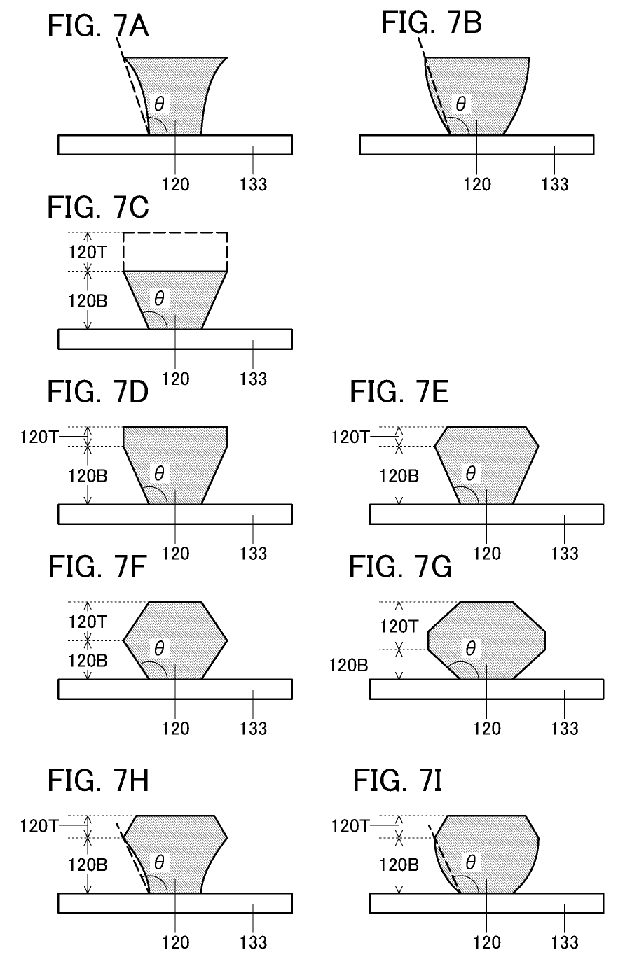

Each of FIGS. 7A - 7I illustrates the partition 120 formed over the insulating layer 133, and is an enlarged view of a region including the insulating layer 133 and the partition 120.

In examples illustrated in FIGS. 7A and 7B, the side surface of the partition 120 is curved. FIG. 7A illustrates the side surface having a concave surface, and FIG. 7B illustrates the side surface having a convex surface.

In the case where the side surface of the partition 120 is curved, it is difficult to uniquely determine the taper angle . In that case, as illustrated in FIGS. 7A and 7B, in a cross-sectional view, a straight line that connects a point of a portion with a largest width in the partition 120 and a point of an end portion of the contact surface of the partition 120 with the base film (the insulating layer 133) is assumed to be a virtual side surface of the partition 120; and an angle between the straight line and the contact surface of the partition 120 with the base film (the insulating layer 133) can be the taper angle . As long as the partition 120 has a tapered shape at least in a portion in contact with the base film, there is no particular limitation on the shape of the partition 120 in a portion above the portion in contact with the base film.

Specifically, as illustrated in FIG. 7C, the partition 120 can be divided into a lower portion 120B (also referred to as a first portion) having an inverse tapered shape and an upper portion 120T (also referred to as a second portion) positioned above the lower portion 120B. Since the shape of the upper portion 120T can be varied, the shape is not illustrated here and is denoted by a dashed line. Examples of different shapes of the upper portion 120T will be described below.

FIG. 7D illustrates an example of the upper portion 120T having a rectangular shape in a cross-sectional view. FIGS. 7E and 7F each illustrate an example of the upper portion 120T having a trapezoidal shape in which the length of the upper side (also referred to as the upper base) is shorter than the length of the lower side (also referred to as the lower base) in a cross-sectional view. Note that the upper side and the lower side are straight-line segments along the width direction of the partition 120. FIG. 7E illustrates an example in which the height of the upper portion 120T is smaller than that of the lower portion 120B, and FIG. 7F illustrates an example in which the height of the upper portion 120T is substantially equal to that of the lower portion 120B.

It can also be said that the partition 120 illustrated in each of FIGS. 7D - 7F has a hexagonal shape in a cross-sectional view. FIG. 7G illustrates an example of the partition 120 having an octagonal shape in a cross-sectional view. In FIG. 7G, part of the side surface of the partition 120 is substantially perpendicular to the formation surface.

FIGS. 7H and 7I illustrate modification examples of FIGS. 7A and 7B, respectively, in which the partition 120 includes the lower portion 120B having a curved surface and the upper portion 120T having a trapezoidal shape in a cross-sectional view.

Note that although the side surface of the partition 120 has corner portions in the above description, the corners are rounded in some cases depending on a processing method of the partition 120. The partition 120 tends to have rounded corners, particularly when the partition 120 is formed by an isotropic etching method such as wet etching.

### Modification example 3

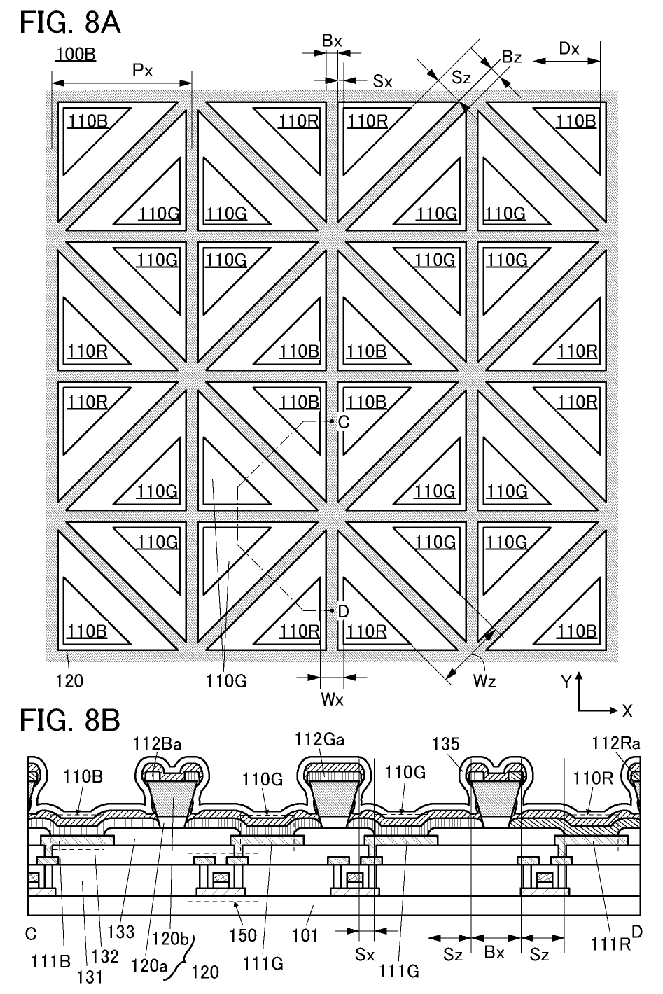

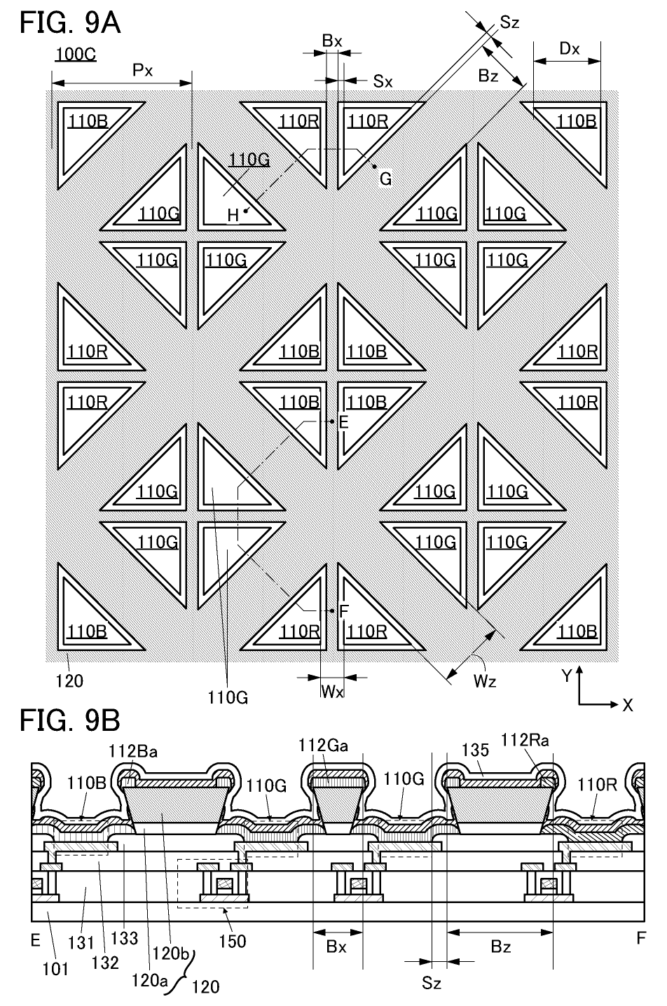

In this modification example, part of a pixel arrangement in the display portion of each of the display apparatuses 100B and 100C will be described. Each of the display apparatuses 100B and 100C has a pixel arrangement illustrated in FIG. 8A or 9A. This pixel arrangement includes a first row where light-emitting devices 110R arranged in two rows and two columns adjacent to each other and light-emitting devices 110B arranged in two rows and two columns adjacent to each other are alternately arranged in the X direction. The pixel arrangement also includes a second row where light-emitting devices 110G arranged in two rows and two columns adjacent to each other are repeatedly arranged in the X direction. The first row and the second row are alternately arranged. The pixel arrangement also includes a first column where the light-emitting devices 110R arranged in two rows and two columns adjacent to each other and the light-emitting devices 110B arranged in two rows and two columns adjacent to each other are alternately arranged in the Y direction. The pixel arrangement also includes a second column where the light-emitting devices 110G arranged in two rows and two columns adjacent to each other are repeatedly arranged in the Y direction. The first column and the second column are alternately arranged.

FIGS. 8A and 8B illustrate an example in which red, green, and blue light-emitting devices 110R, 110G, and 110B are in the PenTile arrangement. FIG. 8A is a schematic top view, and FIG. 8B is a schematic cross-sectional view of the display apparatus 100B along the cutting line C–D in FIG. 8A.

As illustrated in the top view in FIG. 8A, a gap is provided between the partition 120 and the light-emitting device 110. Note that the partition 120 has a uniform width. FIG. 8A illustrates a width Px of the pixel in the X direction, a width Bx of the partition 120 in the X direction, and a width Dx of the light-emitting device in the X direction. In the case where the light-emitting devices that emit light of the same color are adjacent to each other with the partition therebetween, the gap between the light-emitting device 110 and the partition 120 is referred to as a gap Sx. In the case where the light-emitting devices that emit light of different colors are adjacent to each other with the partition 120 therebetween, the gap between the light-emitting device 110 and the partition 120 is referred to as a gap Sz. Although the X direction and the Y direction are used for description here, the X direction and the Y direction may be interchanged with each other because this arrangement is point-symmetric.

As illustrated in FIG. 8A, the shortest distance between the light-emitting devices 110R and 110G or between the light-emitting devices 110G and 110B corresponds to the sum of twice the gap Sz and the width Bx (2 × Sz + Bx).

As illustrated in FIG. 8A and the like, the shortest distance between two light-emitting devices 110R, 110G, or 110B that emit light of the same color corresponds to the sum of twice the gap Sx and the width Bx (2 × Sx + Bx).

In other words, the distance between the light-emitting devices that emit light of different colors is different from the distance between the light-emitting devices that emit light of the same color.

As illustrated in FIGS. 9A and 9B, the width of the partition 120 between the light-emitting devices that emit light of different colors may be different from the width of the partition 120 between the light-emitting devices that emit light of the same color. FIG. 9A is a schematic top view of a display apparatus 100C, and FIG. 9B is a schematic cross-sectional view of the display apparatus 100C along the cutting line E–F in FIG. 9A. FIGS. 9A and 9B illustrate a width Bz of the partition 120 between the light-emitting devices that emit light of different colors, and the width Bx of the partition 120 between the light-emitting devices that emit light of the same color.

Thus, as illustrated in FIG. 9A and the like, the shortest distance between the light-emitting devices 110R and 110G or between the light-emitting devices 110G and 110B corresponds to the sum of twice the gap Sz and the width Bz (2 × Sz + Bz).

In the display apparatus 100C, as in the display apparatus 100B, the distance between the light-emitting devices that emit light of different colors is different from the distance between the light-emitting devices that emit light of the same color.

In the arrangements described with reference to FIGS. 8A - 9B, the light-emitting layers for the same color are separated by the partition; thus, the pixel density can exceed the upper limit that is imposed by the accuracy of shadow mask alignment. Since the light-emitting layers for the same color are separated by the partition, the organic compound layer 112Ga over the partition 120 placed between adjacent light-emitting devices 110G, for example, is not divided and is formed as a continuous film. In the case where the light-emitting device 110G is adjacent to a light-emitting device that emits light of the same color (i.e., the light-emitting device 110G), the organic compound layer 112Ga is formed without disconnection over the top surface of the partition 120 between the adjacent light-emitting devices 110G.

Although FIGS. 8A and 8B illustrate the organic compound layers also over the partition 120 placed between the light-emitting devices that emit light of different colors, the organic compound layers are not necessarily formed over the partition 120 in the case of mask misalignment, a different pixel density, or the like.

In this pixel arrangement, the distance between light-emitting devices that emit light of the same color (specifically, 2 × Sx + Bx) is shorter than the distance between light-emitting devices that emit light of different colors (specifically, 2 × Sz + Bx or 2 × Sz + Bz), so that a high aperture ratio can be achieved even at a pixel density higher than or equal to 500 ppi. In particular, at a high pixel density of 1000 ppi, a distance necessary for separate formation using a shadow mask such as a fine metal mask can be provided between light-emitting devices, and a practical aperture ratio higher than or equal to 20 % can be achieved. In other words, a high pixel density and a high aperture ratio can be achieved at the same time, and a high aperture ratio can be maintained even at a pixel density higher than or equal to 500 ppi in particular.

As illustrated in FIG. 8A and the like, a gap is provided between the partition 120 and the light-emitting device 110 in a plan view. A gap between light-emitting devices that emit light of the same color can be narrowed because it does not necessarily require consideration of the accuracy of shadow mask alignment. For example, in FIG. 8A, a gap between the light-emitting device 110R and the partition between two adjacent light-emitting devices 110R, a gap between the light-emitting device 110G and the partition between two adjacent light-emitting devices 110G, and a gap between the light-emitting device 110B and the partition between two adjacent light-emitting devices 110B are each denoted as the gap Sx, which is smaller than the gap Sz between the light-emitting device and the partition between adjacent light-emitting devices that emit light of different colors (e.g., the light-emitting devices 110R and 110G).

In the case where the light-emitting devices 110 adjacent to each other with the partition therebetween emit light of the same color, the shortest distance Wx between the adjacent light-emitting devices 110 can be expressed as the sum of twice the gap Sx and the width Bx (Sx × 2 + Bx).

In the case where the light-emitting devices 110 adjacent to each other with the partition therebetween emit light of different colors, the shortest distance Wz between the adjacent light-emitting devices 110 can be expressed as the sum of twice the gap Sz and the width Bz (Sz × 2 + Bz).

FIG. 9A illustrates an example in which the width of the partition 120 between the light-emitting devices that emit light of different colors is different from the width of the partition 120 between the light-emitting devices that emit light of the same color in a plan view. A gap between the light-emitting device R and the partition between two adjacent light-emitting devices R, a gap between the light-emitting device G and the partition between two adjacent light-emitting devices G, and a gap between the light-emitting device B and the partition between two adjacent light-emitting devices B are each denoted as the gap Sx. In addition, FIG. 9A illustrates the gap Sz between the light-emitting device and the partition between adjacent light-emitting devices that emit light of different colors (e.g., the light-emitting devices B and G).

In the case where the light-emitting devices 110 adjacent to each other with the partition therebetween emit light of the same color, the shortest distance Wx between the adjacent light-emitting devices 110 can be expressed as the sum of twice the gap Sx and the width Bx (Sx × 2 + Bx).

In the case where the light-emitting devices 110 adjacent to each other with the partition therebetween emit light of different colors, the shortest distance Wz between the adjacent light-emitting devices 110 can be expressed as the sum of twice the gap Sz and the width Bz (Sz × 2 + Bz).

In either case of FIG. 8A or FIG. 9A, the distance Wx can be smaller than the distance Wz. Specifically, the distance Wx is preferably less than 10 μm, further preferably less than 5 μm. Specifically, the distance Wz is less than or equal to 40 μm, preferably less than 25 μm, further preferably less than 15 μm, still further preferably less than 10 μm.

As described above, the light-emitting layers for the same color are separated by the partition; thus, the pixel density can exceed the upper limit that is imposed by the accuracy of shadow mask alignment. Since the light-emitting layers for the same color are separated by the partition, the organic compound layer 112Ga over the partition 120 placed between adjacent light-emitting devices 110G, for example, is not divided and is formed as a continuous film. In the case where the light-emitting device 110G is adjacent to a light-emitting device that emits light of the same color (i.e., the light-emitting device 110G), the organic compound layer 112Ga is formed without disconnection over the top surface of the partition 120 between the adjacent light-emitting devices 110G.

Although an example is described above in which the organic compound layers are provided also over the partition 120 placed between the light-emitting devices that emit light of different colors, the organic compound layers are not necessarily formed over the partition 120 in the case of mask misalignment, a different pixel density, or the like.

In the above pixel arrangement, the distance between light-emitting devices that emit light of the same color (specifically, Sx × 2 + Bx) is shorter than the distance between light-emitting devices that emit light of different colors (specifically, Sz × 2 + Bx or Sz × 2 + Bz). Accordingly, a high aperture ratio can be achieved even at a pixel density higher than or equal to 500 ppi. In the display apparatus of one embodiment of the present invention, a distance necessary for separate formation using a shadow mask such as a fine metal mask can be provided between light-emitting devices, and thus the aperture ratio can be increased.

An example of a factor that determines the size of the gap Sz is the accuracy of shadow mask alignment.

The gap Sx is not affected by the accuracy of shadow mask alignment. The gap Sx corresponds to, for example, a distance between an end portion of an opening in the insulating layer 133 covering the pixel electrode 111 and an end portion of the partition 120. Thus, the size of the gap Sx is dominated by the accuracy of photolithography or the like.

The gap Sx can be roughly decreased to the accuracy of photolithography. Accordingly, the display apparatus of one embodiment of the present invention, for example, can have a high aperture ratio even with a high resolution.

The display apparatus of one embodiment of the present invention can have a high aperture ratio of 30 % or higher at 700 ppi or approximately 13 % at 1000 ppi, for example. In other words, a high pixel density and a high aperture ratio can be achieved at the same time, and a high aperture ratio can be maintained even at a pixel density higher than or equal to 500 ppi in particular.

The distance between the light-emitting devices that emit light of different colors is preferably larger than the accuracy of alignment between the substrate and the fine metal mask, for example. Specifically, assuming that the maximum amount of positional deviation of the fine metal mask from the substrate, Q1, is equal to ±M1 (μm), the distance between the light-emitting devices that emit light of different colors is preferably greater than or equal to 2 × M1 (μm), for example.

Here, the upward and downward (or leftward and rightward) positional deviations of the fine metal mask can be expressed as +M1 in one of the directions (e.g., the upward or rightward direction) and -M1 in the other direction (e.g., the downward or leftward direction).

The distance between the light-emitting devices that emit light of different colors is preferably determined in consideration of a deviation due to the processing accuracy of the fine metal mask, a blur in film formation, or the like in addition to the above positional deviation. For example, it is preferable that a region where a film formation blur occurs not overlap with the light-emitting region of the light-emitting device 110.

As deviations due to the processing accuracy of the fine metal mask, it is assumed here that a deviation of the opening size, Q2, is equal to ±M2 (μm) and a deviation of the opening position, Q3, is equal to ±M3 (μm).

In consideration of the region where a film formation blur occurs, it is assumed here that the distance between a device region and the edge of an opening in the fine metal mask, Q4, which is necessary for design, is equal to ±M4 (μm).

The amount of deviation in consideration of the above-described positional deviation (Q1), deviations due to processing accuracy (Q2 and Q3), film formation blur (Q4), and the like, Qt, is equal to Q1 + Q2 + Q3 + Q4 = ±Mt (μm).

For example, ±Mt (μm) can be expressed as the amount of deviation of the end portion of a region where a film is formed using the fine metal mask (excluding the region where a film formation blur occurs).

As for the specific range of ±Mt (μm), Mt is preferably less than or equal to 12 (μm), further preferably less than or equal to 10 (μm), further preferably less than or equal to 7.5 (μm), further preferably less than or equal to 5 (μm), further preferably less than or equal to 2 (μm), for example.

For example, Mt (μm) can be less than or equal to 5 (μm) when M1 (μm) is less than or equal to 1 (μm), M2 (μm) is less than or equal to 1 (μm), M3 (μm) is less than or equal to 2 (μm), and M4 (μm) is less than or equal to 1 (μm).

In the case where the value of ±Mt (μm) is ±5 μm, for example, the distance Wz between the light-emitting devices 110 that emit light of different colors can be equal to (5 × 2 + 2) = 12 μm with a margin of 2 μm.

As described above, Wz is preferably greater than or equal to a value that takes into consideration the processing accuracy of the fine metal mask, the film formation blur, the accuracy of alignment between the substrate and the fine metal mask, and the like. Specifically, in the case where the position of the edge of an opening in the fine metal mask is deviated in the upward or downward direction or in the leftward or rightward direction, it is preferable that the region where a film is formed (excluding the region where a film formation blur occurs) overlap with the light-emitting region of the light-emitting device 110 and not overlap with the light-emitting regions of the light-emitting devices 110 that emit light of different colors.

The distance Wx between the light-emitting devices that emit light of the same color corresponds to a value that takes into consideration the accuracy of positional alignment in photolithography with the positions of the partition 120, the opening portion in the insulating layer 133, and the pixel electrode 111, for example. Here, Wx is assumed to be 6 μm, for example.

Specific examples of the values of the gap Sx, the gap Sz, and the width Bx and the width Bz of the partition 120 are given below.

In the above example, it is assumed that the shortest distance Wx between the light-emitting devices that emit light of the same color is 6 μm and the shortest distance Wz between the light-emitting devices that emit light of different colors is 12 μm.

In FIG. 8A, the width Bx of the partition 120 between the light-emitting devices that emit light of the same color is equal to the width Bz of the partition between the light-emitting devices that emit light of different colors. The gap Sx between the light-emitting device and the partition 120 between the light-emitting devices that emit light of the same color is different from the gap Sz between the light-emitting device and the partition 120 between the light-emitting devices of different colors.

In an example satisfying the above values, the widths Bx and Bz are each 4 μm, the gap Sx is 1 μm, and the gap Sz is 4 μm. The distance Wx can be expressed as (Sx × 2 + Bx) = (1 × 2 + 4) = 6 μm, and the distance Wz can be expressed as (Sz × 2 + Bz) = (4 × 2 + 4) = 12 μm.

In FIG. 9A, the width Bx of the partition 120 between the light-emitting devices that emit light of the same color is different from the width Bz of the partition between the light-emitting devices that emit light of different colors. The gap Sx between the light-emitting device and the partition 120 between the light-emitting devices that emit light of the same color is equal to the gap Sz between the light-emitting device and the partition 120 between the light-emitting devices that emit light of different colors.

In an example satisfying the above values, the width Bx is 4 μm, the width Bz is 10 μm, the gap Sx is 1 μm, and the gap Sz is 1 μm. The distance Wx can be expressed as (Sx × 2 + Bx) = (1 × 2 + 4) = 6 μm, and the distance Wz can be expressed as (Sz × 2 + Bz) = (1 × 2 + 10) = 12 μm.

When the width Bx or the width Bz of the partition 120 is decreased, the gap Sx and the gap Sz can be increased. For example, when the width Bx or the width Bz of the partition 120 is decreased from 4 μm to 3 μm, the gap Sx and the gap Sz can each be increased by 0.5 μm.

With use of the above values of Wx and Wz, the aperture ratio in the structure illustrated in FIG. 8B and the like can be estimated to be 50.0 % at a pixel density of 513 ppi, 38.6 % at 664 ppi, 36.1 % at 700 ppi, 18.5 % at 1000 ppi, or 15.7 % at 1058 ppi.

The display apparatus of one embodiment of the present invention can maintain its aperture ratio at a high resolution and can thus display an image with an improved texture. Thus, in the case where the display apparatus of one embodiment of the present invention is used as a direct-view display apparatus, a phenomenon can be expected in which a natural stereoscopic effect can be obtained from a two-dimensional image without using a parallax effect or the like (such a phenomenon is referred to as Natural 3D (registered trademark) or N3D (registered trademark)).

The above is the description of the modification examples.

### Manufacturing method example 1

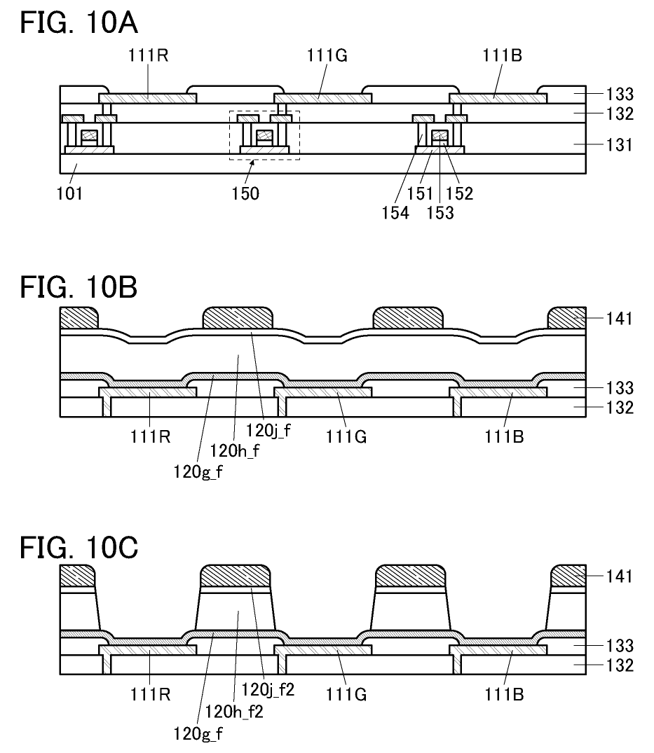

An example of a method for manufacturing the display apparatus of one embodiment of the present invention will be described below with reference to drawings. Here, the description is made with use of the display apparatus 100 shown in the above structure example. FIGS. 10A - 15E are schematic cross-sectional views of steps in the manufacturing method of the display apparatus described as an example below.

Note that thin films included in the display apparatus (e.g., insulating films, semiconductor films, and conductive films) can be formed by a sputtering method, a CVD method, a vacuum evaporation method, a pulsed laser deposition (PLD) method, an atomic layer deposition (ALD) method, or the like.

Alternatively, thin films included in the display apparatus (e.g., insulating films, semiconductor films, and conductive films) can be formed by a method such as spin coating, dipping, spray coating, ink-jetting, dispensing, screen printing, or offset printing or with a doctor knife, a slit coater, a roll coater, a curtain coater, or a knife coater.

Examples of the sputtering method include an RF sputtering method using a high-frequency power source for a sputtering power source, a DC sputtering method using a DC power source, and a pulsed DC sputtering method in which voltage applied to an electrode is changed in a pulsed manner. For film formation using an insulating target, an RF sputtering method is preferably used. A DC sputtering method is used mainly in the case of film formation using a conductive target. In a DC sputtering method, not only formation of a conductive film but also formation of an insulating film is possible by reactive sputtering using a pulsed DC sputtering method. The pulsed DC sputtering method can be specifically used to form a layer of a compound such as an oxide, a nitride, or a carbide by a reactive sputtering method.

CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object to be processed. A thermal CVD method yields a film with few defects because of no plasma damage during film formation.

Examples of the ALD method include a thermal ALD method, in which a precursor and a reactant react with each other only by a thermal energy, and a PEALD method, in which a reactant excited by plasma is used.

Unlike a sputtering method, a CVD method and an ALD method are less likely to be influenced by the shape of an object to be processed and thus enable favorable step coverage. In particular, an ALD method allows excellent step coverage and excellent thickness uniformity and can be suitably used to cover a surface of an opening portion with a high aspect ratio, for example. Note that an ALD method has a relatively low film formation rate; hence, in some cases, an ALD method is preferably combined with another film formation method with a high film formation rate, such as a CVD method.

By a CVD method, a film with a desired composition can be formed by adjusting the flow rate ratio of source gases. For example, a CVD method enables formation of a film whose composition is gradually changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the display apparatus can be improved in some cases.

An ALD method in which a plurality of different kinds of precursors are used enables formation of a film with a desired composition. In the case where a plurality of different kinds of precursors are introduced, the number of cycles for each precursor is controlled, whereby a film with a desired composition can be formed. Furthermore, a film whose composition is continuously changed can be formed as in the CVD method.

The thin films included in the display apparatus can be processed by a photolithography method or the like. Besides, a nanoimprinting method, a sandblasting method, a lift-off method, or the like may be employed to process the thin films. Alternatively, island-shaped thin films may be directly formed by a film formation method using a shadow mask such as a metal mask. Alternatively, a directed self-assembly (DSA) method may be used.

There are two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by a liquid immersion exposure technique. As the light for exposure, extreme ultraviolet (EUV) light or X-rays may also be used. Furthermore, instead of the light used for the exposure, an electron beam can also be used. EUV, X-rays, or an electron beam is preferably used to enable extremely minute processing. When exposure is performed by scanning with the above light or a beam such as an electron beam, a photomask is not needed.

For etching of thin films, a dry etching method, a wet etching method, a sandblasting method, or the like can be used. By a dry etching method, isotropic etching or anisotropic etching can be performed when the conditions of etching are controlled. By a wet etching method, isotropic etching can be performed.

First, as illustrated in FIG. 10A, the substrate 101 is prepared, and the transistors 150, the insulating layer 131, the insulating layer 132, and the like are formed. Next, a conductive film is formed over the insulating layer 132 and an unnecessary portion of the conductive film is removed by etching, whereby the pixel electrode 111R, the pixel electrode 111G, and the pixel electrode 111B are formed.

In the case where a conductive film that reflects visible light is used for the pixel electrodes 111, it is preferable to use a material (e.g., silver or aluminum) having as high a reflectance as possible in the whole wavelength range of visible light. This can increase both light extraction efficiency and color reproducibility of the light-emitting devices.

Next, as illustrated in FIG. 10A, the insulating layer 133 is formed to cover the end portions of the pixel electrodes 111. An organic insulating film or an inorganic insulating film can be used as the insulating layer 133.

The end portions of the insulating layer 133 preferably have a tapered shape to improve step coverage with a film to be organic compound layers. In particular, when an organic insulating film is used, a photosensitive material is preferably used so that the shape of the end portions can be easily controlled by the conditions of light exposure and development.

Next, as illustrated in FIG. 10B, a film 120g_f, a film 120h_f, and a film 120j_f to be the layer 120g, the layer 120h, and the layer 120j are stacked in this order. The layers 120g, 120h, and 120j are collectively referred to as the partition 120 in some cases. Note that the components below the insulating layer 132 are omitted in FIG. 10B and subsequent drawings.

The film 120g_f is preferably formed using a material that exhibits high etching rate selectivity with respect to the pixel electrodes 111. The film 120g_f is also preferably formed using a material that exhibits high etching rate selectivity with respect to the films 120h_f and 120j_f. The film 120h_f is preferably formed using a material that exhibits high etching rate selectivity with respect to the film 120j_f.

The film 120g_f and the uppermost layer of the pixel electrode 111 are preferably formed using different conductive materials. Alternatively, in the case where a film functioning as an etching stopper is formed before the formation of the film 120g_f and the film positioned over the pixel electrode 111 is removed after the etching of the film 120g_f, the pixel electrode 111 and the film 120g_f can be formed using the same conductive material.

The film 120h_f is preferably formed using an insulating material different from that of the film 120j_f. For example, when a silicon oxynitride film is used as the film 120h_f and a silicon nitride oxide film is used as the film 120j_f, the etching selectivity can be high.

The film 120h_f is preferably formed using an insulating material different from that of the insulating layer 133. Alternatively, before the film 120g_f is formed, a film functioning as an etching stopper may be formed to protect the insulating layer 133 from etching treatment performed on the films 120h_f and 120j_f. In that case, the film 120h_f, the film 120j_f, and the insulating layer 133 can be formed using the same insulating material.

Next, a resist mask 141 is formed over the film 120j_f (FIG. 10B). In the case where a large-sized substrate is used as the substrate 101, the subsequent steps may be performed after the substrate is cut at this point. Then, portions of the films 120h_f and 120j_f that are not covered with the resist mask 141 are etched to form a film 120h_f2 and a film 120j_f2 (FIG. 10C). The films 120h_f and 120j_f can be processed by a wet etching method or a dry etching method. The films 120h_f and 120j_f are preferably processed by dry etching.

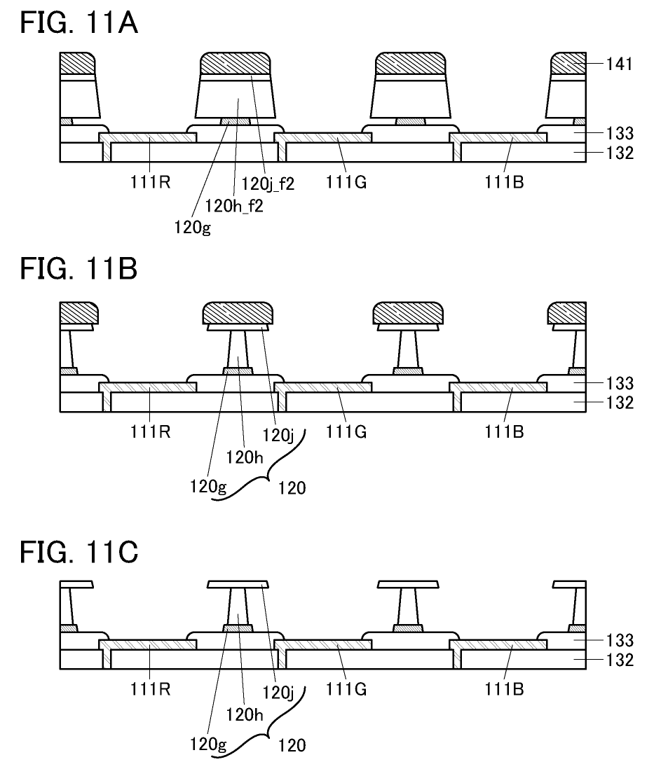

Next, portions of the film 120g_f that are not covered with the resist mask 141 are etched to form the layer 120g (FIG. 11A). The film 120g_f can be processed by a wet etching method or a dry etching method. The film 120g_f is preferably processed by wet etching. By the wet etching method, the side surface of the film 120g_f can be made to recede to a position inward from the film 120h_f2.

The wet etching method can inhibit etching of the pixel electrodes 111 in processing the film 120g_f, as compared with the dry etching method.

In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a mixed solution containing two or more of these acids, for example. In the case of using a wet etching method, a mixed acid chemical solution containing water, phosphoric acid, dilute hydrofluoric acid, and nitric acid may be used. A chemical solution used for the wet etching treatment may be alkaline or acid.

Next, the films 120h_f2 and 120j_f2 are etched by isotropic etching to make their side surfaces recede, whereby the layer 120h and the layer 120j are formed (FIG. 11B). For example, the films 120h_f2 and 120j_f2 can be etched by a wet etching method or an isotropic dry etching method. When the films 120h_f2 and 120j_f2 are processed such that the lower film 120h_f2 is etched faster than the film 120j_f2, the film 120j_f2 can be formed to overhang (or protrudes) in the lateral direction. After the layer 120g, the layer 120h, and the layer 120j are formed in this manner, the resist mask 141 is removed (FIG. 11C).

In the case of forming the partition 120 having an inverse tapered shape as illustrated in FIG. 5B, for example, only the film 120g_f is formed and etched by an isotropic etching method. For example, the film 120g_f can be etched by a wet etching method or an isotropic dry etching method. Wet etching is particularly preferable because it excels in isotropic etching and enables favorable processability even when the film 120g_f has a small thickness.

The film 120g_f is processed such that the lower portion of the film 120g_f is etched faster than the upper portion thereof, whereby the partition 120 having an inverse tapered shape can be formed. For example, materials are selected such that the adhesion between the film 120g_f and the insulating layer 133 is lower than the adhesion between the film 120g_f and the resist mask 141, whereby the etching rate of the lower portion can be made higher than that of the upper portion and thus the partition 120 having an inverse tapered shape can be formed. For example, when a conductive oxide such as indium tin oxide is used for the film 120g_f, an organic material with low adhesion to indium tin oxide (e.g., an acrylic resin) can be used for the insulating layer 133.

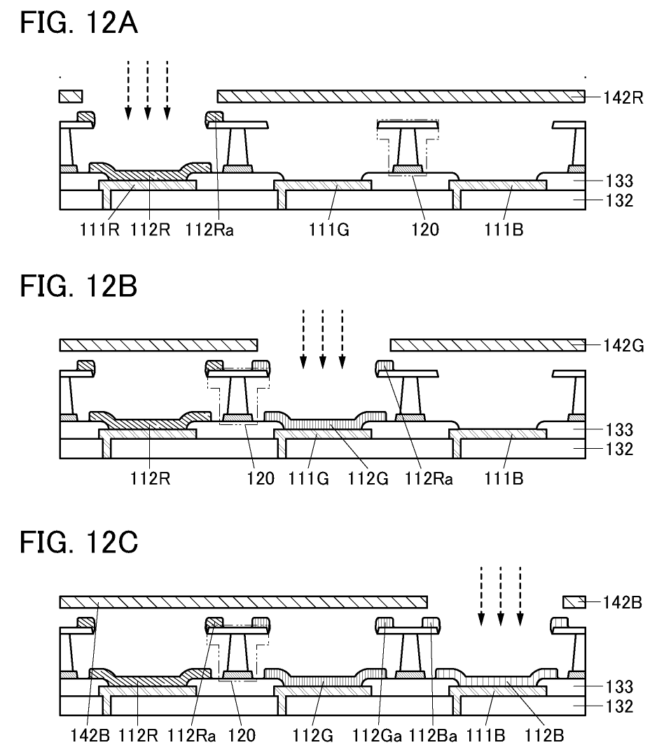

Next, the organic compound layer 112R and the organic compound layer 112Ra are formed by a vacuum evaporation method using a shadow mask 142R (FIG. 12A). Note that the organic compound layer 112R having an island shape may be formed by a sputtering method using a fine metal mask (FMM) or an inkjet method. The organic compound layer 112R and the organic compound layer 112Ra are formed by disconnection by the partition 120. The organic compound layer 112R is formed over the pixel electrode 111R and the insulating layer 133, and the organic compound layer 112Ra is formed at part of each of the side and top surfaces of the partition 120.

In an evaporation method using a shadow mask or the like, evaporation is performed in an area larger than an opening pattern in the shadow mask in some cases. For example, the organic compound layer 112Ra is formed also in a region under the shadow mask 142R in some cases. Specifically, the organic compound layer 112Ra is formed over the partition 120 overlapping with the shadow mask 142R in a cross-sectional view in some cases. The organic compound layer 112R is formed also over the insulating layer 133 overlapping with the protruding portion of the partition 120 in some cases. In that case, it is necessary to adjust the position of the laterally overhanging portion of the layer 120j in the partition 120, the traveling direction of a film material, or the like in order to prevent the end portion of the organic compound layer 112R from being in contact with the layer 120g of the partition 120.

Next, like the organic compound layer 112R, the organic compound layer 112G and the organic compound layer 112Ga are formed by a vacuum evaporation method using a shadow mask 142G (FIG. 12B). The organic compound layer 112G and the organic compound layer 112Ga are formed by disconnection by the partition 120. The organic compound layer 112G is formed over the pixel electrode 111G and the insulating layer 133, and the organic compound layer 112Ga is formed at part of each of the side and top surfaces of the partition 120.

Next, like the organic compound layers 112R and 112G, the organic compound layer 112B and the organic compound layer 112Ba are formed by a vacuum evaporation method using a shadow mask 142B (FIG. 12C). The organic compound layer 112B and the organic compound layer 112Ba are formed by disconnection by the partition 120. The organic compound layer 112B is formed over the pixel electrode 111B and the insulating layer 133, and the organic compound layer 112Ba is formed at part of each of the side and top surfaces of the partition 120.

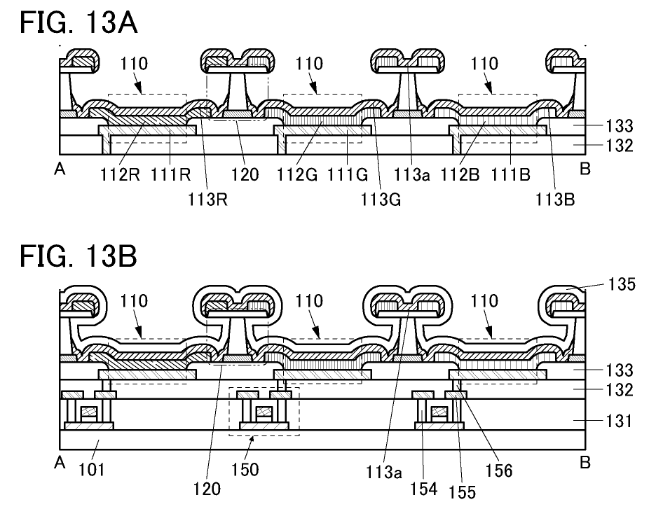

Next, the upper electrode 113R, the upper electrode 113G, and the upper electrode 113B are formed to cover the organic compound layer 112R, the organic compound layer 112G, the organic compound layer 112B, and the like (FIG. 13A). The upper electrodes 113 of the light-emitting devices 110 are formed to cover the end portions of the organic compound layers 112R, 112G, and 112B and to be in contact with at least part of the layer 120g of the partition 120. The upper electrodes 113 can be formed by one or more of a vacuum evaporation method, a sputtering method, and a CVD method.

The layer 113a is formed to cover organic compound layers such as the organic compound layer 112Ra formed at part of each of the side and top surfaces of the partition 120. The layer 113a is a conductive layer obtained by processing the same conductive film as the pixel electrode.

Next, the protective layer 135 is formed to cover the upper electrode 113, the layer 113a, and the partition 120 (FIG. 13B). The protective layer 135 is preferably formed by a film formation method that provides high step coverage, and is preferably formed by a CVD method or an ALD method. A PECVD method is particularly preferable because the protective layer 135 can be formed over a large-area substrate.

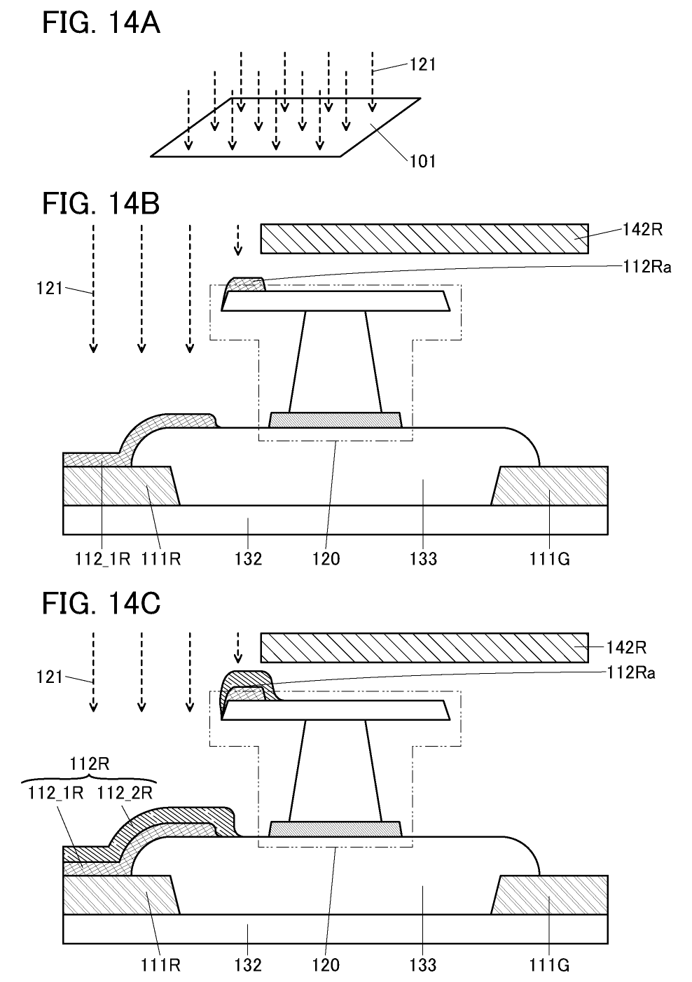

A method for forming the organic compound layer 112R is described here with reference to FIGS. 14A - 14C. The organic compound layer 112R is preferably formed by a highly anisotropic film formation method. In other words, the organic compound layer 112R is formed in such a manner that a film material 121 travels in a direction substantially perpendicular to the top surface of the substrate 101 as illustrated in FIG. 14A. Thus, disconnection can be caused by the partition 120 as illustrated in FIGS. 14B and 14C. In that case, a sufficient space for entry of the upper electrode 113R is preferably provided between the organic compound layer 112R and the partition 120.

The organic compound layer 112R includes the layer 112_1R containing a substance having an electron-accepting property over the pixel electrode 111R (FIG. 14B). The organic compound layer 112R also includes the organic compound layer 112R_2R containing a light-emitting substance over the organic compound layer 112R_1R (FIG. 14C). The layer 112_2R is formed to cover the end portion of the layer 112_1R. For example, the layer 112_2R can be formed under conditions where the film material travels in a direction at an angle with that in the step of forming the layer 112_1R.

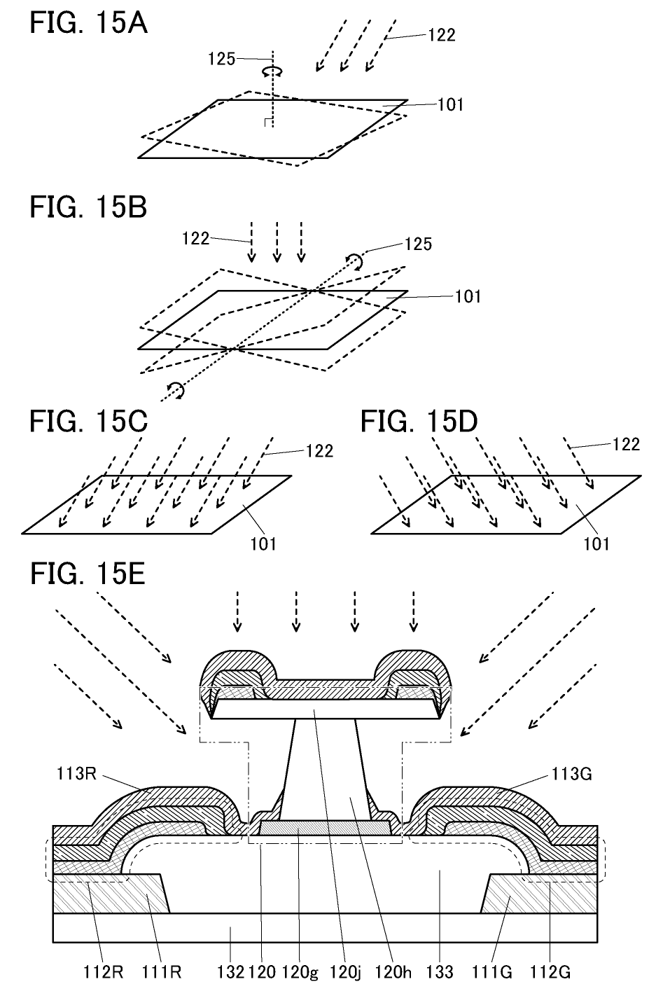

Methods for forming the upper electrode 113 (specifically, the upper electrode 113R, the upper electrode 113G, and the upper electrode 113B) are described with reference to FIGS. 15A - 15E.

The upper electrode 113R, the upper electrode 113G, and the upper electrode 113B (not illustrated) are formed to cover the organic compound layer 112R and the like (FIG. 15E). The upper electrode 113R is formed to cover the end portion of the organic compound layer 112R and to be in contact with at least part of the layer 120g. Similarly, the upper electrode 113G is formed to cover the end portion of the organic compound layer 112G and to be in contact with at least part of the layer 120g. Similarly, the upper electrode 113B is formed to cover the end portion of the organic compound layer 112B and to be in contact with at least part of the layer 120g. The upper electrodes 113 can be formed by one or more of a vacuum evaporation method, a sputtering method, and a CVD method.

The upper electrode 113R is preferably formed by a less anisotropic film formation method than that for the organic compound layer 112R. Similarly, the upper electrode 113G is preferably formed by a less anisotropic film formation method than that for the organic compound layer 112G, and the upper electrode 113B is preferably formed by a less anisotropic film formation method than that for the organic compound layer 112B. In other words, a film formation method is preferably employed in which the traveling direction of a film material of the upper electrode 113 includes not only a component perpendicular to the top surface of the substrate but also a component oblique thereto.

A low-anisotropy film formation method can be obtained by, for example, decreasing the distance between an evaporation source (or a sputtering target) and the substrate, using a plurality of evaporation sources (or sputtering targets), or increasing the area of an evaporation source (or a sputtering target). Alternatively, it is possible to use a film formation apparatus including a mechanism by which a film material 122 travels in a direction oblique to the top surface of the substrate 101 and the substrate 101 rotates on a rotation axis 125 as illustrated in FIG. 15A.

Although FIG. 15A illustrates an example in which the rotation axis 125 passes through the center of the substrate 101, the rotation axis 125 may pass through any point on the substrate 101 or may be positioned outside the substrate 101. The rotation axis 125 is not necessarily perpendicular to the surface of the substrate 101.

Alternatively, it is possible to use a film formation apparatus including a mechanism by which the substrate 101 rotates (or swings) on the rotation axis 125 that is parallel to the substrate surface as illustrated in FIG. 15B. In that case, the film material 122 can travel in a direction perpendicular to the rotation axis 125.

With the use of a film formation apparatus including a mechanism like those illustrated in FIG. 15A and 15B, the film formation process for the upper electrode 113R can include a period in which the film material 122 travels toward the surface of the substrate 101 in an oblique direction as illustrated in FIG. 15C and a period in which the film material 122 travels in the symmetrically opposite oblique direction as illustrated in FIG. 15D. Thus, the upper electrode 113 (specifically, the upper electrode 113R and the upper electrode 113G) can be formed to be in contact with and to cover the layer 120g having a conductive property, as illustrated in FIG. 15E.

Although the cases where the substrate 101 moves are described above as examples, the evaporation source may be moved, or both the substrate 101 and the evaporation source may be moved.

A silicon nitride film, a silicon nitride oxide film, or the like is preferably formed as the protective layer 135 by a PECVD method. Two or more of the above insulating films may be stacked.

For example, an aluminum oxide film can be formed as the protective layer 135 by an ALD method. In that case, as a precursor containing aluminum, trimethylaluminum, triethylaluminum, triisobutylaluminum, dimethylaluminum hydride, tris(dimethylamino)aluminum, tris(diethylamino)aluminum, aluminum trichloride, or the like is preferably used. As an oxidizer, for example, ozone (O₃), oxygen (O₂), water (H₂O), nitrogen dioxide (NO₂), dinitrogen monoxide (N₂O), hydrogen peroxide (H₂O₂), or the like can be used, or two or more of these can be used.

The protective layer 135 may have a stacked-layer structure of a film formed by an ALD method and a film formed by a film formation method other than an ALD method (e.g., a CVD method or a sputtering method). An ALD method provides extremely high step coverage but has a lower film formation rate than other film formation methods; the time taken for the film formation step for the protective layer 135 can be shortened by first forming a film with extremely few defects by an ALD method and then forming a thick insulating film by a CVD method or the like.

Through the above-described steps, the display apparatus 100 can be manufactured.

### Manufacturing method example 2

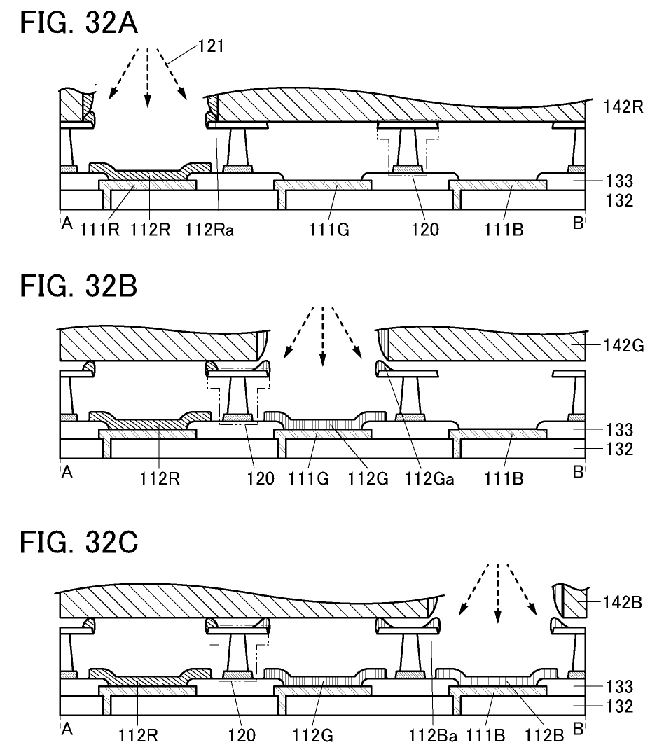

A manufacturing method different from the above-described manufacturing method example 1 will be described with reference to FIGS. 32A - 34B. Note that portions similar to those described in the above-described manufacturing method example 1 are not described in some cases.

First, the components up to the partition 120 are formed as in the manufacturing method example 1 (FIG. 11C).

Next, the organic compound layer 112R is formed using the partition 120 as a spacer (FIG. 32A). The description of FIG. 12A can be referred to for the method for forming the organic compound layer 112R. The organic compound layer 112R is formed over the pixel electrode 111R and the insulating layer 133, and the organic compound layer 112Ra is formed at part of each of the top and side surfaces of the partition 120. The organic compound layers 112R and 112Ra are formed by disconnection by the partition 120.

In the case where the organic compound layer 112R is formed using a shadow mask such as an FMM, the partition 120 can inhibit the shadow mask from being in contact with the formation surface.

In an evaporation method using a shadow mask or the like, evaporation is performed in an area larger than an opening pattern in the shadow mask in some cases. Specifically, a material for forming the organic compound layer 112 may enter a space between the shadow mask 142R and the substrate also in a region overlapping with the shadow mask 142R, whereby the organic compound layer 112a (specifically, the organic compound layer 112Ra, the organic compound layer 112Ga, and the organic compound layer 112Ba) is formed in some cases. Such a phenomenon in which the material for forming the organic compound layer 112 is deposited by evaporation in a region larger than the design size of the opening of the shadow mask is also referred to as a film formation blur or an evaporation blur. When the shadow mask is warped by the self-weight of the shadow mask, heat at the time of evaporation, or the like, a gap is generated between the shadow mask and the substrate. This might cause a film formation blur.

When the top surface of the partition 120 is in contact with the shadow mask 142R as in this manufacturing method example 2, the distance between the substrate and the shadow mask can be shortened. This can reduce the film formation blur in the evaporation step of the organic compound layer 112R.

To maintain close contact between the shadow mask and the substrate, a magnet plate is preferably provided on the rear surface side of the substrate. A magnetic field is generated around the magnet plate. By attractive force owing to this magnetic field, the shadow mask is attracted to the magnet plate even in the case where the shadow mask is deformed by the self-weight or heat. As a result, the shadow mask and the substrate can be brought into close contact, so that deformation of the shadow mask can be inhibited. This can inhibit a large gap from being generated between the shadow mask and the substrate, thereby reducing a film formation blur caused by the entry of the material of the organic compound layer 112 through the gap.

Next, the organic compound layer 112G is formed using the partition 120 as a spacer (FIG. 32B). The organic compound layer 112G is formed over the pixel electrode 111G and the insulating layer 133, and the organic compound layer 112Ga is formed at part of each of the side and top surfaces of the partition 120. The organic compound layer 112G and the organic compound layer 112Ga are formed by disconnection by the partition 120.

The area of the film formation blur of the organic compound layer 112Ga is larger than the area of the film formation blur of the organic compound layer 112Ra in some cases. The film material might reach a larger area through the opening of the shadow mask 142G than the film material does through the opening of the shadow mask 142R. This is because the organic compound layer 112Ra is already formed over the partition 120 at the time of forming the organic compound layer 112G. In other words, the shadow mask and the substrate (specifically, the top surface of the partition 120) are positioned apart from each other by at least the thickness of the organic compound layer 112Ra, which increases the possibility of entry of the film material. However, since the organic compound layer 112Ra is sufficiently thin, the influence of the film formation blur is small.

Next, the organic compound layer 112B is formed using the partition 120 as a spacer (FIG. 32C). The organic compound layer 112B is formed over the pixel electrode 111B and the insulating layer 133, and the organic compound layer 112Ba is formed at part of each of the side and top surfaces of the partition 120. The organic compound layer 112B and the organic compound layer 112Ba are formed by disconnection by the partition 120.

A film formation blur occurs also in a region of the substrate overlapping with the shadow mask 142B, as in the step of forming the organic compound layer 112Ga.

The positional relation between the display apparatus and an evaporation apparatus in the step of forming the organic compound layer 112R is described here.

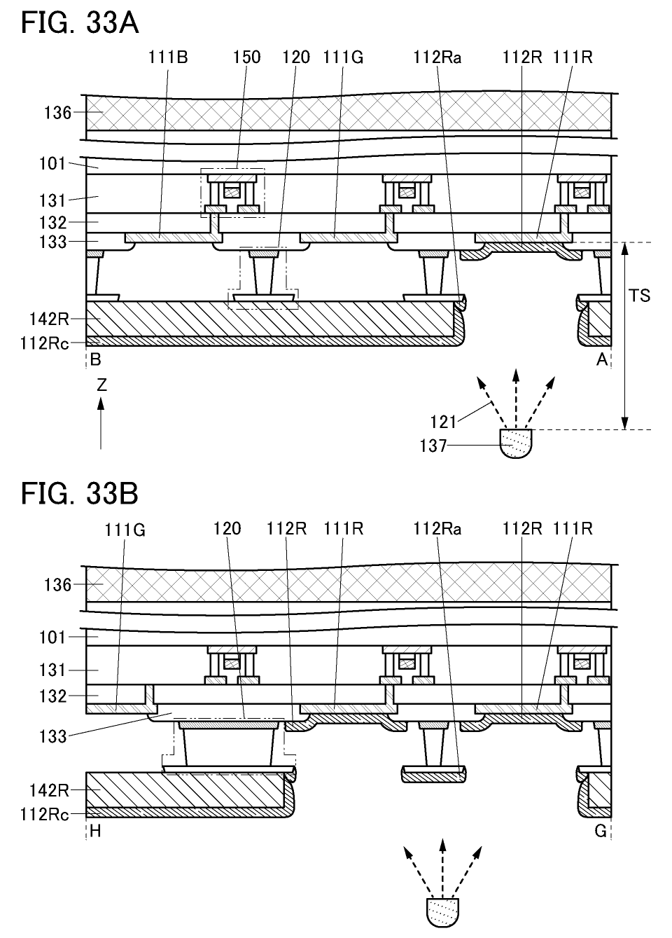

FIG. 33A illustrates a schematic view in which the display apparatus 100 in the middle of the manufacturing process is placed inside an evaporation apparatus including an evaporation source 137, a film material 121, and a magnet plate 136. The display apparatus 100 is placed such that the formation surface of the organic compound layer 112R faces downward. The display apparatus 100 in FIG. 33A corresponds to the manufacturing step in FIG. 32A, and FIG. 33A illustrates a schematic cross-sectional view of the display apparatus 100 along the cutting line A–B in FIG. 1A.

FIG. 33B illustrates a schematic view in which the display apparatus 100C in the middle of the manufacturing process is placed inside the evaporation apparatus including the evaporation source 137, the film material 121, and the magnet plate 136. The display apparatus 100C is placed such that the formation surface of the organic compound layer 112R faces downward. The display apparatus 100C in FIG. 33B corresponds to the manufacturing step in FIG. 13A. The display apparatus 100C has the pixel layout illustrated in FIG. 9A. Thus, in the schematic cross-sectional view of the display apparatus 100C in FIG. 33B, the shape of the partition 120 is changed to the shape illustrated in FIG. 2A and the like.

As illustrated in FIG. 33A, the evaporation source 137 is positioned at a distance TS from the pixel electrode 111 (specifically, the pixel electrode 111R, the pixel electrode 111G, and the pixel electrode 111B). In other words, the distance TS corresponds to a distance between the formation surface of the organic compound layer 112 (specifically, the organic compound layers 112R, 112G, and 112B) and the evaporation source 137. Here, the distance TS is approximately several tens of centimeters to one meter, which is sufficiently large with respect to the unevenness of the formation surface over the substrate 101. Note that the distance TS is sometimes regarded as a distance between the evaporation source 137 and the surface of the substrate 101 (the lower surface in FIG. 33A).

The film material 121 is vaporized and released (also referred to as scattered) by heating the evaporation source 137. Note that there is no particular limitation on the direction in which the film material is released (or scattered) from the evaporation source 137. Although the evaporation source 137 in FIG. 33A, for example, faces upward, the evaporation source 137 may face in any direction other than the upward direction, such as a lateral direction or a downward direction.

When the evaporation source 137 is moved relative to the substrate 101 without change in the distance TS, variation in deposition amount among different positions on the formation surface can be inhibited. A thin film with a uniform thickness can be formed all over a large-sized substrate by performing film formation while moving the evaporation source 137 relative to the substrate. Alternatively, the substrate 101 can be rotated or moved while the evaporation source is fixed. Either method enables formation of a thin film with a uniform thickness.

The film material 121 is deposited on the pixel electrode 111 surrounded by the partition 120 through the opening in the shadow mask 142R. Part of the film material 121 is deposited on the surface and the side surface of the shadow mask 142R.

Neither the organic compound layer 112Ra formed on the surface of the partition 120 nor an organic compound layer 112Rc formed on the surface of the shadow mask 142R and the side surface of the shadow mask 142R functions as the organic compound layer of the light-emitting device 110.

In the step of forming the organic compound layer 112R, the device formation surface (e.g., the transistor 150 and the pixel electrode 111) of the substrate 101 preferably faces downward, in the horizontal direction, or in a direction therebetween. Such a structure can inhibit unintentional deposition onto the formation surface during evaporation, enabling the display apparatus to have high reliability.

The magnet plate 136 is placed to face the shadow mask 142R with the substrate 101 therebetween. Accordingly, the shadow mask 142R is attracted to the magnet plate 136, whereby the shadow mask and the substrate can be brought into close contact. As a result, the shadow mask 142R does not warp or hardly warps; thus, the organic compound layer 112Ra can be inhibited from being formed in an unnecessary region.

The magnet plate 136 can hold the substrate 101 in addition to the shadow mask. Accordingly, in this embodiment, the formation surface over the substrate 101 can face downward. As a result, dust or the like is less likely to be attached to the substrate 101 during film formation, so that the display apparatus can have high reliability.

FIG. 33B illustrates a schematic cross-sectional view of the display apparatus 100C along the cutting line G–H in FIG. 9A. The display apparatus 100C can be formed without providing a shadow mask between the adjacent light-emitting devices that emit light of the same color. In other words, the shadow mask 142 (specifically, the shadow mask 142R) is not provided over the partition 120 between the light-emitting devices that emit light of the same color. Accordingly, the top surface of the partition 120 between the adjacent light-emitting devices that emit light of the same color is covered with the organic compound layer 112Ra.

Next, the positional relation between the display apparatus and the evaporation apparatus in the step of forming the upper electrode is described in this embodiment.

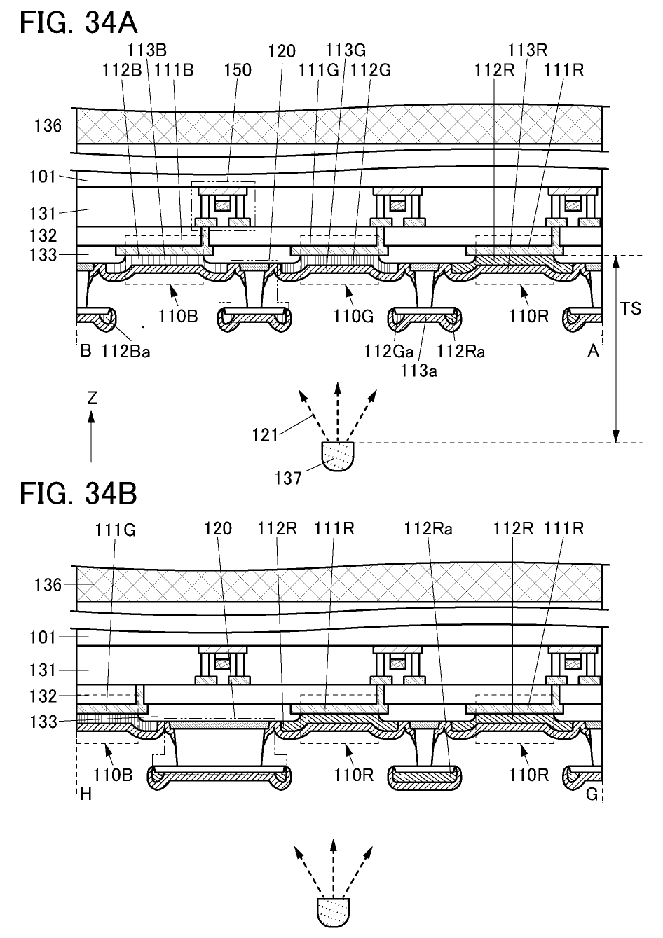

FIGS. 34A and 34B illustrate schematic cross-sectional views corresponding to the manufacturing step in FIG. 13A. FIG. 34A illustrates a schematic cross-sectional view of the display apparatus 100 along the cutting line A–B in FIG. 1A. FIG. 34B illustrates a schematic cross-sectional view of the display apparatus 100C along the cutting line G–H in FIG. 9A.

The description of FIGS. 33A and 33B can be referred to for the structure illustrated in FIG. 34A or 34B. Note that the structure illustrated in FIG. 34A or 34B is different from the structure illustrated in FIG. 33A in that, in the structure illustrated in FIG. 34A or 34B, a film (specifically, the upper electrode 113R, the upper electrode 113G, and the upper electrode 113B) can be formed in a pixel portion without using a fine metal mask.

In the pixel portion, the upper electrode 113 does not need to be separately patterned using a shadow mask. Meanwhile, outside the pixel portion, the upper electrode 113 is sometimes formed using a shadow mask for limiting the formation region. With use of the shadow mask, a region where the upper electrode 113 and the like are patterned can be provided in the vicinity of the pixel portion. Such a shadow mask is sometimes referred to as an area mask, a rough metal mask, or the like, for distinction from a metal mask, an FMM, or the like.

FIG. 34B illustrates an example where, in the display apparatus 100C, the width of the partition between the light-emitting devices that emit light of different colors is larger than the width of the partition between the light-emitting devices that emit light of the same color as in the case of the pixel arrangement illustrated in FIG. 9A.

The shadow mask 142R is not placed to overlap with the partition between the light-emitting devices that emit light of the same color. Thus, the organic compound layer 112Ra, the organic compound layer 112Ba, and the organic compound layer 112Ga (not illustrated) are formed over the top surface of the partition 120 (illustrated upside down in FIG. 34B).

Since the shadow mask 142 (specifically, the shadow mask 142R, the shadow mask 142G, and the shadow mask 142R) is placed over the partition between the light-emitting devices that emit light of different colors, the organic compound layer 112Ra or the like is sometimes not formed between the partition 120 and the layer 113a.

Through the above steps, the display apparatus 100 and the display apparatus 100C can be manufactured by a manufacturing method different from the above-described manufacturing method example 1 (i.e., by the manufacturing method example 2).

### [Example of film formation apparatus]

Described below are examples of film formation apparatuses capable of forming an organic compound layer, an upper electrode, and a protective layer successively without exposure to the air. The film formation apparatuses described below as examples can be used as manufacturing apparatuses for a display apparatus. The film formation apparatuses described below as examples can be used to form the organic compound layer 112, the upper electrode 113, and the protective layer 135 for each of the light-emitting devices 110.

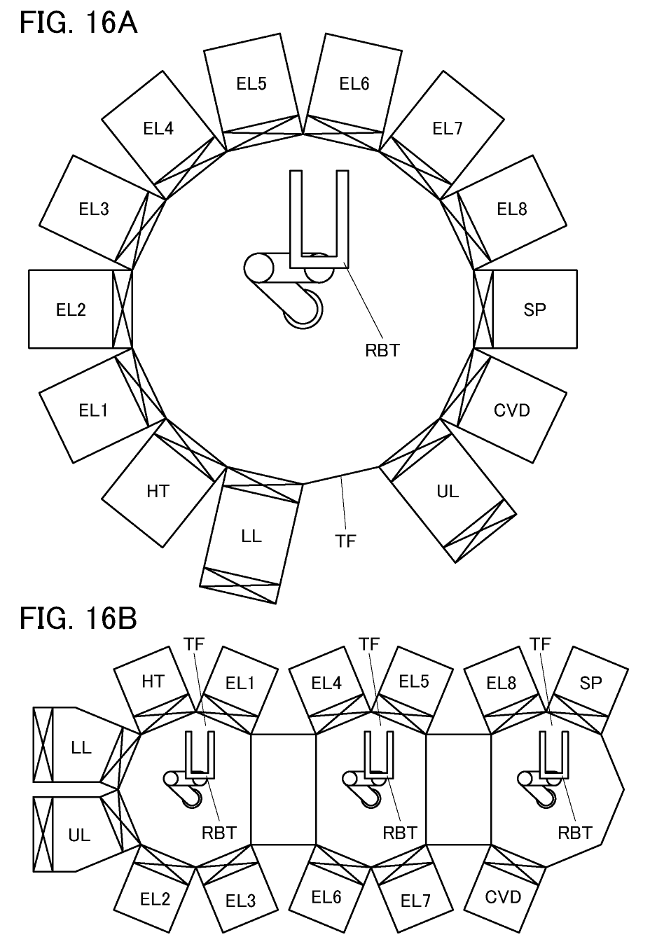

FIG. 16A is a schematic diagram of a film formation apparatus. The film formation apparatus includes a loading chamber LL, an unloading chamber UL, a treatment chamber HT, film formation chambers EL1 to EL8, a film formation chamber CVD, and a film formation chamber SP around a transfer chamber TF. The transfer chamber TF includes a transfer robot RBT, and the transfer robot RBT can load and unload the substrate 101 into and from each chamber.

The transfer chamber TF and each chamber are connected to a vacuum pump and are kept under reduced pressure. A gate valve is provided between the transfer chamber TF and each chamber to separately control the atmosphere, e.g., the pressure or the temperature, of each chamber.

The loading chamber LL is a chamber for loading the substrate 101, and the unloading chamber UL is a chamber for unloading the substrate 101. The loading chamber LL and the unloading chamber UL are each provided with a gate valve that connects to the outside.

In the treatment chamber HT, treatment for heating the substrate 101 can be performed. The treatment chamber HT includes a baking apparatus. For example, a hot-plate baking apparatus or a baking apparatus including a resistive heater or an infrared lamp may be used.

In the film formation chambers EL1 to EL8, films included in the organic compound layer 112 can be formed. The film formation chambers EL1 to EL8 each include a vacuum evaporation apparatus or a sputtering apparatus, for example.

For example, the film formation chamber EL1 includes an apparatus for forming a hole-injection layer; the film formation chamber EL2, a hole-transport layer; the film formation chamber EL3, an electron-blocking layer; the film formation chamber EL4, a light-emitting layer; the film formation chamber EL5, a hole-blocking layer; the film formation chamber EL6, an electron-transport layer; the film formation chamber EL7, an electron-injection layer; and the film formation chamber EL8, a charge-generation layer.

In the film formation chamber SP, the upper electrode 113 can be formed. For example, the film formation chamber SP includes a sputtering apparatus.

In the film formation chamber CVD, the protective layer 135 can be formed. For example, the film formation chamber CVD includes a PECVD apparatus.

Although FIG. 16A illustrates an example in which one transfer chamber TF is provided, a plurality of transfer chambers TF may be joined together. FIG. 16B illustrates an example in which three transfer chambers TF are joined. Each of the transfer chambers TF is provided with one transfer robot RBT. In the example illustrated in FIG. 16B, each of the transfer chambers TF can be connected to four to six chambers excluding the loading chamber LL and the unloading chamber UL. In FIG. 16B, up to three more chambers can be provided depending on the application.

Next, an example of a film formation method using either of the film formation apparatuses is described. First, the substrate 101 provided with components up to the partition 120 is loaded into the film formation apparatus from the loading chamber LL, and heat treatment is performed in the treatment chamber HT. Through this heat treatment, moisture or the like adsorbed on the surface can be removed. Next, the hole-injection layer, the hole-transport layer, the electron-blocking layer, the light-emitting layer, the hole-blocking layer, the electron-transport layer, and the electron-injection layer are sequentially formed in the film formation chambers EL1 to EL7. Next, the upper electrode is formed in the film formation chamber SP. Next, the protective layer 135 is formed in the film formation chamber CVD, and then the substrate 101 is unloaded to the outside from the unloading chamber UL. In the above manner, the organic compound layer 112, the upper electrode 113, and the protective layer 135 can be formed successively without exposure of the substrate 101 to the air.

The above-described film formation apparatus can also be used to form a light-emitting device having what is called a tandem structure, which includes a plurality of light-emitting layers with a charge-generation layer(s) therebetween.

First, as described above, after heat treatment is performed in the treatment chamber, the substrate 101 is sequentially transferred to the film formation chambers EL1 to EL7, so that hole-injection to electron-injection layers are sequentially formed. Next, a charge-generation layer is formed in the film formation chamber EL8. After that, hole-injection to electron-injection layers are sequentially formed again in the film formation chambers EL1 to EL7. Then, as described above, the upper electrode 113 is formed in the film formation chamber SP, the protective layer 135 is formed in the film formation chamber CVD, and the substrate 101 is unloaded from the unloading chamber UL. This makes it possible to manufacture a light-emitting device having a two-unit tandem structure in which the two light-emitting layers are stacked with the charge-generation layer therebetween.

In the film formation chamber EL8, at least one layer included in the charge-generation layer is formed. At least one of the electron-injection layer and the hole-injection layer formed before and after the film formation step in the film formation chamber EL8 can also serve as a layer included in the charge-generation layer. For example, in the case where the charge-generation layer has a stacked-layer structure of an electron-injection buffer layer, an electron-relay layer, and a p-type layer, the electron-injection layer may have a function of the electron-injection buffer layer, and the hole-injection layer may have a function of the p-type layer. In that case, the electron-relay layer may be formed in the film formation chamber EL8.

Note that a light-emitting device having an N-unit tandem structure (N is a natural number greater than or equal to 2) can be manufactured in such a manner that the film formation in the film formation chambers EL1 to EL8 is repeated N-1 times, the film formation in the film formation chamber EL8 is omitted for the last N-th time, and then the upper electrode 113 and the protective layer 135 are formed.

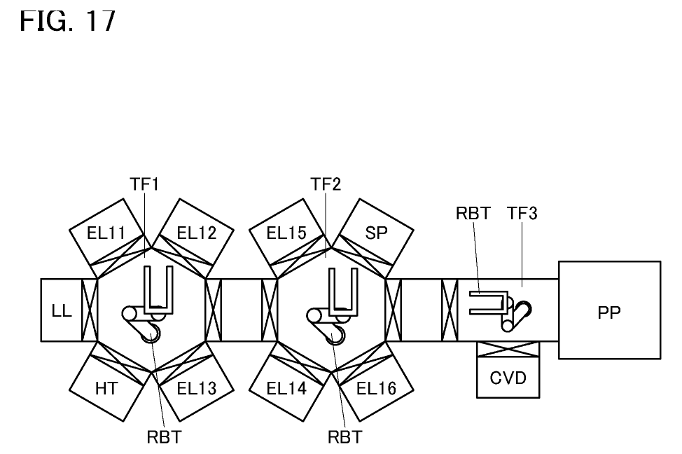

FIG. 17 illustrates a structure example of a film formation apparatus different from the above. The film formation apparatus illustrated in FIG. 17 has a structure in which three transfer chambers (a transfer chamber TF1, a transfer chamber TF2, and a transfer chamber TF3) are joined together.

The transfer chamber TF1 is connected to the loading chamber LL, three film formation chambers (a film formation chamber EL11, a film formation chamber EL12, and a film formation chamber EL13), and the treatment chamber HT. The transfer chamber TF2 is connected to four film formation chambers (a film formation chamber EL14, a film formation chamber EL15, a film formation chamber EL16, and the film formation chamber SP). The transfer chamber TF3 is connected to the film formation chamber CVD and a treatment chamber PP that performs later steps such as sealing. In the structure illustrated in FIG. 17, the loading chamber LL also serves as the unloading chamber, and a substrate can be loaded and unloaded through the loading chamber LL.

The film formation chambers EL11 to EL16 each include a vacuum evaporation apparatus, where an organic film or an inorganic film can be formed. The above description can be referred to for the film formation chamber SP, the film formation chamber CVD, the treatment chamber HT, and the like.

Here, the transfer chamber TF1 and the transfer chamber TF2 preferably have a reduced-pressure atmosphere. Meanwhile, the transfer chamber TF3 preferably has an atmospheric pressure atmosphere or a pressured (positive pressure) atmosphere. The inside of the transfer chamber TF3 is preferably kept in an atmosphere that contains an inert gas such as nitrogen or a noble gas as its main component and contains as little water as possible.

A sealing apparatus and the like included in the treatment chamber PP sometimes perform treatment in a reduced-pressure atmosphere; however, the treatment does not require a vacuum degree as high as that for a vacuum evaporation apparatus in some cases. For example, while the vacuum evaporation apparatus keeps pressure inside its chamber reduced and performs film formation treatment in a reduced-pressure atmosphere, the sealing apparatus and the like greatly change the pressure during the treatment in some cases. Thus, the transfer chamber TF3 does not need to have a reduced-pressure atmosphere. The inside of the transfer chamber TF3 is preferably kept under positive pressure, in which case entry of minute dust from the outside can be prevented and thus the inside can be kept clean. Furthermore, the transfer chamber TF1 and the transfer chamber TF2 each have a structure that can withstand a high vacuum degree by using a metal member for the exterior, for example. Meanwhile, the transfer chamber TF3 does not require high airtightness, and thus can be formed using a lightweight member such as an acrylic resin.

One or both of the treatment chamber PP and the transfer chamber TF3 may be provided with a mechanism for unloading the substrate. In that case, the substrate processed in the treatment chamber PP or the film formation chamber CVD does not need to be transferred to the transfer chamber TF1, the transfer chamber TF2, or the like having a reduced-pressure atmosphere again, so that the time for unloading the substrate can be shortened. At this time, it is preferable to use a container with high hermeticity, such as a front opening unified pod (FOUP) or a front opening shipping box (FOSB) for unloading the substrate, in which case the substrate can be transferred to an external apparatus without exposure to the air.

In the film formation apparatus illustrated in FIG. 17, the substrate is loaded from the loading chamber LL; heat treatment is performed in the treatment chamber HT; thin films included in the light-emitting device are formed in the film formation chambers connected to the transfer chamber TF1 and the transfer chamber TF2; the substrate is transferred to the transfer chamber TF3; and then a protective film can be formed in the film formation chamber CVD. Since the substrate is not exposed to the air until the end of the formation of the protective film in this manner, a light-emitting device with extremely high reliability can be manufactured. Furthermore, even after all the light-emitting devices are formed, processing can be successively performed without exposure of the substrate to the air between the step of forming the protective film in the film formation chamber CVD and the sealing step in the treatment chamber PP. This can prevent generation of a defect such as defective sealing due to dust and increase the manufacturing yield.

The above is the description of the film formation apparatuses and the film formation methods using the film formation apparatuses.

### Embodiment 2

In this embodiment, structure examples of the display apparatus of one embodiment of the present invention will be described.

The display apparatus in this embodiment can be a high-resolution display apparatus or a large-sized display apparatus. Accordingly, the display apparatus in this embodiment can be used for display portions of electronic appliances such as a digital camera, a digital video camera, a digital photo frame, a mobile phone, a portable game console, a smartphone, a wristwatch terminal, a tablet terminal, a portable information terminal, and an audio reproducing device, in addition to display portions of electronic appliances with a relatively large screen, such as a television apparatus, a desktop or laptop personal computer, a monitor of a computer or the like, digital signage, and a large game machine like a pachinko machine.

### Display apparatus 400A

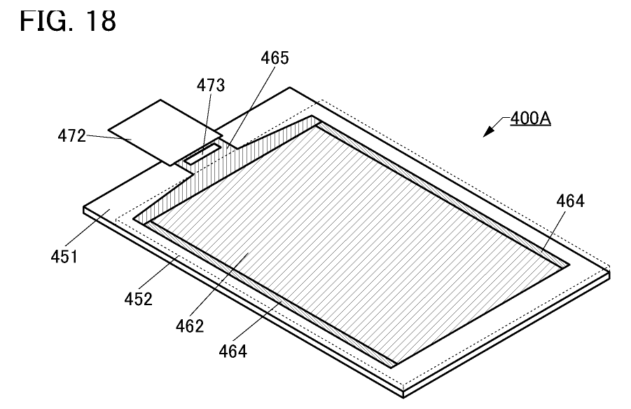

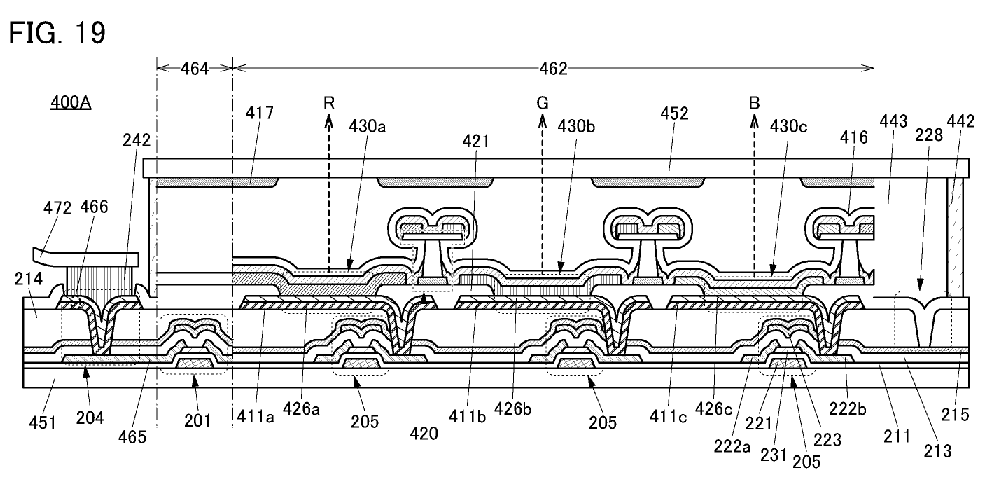

FIG. 18 is a perspective view of a display apparatus 400A, and FIG. 19 is a cross-sectional view of the display apparatus 400A.

In the display apparatus 400A, a substrate 452 and a substrate 451 are bonded to each other. In FIG. 18, the substrate 452 is denoted by a dashed line.

The display apparatus 400A includes a display portion 462, a circuit 464, a wiring 465, and the like. FIG. 18 illustrates an example where an integrated circuit (IC) 473 and an FPC 472 are mounted on the display apparatus 400A. Thus, the structure illustrated in FIG. 18 can be regarded as a display module including the display apparatus 400A, the IC, and the FPC.

As the circuit 464, a scan line driver circuit can be used, for example.

The wiring 465 has a function of supplying a signal and power to the display portion 462 and the circuit 464. The signal and power are input to the wiring 465 from the outside through the FPC 472 or input to the wiring 465 from the IC 473.

FIG. 18 illustrates an example where the IC 473 is provided over the substrate 451 by a chip on glass (COG) method, a chip on film (COF) method, or the like. An IC including a scan line driver circuit, a signal line driver circuit, or the like can be used as the IC 473, for example. Note that the display apparatus 400A and the display module are not necessarily provided with an IC. Alternatively, the IC may be mounted on the FPC by a COF method or the like.

FIG. 19 illustrates an example of cross sections of part of a region including the FPC 472, part of the circuit 464, part of the display portion 462, and part of a region including an end portion in the display apparatus 400A.

The display apparatus 400A illustrated in FIG. 19 includes a transistor 201, transistors 205, a light-emitting device 430a that emits red light, a light-emitting device 430b that emits green light, a light-emitting device 430c that emits blue light, and the like between the substrate 451 and the substrate 452.

The light-emitting devices described as an example in Embodiment 1 can be used as the light-emitting devices 430a, 430b, and 430c. The light-emitting devices 430 include a pixel electrode 411a, a pixel electrode 411b, a pixel electrode 411c, island-shaped organic compound layers including different light-emitting layers, and island-shaped upper electrodes.

In the case where a pixel of the display apparatus includes three kinds of subpixels including light-emitting devices that emit light of different colors, the three subpixels can be of three colors of R, G, and B or of three colors of yellow (Y), cyan (C), and magenta (M). In the case where four subpixels are included, the four subpixels can be of four colors of R, G, B, and white (W) or of four colors of R, G, B, and Y.

A protective layer 416 and the substrate 452 are bonded to each other with an adhesive layer 442. A solid sealing structure, a hollow sealing structure, or the like can be employed to seal the light-emitting devices. In FIG. 19, a hollow sealing structure is employed in which a space 443 surrounded by the substrate 452, the adhesive layer 442, and the substrate 451 is filled with an inert gas (e.g., nitrogen or argon). The adhesive layer 442 may overlap with the light-emitting device. The space 443 surrounded by the substrate 452, the adhesive layer 442, and the substrate 451 may be filled with a resin different from that of the adhesive layer 442.

The light-emitting devices 430a, 430b, and 430c each include an optical adjustment layer between the pixel electrode and the organic compound layer. The light-emitting device 430a includes an optical adjustment layer 426a, the light-emitting device 430b includes an optical adjustment layer 426b, and the light-emitting device 430c includes an optical adjustment layer 426c. Embodiment 1 can be referred to for the details of the light-emitting devices. The optical adjustment layers 426 have different thicknesses. The optical adjustment layers 426 preferably contain the same material having a light-transmitting property and conductivity. For the optical adjustment layers 426, a conductive metal oxide film containing indium or zinc is preferably used.

The pixel electrodes 411a, 411b, and 411c are each connected to a conductive layer 222b included in the transistor 205 through an opening provided in an insulating layer 213, an insulating layer 214, and an insulating layer 215.

End portions of the pixel electrodes and the optical adjustment layers are covered with an insulating layer 421. The pixel electrodes contain a material that reflects visible light, and the counter electrodes contain a material that transmits visible light.

Light emitted from the light-emitting devices is emitted to the substrate 452 side. For the substrate 452, a material having a high visible-light-transmitting property is preferably used.

A partition 420 is provided over the insulating layer 421. For the partition 420, the description of the partition 120 in Embodiment 1 can be referred to. The partition 420 is provided in a region overlapping with a light-blocking layer 417. Parts of upper electrodes of two light-emitting devices adjacent to each other with the partition 420 therebetween and layers containing the same materials as the organic compound layers are provided over the partition 420. The protective layer 416 is provided to cover the partition 420.

The transistor 201 and the transistors 205 are formed over the substrate 451. These transistors can be manufactured using the same materials through the same process.

An insulating layer 211, the insulating layer 213, the insulating layer 215, and the insulating layer 214 are provided in this order over the substrate 451. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

A material through which impurities such as water and hydrogen are less likely to diffuse is preferably used for at least one of the insulating layers covering the transistors. This is because such an insulating layer can function as a barrier layer. Such a structure can effectively inhibit diffusion of impurities into the transistors from the outside and improve the reliability of the display apparatus.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Two or more of the above insulating films may also be stacked.

Here, an organic insulating film often has a lower barrier property than an inorganic insulating film. Therefore, the organic insulating film preferably has an opening in the vicinity of the end portion of the display apparatus 400A. This can inhibit entry of impurities from the end portion of the display apparatus 400A through the organic insulating film. Alternatively, the organic insulating film may be formed such that its end portion is positioned inward from the end portion of the display apparatus 400A, to prevent the organic insulating film from being exposed at the end portion of the display apparatus 400A.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

In a region 228 illustrated in FIG. 19, an opening is formed in the insulating layer 214. This can inhibit entry of impurities into the display portion 462 from the outside through the insulating layer 214 even when an organic insulating film is used as the insulating layer 214. Consequently, the reliability of the display apparatus 400A can be increased.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is employed for each of the transistors 201 and 205. The two gates may be connected to each other and supplied with the same signal to drive the transistor. Alternatively, the threshold voltage of the transistor may be controlled by supplying a potential for controlling the threshold voltage to one of the two gates and supplying a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

It is preferable that a semiconductor layer of a transistor contain a metal oxide (also referred to as an oxide semiconductor). That is, a transistor containing a metal oxide in its channel formation region is preferably used in the display apparatus of this embodiment. Alternatively, the semiconductor layer of the transistor may contain silicon. Examples of silicon include amorphous silicon and crystalline silicon (e.g., low-temperature polysilicon or single crystal silicon).

The semiconductor layer preferably contains a metal oxide containing indium. In particular, the semiconductor layer preferably contains indium oxide.

The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer.

When the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide include In:M:Zn = 1:1:1, 1:1:1.2, 2:1:3, 3:1:2, 4:2:3, 4:2:4.1, 5:1:3, 5:1:6, 5:1:7, 5:1:8, 6:1:6, and 5:2:5 and an atomic ratio in the neighborhood thereof. Note that the neighborhood of the atomic ratio includes ±30 % of an intended atomic ratio.

For example, when the atomic ratio is described as In:Ga:Zn = 4:2:3 or being in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn = 5:1:6 or being in the neighborhood thereof, the case is included where the atomic proportion of Ga is greater than 0.5 and less than or equal to 2 and the atomic proportion of Zn is greater than or equal to 5 and less than or equal to 7 with the atomic proportion of In being 5. Furthermore, when the atomic ratio is described as In:Ga:Zn = 1:1:1 or being in the neighborhood thereof, the case is included where the atomic proportion of Ga is greater than 0.5 and less than or equal to 2 and the atomic proportion of Zn is greater than 0.1 and less than or equal to 2 with the atomic proportion of In being 1.

The transistor included in the circuit 464 and the transistors included in the display portion 462 may have the same structure or different structures. One structure or two or more kinds of structures may be employed for a plurality of transistors included in the circuit 464. Similarly, one structure or two or more kinds of structures may be employed for a plurality of transistors included in the display portion 462.

A connection portion 204 is provided in a region of the substrate 451 where the substrate 452 does not overlap. In the connection portion 204, the wiring 465 is electrically connected to the FPC 472 through a conductive layer 466 and a connection layer 242. An example is illustrated in which the conductive layer 466 has a stacked-layer structure of a conductive film obtained by processing the same conductive film as the pixel electrode and a conductive film obtained by processing the same conductive film as the optical adjustment layer. On the top surface of the connection portion 204, the conductive layer 466 is exposed. Thus, the connection portion 204 and the FPC 472 can be electrically connected to each other through the connection layer 242.

The light-blocking layer 417 is preferably provided on the surface of the substrate 452 on the substrate 451 side. A variety of optical members can be arranged on the outer surface of the substrate 452. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 452.

Providing the protective layer 416 that covers the light-emitting device can inhibit impurities such as water from entering the light-emitting device and increase the reliability of the light-emitting device.

In the region 228 in the vicinity of the end portion of the display apparatus 400A, the insulating layer 215 and the protective layer 416 are preferably in contact with each other through the opening in the insulating layer 214. In particular, the inorganic insulating film included in the insulating layer 215 and an inorganic insulating film included in the protective layer 416 are preferably in contact with each other. This can inhibit entry of impurities into the display portion 462 from the outside through the organic insulating film. Consequently, the reliability of the display apparatus 400A can be increased.

The protective layer 416 may have a stacked-layer structure of an organic insulating film and an inorganic insulating film. In that case, an end portion of the inorganic insulating film preferably extends beyond an end portion of the organic insulating film.

For each of the substrates 451 and 452, glass, quartz, ceramics, sapphire, a resin, a metal, an alloy, a semiconductor, or the like can be used. The substrate on the side from which light from the light-emitting device is extracted is formed using a material that transmits the light. When the substrates 451 and 452 are formed using a flexible material, the flexibility of the display apparatus can be increased. Furthermore, a polarizing plate may be used as the substrate 451 or the substrate 452.

For each of the substrates 451 and 452, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for one or both of the substrates 451 and 452.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display panel might be changed, e.g., creases are generated. Thus, as the substrate, a film with a low water absorption rate is preferably used. For example, the water absorption rate of the film is preferably 1 % or lower, further preferably 0.1 % or lower, still further preferably 0.01 % or lower.

The adhesive layer 442 can be formed using any of a variety of curable adhesives, e.g., a reactive curable adhesive, a thermosetting adhesive, an anaerobic adhesive, or a photocurable adhesive such as an ultraviolet curable adhesive. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component resin may be used. An adhesive sheet or the like may be used.

For the connection layer 242, an anisotropic conductive film (ACF), an anisotropic conductive paste (ACP), or the like can be used.

As materials for the gates, the source, and the drain of each transistor and conductive layers functioning as wirings and electrodes included in the display apparatus, any of metals such as aluminum, titanium, chromium, nickel, copper, yttrium, zirconium, molybdenum, silver, tantalum, and tungsten, or an alloy containing any of these metals as its main component can be used, for example. A single-layer structure or a stacked-layer structure including a film containing any of these materials can be used.

Examples of light-transmitting conductive materials include graphene and a conductive oxide such as indium oxide, indium tin oxide, indium zinc oxide, zinc oxide, or zinc oxide containing gallium. Other examples include a metal material such as gold, silver, platinum, magnesium, nickel, tungsten, chromium, molybdenum, iron, cobalt, copper, palladium, or titanium, and an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to transmit light. Alternatively, a stacked film of any of the above materials can be used for the conductive layers. For example, a stacked film of indium tin oxide and an alloy of silver and magnesium is preferably used because conductivity can be increased. These can also be used for conductive layers such as wirings and electrodes included in the display apparatus, and conductive layers (e.g., a conductive layer functioning as a pixel electrode or a common electrode) included in a light-emitting device.

Examples of insulating materials that can be used for the insulating layers include a resin such as an acrylic resin or an epoxy resin, and an inorganic insulating material such as silicon oxide, silicon oxynitride, silicon nitride oxide, silicon nitride, or aluminum oxide.

### Display apparatus 400B

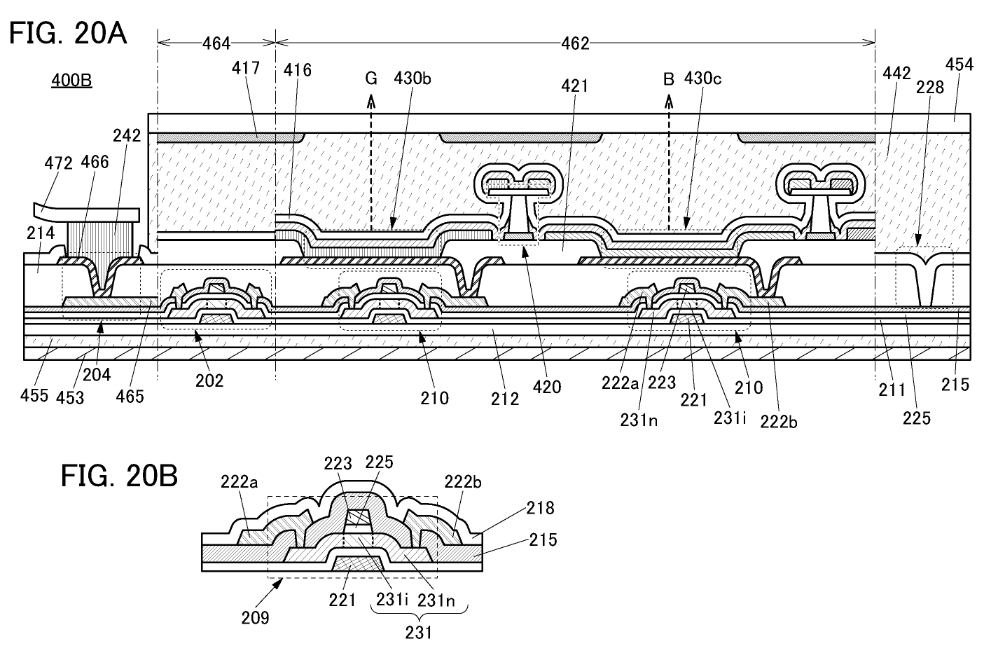

FIG. 20A is a cross-sectional view of a display apparatus 400B. A perspective view of the display apparatus 400B is similar to that of the display apparatus 400A (FIG. 18). FIG. 20A illustrates an example of cross sections of part of a region including the FPC 472, part of the circuit 464, and part of the display portion 462 in the display apparatus 400B. As for the display portion 462, FIG. 20A specifically illustrates an example of a cross section of a region including the light-emitting device 430b that emits green light and the light-emitting device 430c that emits blue light. Note that portions similar to those in the display apparatus 400A are not described in some cases.

The display apparatus 400B illustrated in FIG. 20A includes a transistor 202, transistors 210, the light-emitting device 430b, the light-emitting device 430c, and the like between a substrate 453 and a substrate 454.

The substrate 454 and the protective layer 416 are bonded to each other with the adhesive layer 442. The adhesive layer 442 is provided so as to overlap with the light-emitting devices 430b and 430c; that is, the display apparatus 400B employs a solid sealing structure.

The substrate 453 and an insulating layer 212 are bonded to each other with an adhesive layer 455.

As a method for manufacturing the display apparatus 400B, first, a formation substrate provided with the insulating layer 212, the transistors, the light-emitting devices, and the like and the substrate 454 provided with the light-blocking layer 417 are bonded to each other with the adhesive layer 442. Then, the substrate 453 is attached to a surface exposed by separation of the formation substrate, whereby the components formed over the formation substrate are transferred to the substrate 453. The substrates 453 and 454 are preferably flexible. Accordingly, the display apparatus 400B can be highly flexible.

The inorganic insulating film that can be used as each of the insulating layers 211, 213, and 215 can be used as the insulating layer 212.

The pixel electrode is connected to the conductive layer 222b included in the transistor 210 through an opening provided in the insulating layer 214. The conductive layer 222b is connected to a low-resistance region 231n through an opening provided in the insulating layer 215 and an insulating layer 225. The transistor 210 has a function of controlling the driving of the light-emitting device.

End portions of the pixel electrodes are covered with the insulating layer 421.

Light emitted from the light-emitting devices 430b and 430c is emitted to the substrate 454 side. For the substrate 454, a material having a high visible-light-transmitting property is preferably used.

The connection portion 204 is provided in a region of the substrate 453 where the substrate 454 does not overlap. In the connection portion 204, the wiring 465 is electrically connected to the FPC 472 through the conductive layer 466 and the connection layer 242. The conductive layer 466 can be obtained by processing the same conductive film as the pixel electrode. Thus, the connection portion 204 and the FPC 472 can be electrically connected to each other through the connection layer 242.

Each of the transistors 202 and 210 includes the conductive layer 221 functioning as a gate, the insulating layer 211 functioning as a gate insulating layer, a semiconductor layer including a channel formation region 231i and a pair of low-resistance regions 231n, the conductive layer 222a connected to one of the low-resistance regions 231n, the conductive layer 222b connected to the other low-resistance region 231n, the insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the corresponding low-resistance regions 231n through openings provided in the insulating layer 215. One of the conductive layers 222a and 222b functions as a source, and the other functions as a drain.

FIG. 20A illustrates an example where the insulating layer 225 covers the top and side surfaces of the semiconductor layer. The conductive layer 222a and the conductive layer 222b are connected to the corresponding low-resistance regions 231n through the openings provided in the insulating layer 225 and the insulating layer 215.

In a transistor 209 illustrated in FIG. 20B, the insulating layer 225 overlaps with the channel formation region 231i of the semiconductor layer 231 and does not overlap with the low-resistance regions 231n. The structure illustrated in FIG. 20B is obtained by processing the insulating layer 225 with the conductive layer 223 as a mask, for example. In FIG. 20B, the insulating layer 215 is provided to cover the insulating layer 225 and the conductive layer 223, and the conductive layer 222a and the conductive layer 222b are connected to the low-resistance regions 231n through the openings in the insulating layer 215. Furthermore, an insulating layer 218 covering the transistor may be provided.

At least part of any of the structure examples, the drawings corresponding thereto, and the like described in this embodiment can be combined with any of the other structure examples, the other drawings corresponding thereto, and the like as appropriate.

At least part of this embodiment can be implemented as appropriate in combination with any of the other embodiments described in this specification.

(Embodiment 3)

In this embodiment, a structure example of a display apparatus different from the above will be described.

The display apparatus in this embodiment can be a high-resolution display apparatus. Thus, the display apparatus in this embodiment can be used for display portions of information terminals (wearable devices) such as watch-type or bracelet-type information terminals and display portions of wearable devices capable of being worn on a head, such as a VR device like a head-mounted display and a glasses-type AR device.

### [Display module]

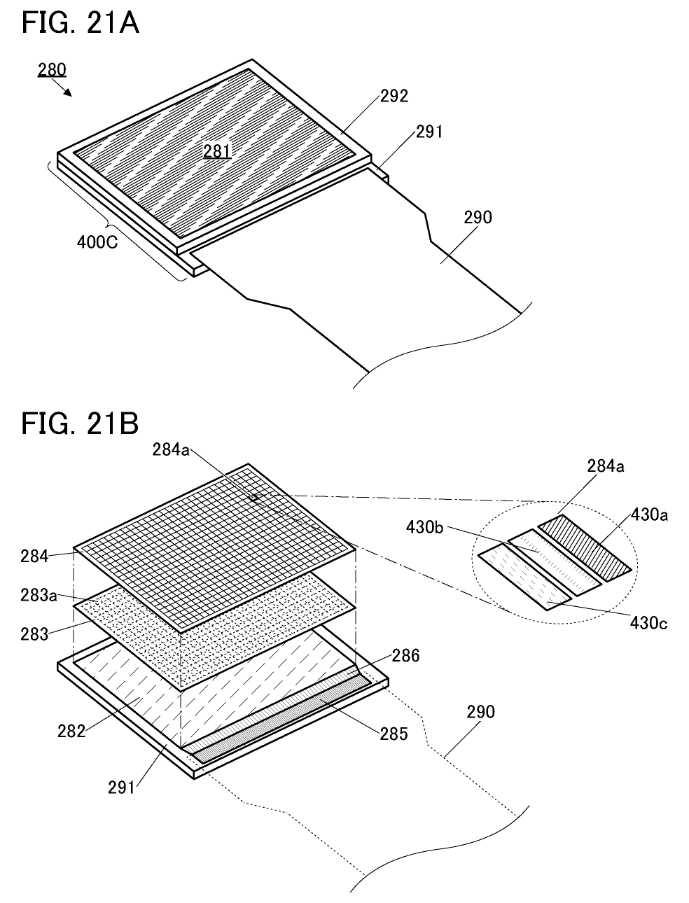

FIG. 21A is a perspective view of a display module 280. The display module 280 includes a display apparatus 400C and an FPC 290. Note that the display apparatus included in the display module 280 is not limited to the display apparatus 400C and may be a display apparatus 400D or a display apparatus 400E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 21B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 21B. The pixel 284a includes the light-emitting devices 430a, 430b, and 430c that emit light of different colors. The plurality of light-emitting devices may be arranged in a stripe pattern as illustrated in FIG. 21B. With the stripe pattern that enables high-density arrangement of pixel circuits, a high-resolution display apparatus can be provided. Alternatively, a variety of kinds of patterns such as a delta pattern or a pentile pattern can be employed.

The pixel circuit portion 283 includes a plurality of pixel circuits 283a arranged periodically.

One pixel circuit 283a is a circuit that controls light emission of three light-emitting devices included in one pixel 284a. One pixel circuit 283a may be provided with three circuits each of which controls light emission of one light-emitting device. For example, the pixel circuit 283a can include at least one selection transistor, one current control transistor (driving transistor), and a capacitor for one light-emitting device. A gate signal is input to a gate of the selection transistor, and a source signal is input to one of a source and a drain of the selection transistor. Thus, an active-matrix display apparatus is obtained.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure where one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40 % and lower than 100 %, preferably higher than or equal to 50 % and lower than or equal to 95 %, further preferably higher than or equal to 60 % and lower than or equal to 95 %. Furthermore, the pixels 284a can be arranged extremely densely and thus the display portion 281 can have significantly high pixel density. For example, the pixels 284a are preferably arranged in the display portion 281 with a pixel density higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a device for VR such as a head-mounted display or a glasses-type device for AR. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion. For example, the display module 280 can be suitably used in a display portion of a wearable electronic appliance, such as a wrist watch.

### Display apparatus 400C

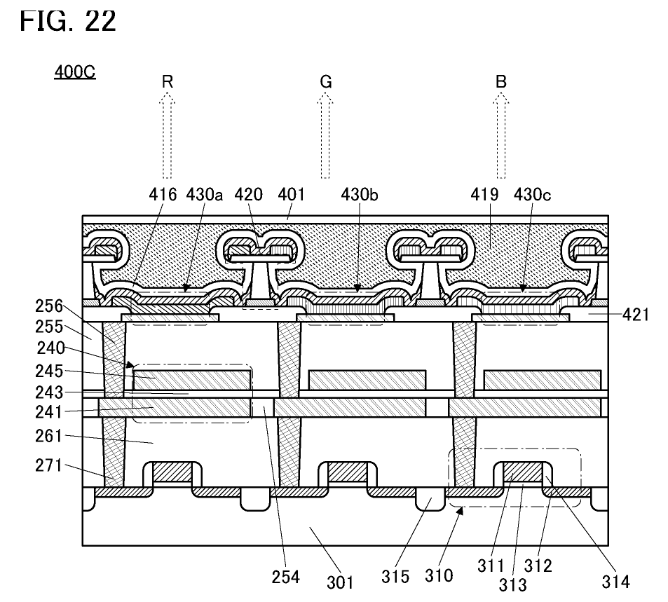

The display apparatus 400C illustrated in FIG. 22 includes a substrate 301, the light-emitting devices 430a, 430b, and 430c, a capacitor 240, and a transistor 310.

The substrate 301 corresponds to the substrate 291 in FIGS. 21A and 21B.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, and the light-emitting devices 430a, 430b, and 430c and the like are provided over the insulating layer 255. The protective layer 416 is provided over the light-emitting devices 430a, 430b, and 430c, and a substrate 401 is bonded to a top surface of the protective layer 416 with a resin layer 419. The substrate 401 corresponds to the substrate 292 in FIG. 21A.

The pixel electrode of the light-emitting device is electrically connected to the one of the source and the drain of the transistor 310 through a plug 256 embedded in the insulating layer 255, the conductive layer 241 embedded in the insulating layer 254, and the plug 271 embedded in the insulating layer 261.

The insulating layer 421 is provided to cover the end portions of the pixel electrodes. An inorganic insulating material is preferably used for the insulating layer 421. For example, an inorganic insulating material such as silicon oxide, silicon nitride, or aluminum oxide can be used.

The partition 420 is provided over the insulating layer 421. For the partition 420, the description of the partition 120 in Embodiment 1 can be referred to. Parts of upper electrodes of two light-emitting devices adjacent to each other with the partition 420 therebetween and layers containing the same materials as the organic compound layers are provided over the partition 420.

### Display apparatus 400D

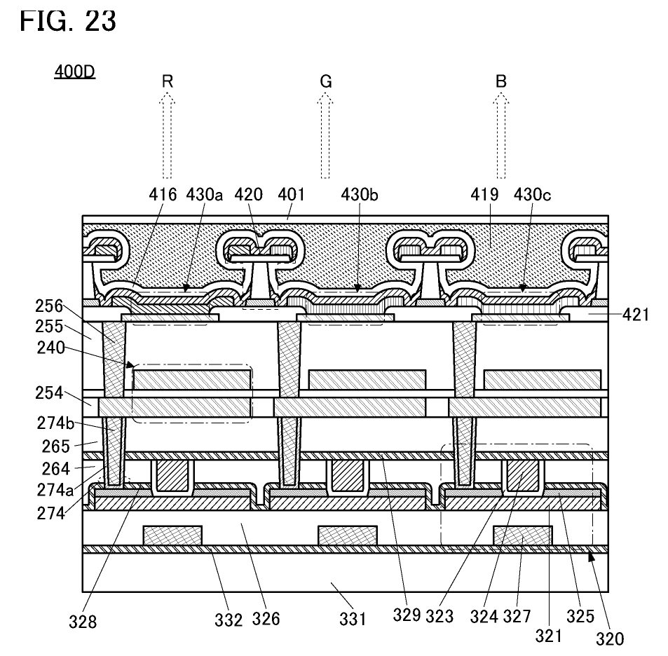

The display apparatus 400D illustrated in FIG. 23 differs from the display apparatus 400C mainly in transistor structure. Note that portions similar to those in the display apparatus 400C are not described in some cases.

A transistor 320 contains a metal oxide (also referred to as an oxide semiconductor) in a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 illustrated in FIGS. 21A and 21B. As the substrate 331, an insulating substrate or a semiconductor substrate can be used.

An insulating layer 332 is provided over the substrate 331. The insulating layer 332 functions as a barrier layer that inhibits diffusion of impurities such as water or hydrogen from the substrate 331 into the transistor 320 and prevents release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327 and the insulating layer 332. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 which is in contact with the semiconductor layer 321. The top surface of the insulating layer 326 is preferably planarized.

The semiconductor layer 321 is provided over the insulating layer 326. A metal oxide film having semiconductor characteristics (also referred to as an oxide semiconductor film) is preferably used for the semiconductor layer 321. A material that can be used for the semiconductor layer 321 is described in detail later.

The pair of conductive layers 325 is provided over and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that inhibits diffusion of impurities such as water or hydrogen from the insulating layer 264 and the like into the semiconductor layer 321 and prevents release of oxygen from the semiconductor layer 321. As the insulating layer 328, an insulating film similar to the insulating layer 332 can be used.

An opening reaching the semiconductor layer 321 is provided in the conductive layer 325 and the insulating layers 328 and 264, and the insulating layer 323 and the conductive layer 324 are provided to fill the inside of the opening. The insulating layer 323 is provided in contact with the side surfaces of the insulating layers 264 and 328 and the conductive layer 325 and the top surface of the semiconductor layer 321. The conductive layer 324 is provided in contact with the top and side surfaces of the insulating layer 323. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are substantially level with each other, and an insulating layer 329 and an insulating layer 265 are provided to cover these layers.

The insulating layers 264 and 265 each function as an interlayer insulating layer. The insulating layer 329 functions as a barrier layer that inhibits diffusion of impurities such as water or hydrogen from the insulating layer 265 or the like into the transistor 320. As the insulating layer 329, an insulating film similar to the insulating layers 328 and 332 can be used.

A plug 274 electrically connecting one electrode of the capacitor 240 and one of the pair of conductive layers 325 to each other is provided to fill an opening in the insulating layers 265, 329, 264, and 328. Here, the plug 274 preferably includes a conductive layer 274a and a conductive layer 274b. The conductive layer 274a is provided in contact with the side surface of the opening in the insulating layers 265, 329, 264, and 328 and in contact with the top surface of the conductive layer 325. The conductive layer 274b is provided in contact with the top and side surfaces of the conductive layer 274a. For the conductive layer 274a, a conductive material in which hydrogen and oxygen are less likely to diffuse is preferably used.

Components from the insulating layer 254 to the substrate 401 in the display apparatus 400D are similar to those in the display apparatus 400C.

### Display apparatus 400E

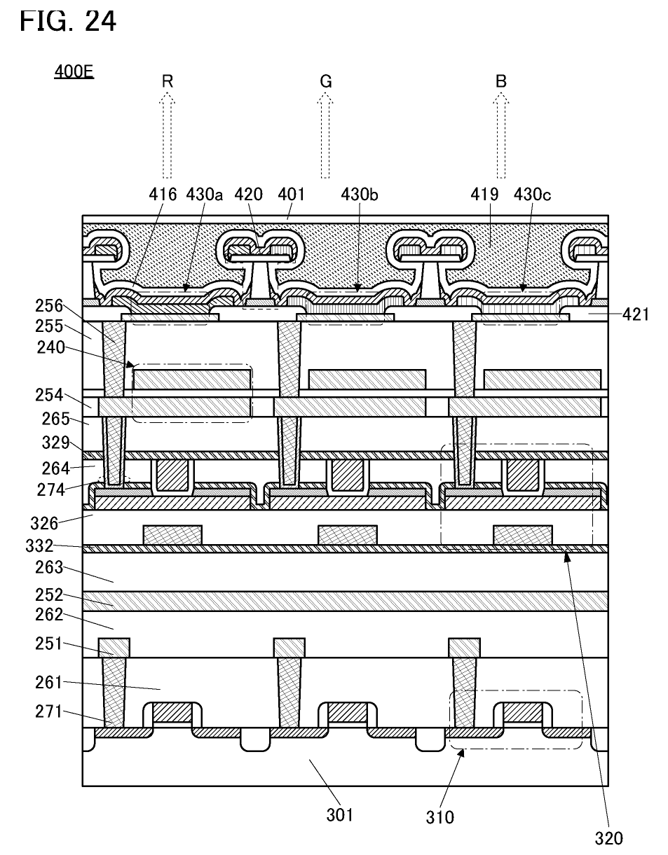

The display apparatus 400E illustrated in FIG. 24 has a structure in which the transistor 310 whose channel is formed in the substrate 301 and the transistor 320 containing a metal oxide in the semiconductor layer where the channel is formed are stacked. Note that portions similar to those in the display apparatuses 400C and 400D are not described in some cases.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layers 251 and 252 each function as a wiring. An insulating layer 263 is provided to cover the conductive layer 252, the insulating layer 332 is provided over the insulating layer 263, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistors 310 and 320 can also be used as transistors included in a variety of circuits such as an arithmetic circuit and a memory circuit.

With such a structure, not only the pixel circuit but also the driver circuit or the like can be formed directly under the light-emitting device; thus, the display apparatus can be downsized as compared with the case where the driver circuit is provided around a display region.

### Display apparatus 400F

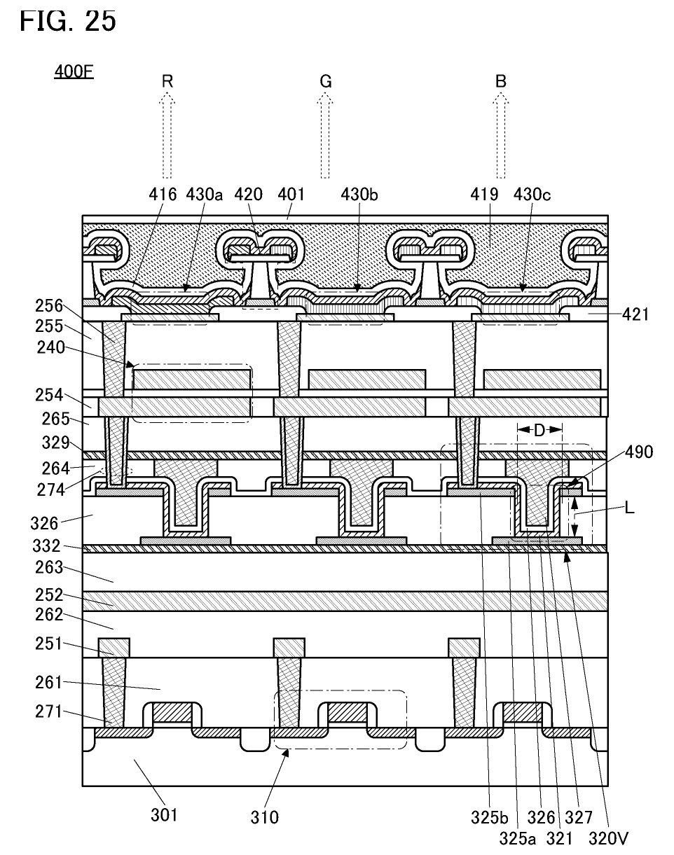

A display apparatus 400F illustrated in FIG. 25 has a structure in which the transistor 310 whose channel is formed in the substrate 301 and a transistor 320V containing a metal oxide in a semiconductor layer where the channel is formed are stacked. Note that portions similar to those in the display apparatuses 400C, 400D, and 400E are not described in some cases.

In FIG. 25, the transistor 320V includes the conductive layer 327 functioning as a first gate electrode, the insulating layer 326 functioning as a first gate insulating layer, the semiconductor layer 321, and conductive layers 325a and 325b. The conductive layer 325a functions as one of a source electrode and a drain electrode, and the conductive layer 325b functions as the other of the source electrode and the drain electrode. A metal oxide can be suitably used for the semiconductor layer 321, for example.

The conductive layer 325a is provided over the insulating layer 332, the insulating layer 326 is provided to cover the conductive layer 325a and the insulating layer 332, and the conductive layer 325b is provided over the insulating layer 326. The conductive layer 325b and the insulating layer 326 include an opening portion 490 reaching the conductive layer 325a. The semiconductor layer 321 is provided to cover the opening portion 490 and is in contact with the conductive layer 325a in the opening portion 490. The semiconductor layer 321 is in contact with the side surface of the insulating layer 326 and the side surface of the conductive layer 325b. Furthermore, the semiconductor layer 321 is preferably in contact with the top surface of the conductive layer 325b. In the semiconductor layer 321, the region in contact with the conductive layer 325a functions as one of a source region and a drain region, and the region in contact with the conductive layer 325b functions as the other of the source region and the drain region. In the semiconductor layer 321, the channel formation region is positioned between the source region and the drain region. The insulating layer 326 is provided over the semiconductor layer 321, and the conductive layer 327 is provided over the insulating layer 326. The conductive layer 327 includes a region overlapping with the semiconductor layer 321 with the insulating layer 326 therebetween in the opening portion 490.

As the insulating layer 326, an inorganic insulating film such as an oxide insulating film, a nitride insulating film, an oxynitride insulating film, or a nitride oxide insulating film can be suitably used. For example, one or more of a silicon oxide film, a silicon oxynitride film, an aluminum oxide film, a silicon nitride film, and a silicon nitride oxide film can be suitably used as the insulating layer 326.

In the transistor 320V, the source electrode and the drain electrode are positioned at different levels (for example, at levels in the direction perpendicular to the substrate surface or the insulating plane over which the transistor is provided) with respect to the surface over which the transistor is formed (here, the top surface of the insulating layer 332), and thus a drain current flows in a direction perpendicular or substantially perpendicular to the top surface of the insulating layer 332. In other words, the channel length direction can be regarded as including a height (vertical) component; therefore, the transistor 320V can also be referred to as a vertical field-effect transistor (VFET), a vertical transistor, a vertical-channel transistor, a vertical-channel-type transistor, or the like.

A channel length L of the transistor 320V can be controlled by the thickness of an insulating layer (here, the insulating layer 326) sandwiched between the source electrode and the drain electrode. Thus, the transistor 320V having a channel length L (e.g., less than or equal to 60 nm, less than or equal to 50 nm, less than or equal to 40 nm, less than or equal to 30 nm, less than or equal to 20 nm, or less than or equal to 10 nm and greater than or equal to 1 nm or greater than or equal to 5 nm) that is shorter than the minimum exposure size of a light-exposure apparatus used for manufacturing the transistor can be manufactured with high accuracy. When the channel length L of the transistor 320V is shortened, the on-state current thereof can be increased. Accordingly, a display apparatus with high-speed operation can be obtained.

In the transistor 320V, the source electrode, the semiconductor layer, and the drain electrode are provided to overlap with each other. Thus, the area occupied by the transistor 320V can be significantly reduced as compared with a so-called planar transistor in which the source electrode, the semiconductor layer, and the drain electrode are arranged in a planar shape. When a VFET is used for the pixel circuit of the display apparatus, the area occupied by the pixel circuit can be reduced, so that a high-resolution display apparatus can be obtained.

When the opening portion 490 in the transistor 320V is formed to be circular or substantially circular in the top view, the semiconductor layer 321, the insulating layer 326, and the conductive layer 327 are concentrically provided. This makes the distance between the conductive layer 327 and the semiconductor layer 321 substantially uniform, so that a gate electric field can be substantially uniformly applied to the semiconductor layer 321.

The side surface of the conductive layer 327 faces the side surface of the semiconductor layer 321 with the insulating layer 326 therebetween. That is, in the top view, the entire perimeter of the semiconductor layer 321 serves as the channel formation region. In this case, for example, a channel width W of the transistor 320V is determined by the length of the outer perimeter of the semiconductor layer 321. In other words, the channel width W of the transistor 320V is determined by the maximum width of the opening portion 490 (the maximum diameter in the case where the opening portion 490 is circular in the top view). In the case where the opening portion 490 is circular in the top view, the maximum width D of the opening portion 490 corresponds to the diameter of the opening portion 490, and the channel width W can be "D × π".

In the case where the opening portion 490 is formed by a photolithography method, the maximum width D of the opening portion 490 is greater than or equal to the minimum exposure size of a light-exposure apparatus. In addition, the maximum width D of the opening portion 490 is determined by the thicknesses of the semiconductor layer 321, the insulating layer 326, and the conductive layer 327 provided in the opening portion 490. The maximum width D of the opening portion 490 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm.

Note that the structure of the transistor 320V described here can also be applied to other structure examples.

At least part of any of the structure examples, the drawings corresponding thereto, and the like described in this embodiment can be combined with any of the other structure examples, the other drawings corresponding thereto, and the like as appropriate.

At least part of this embodiment can be implemented as appropriate in combination with any of the other embodiments described in this specification.

### Embodiment 4

In this embodiment, a light-emitting device that can be used in the display apparatus of one embodiment of the present invention will be described.

In this specification and the like, a light-emitting device includes an organic compound layer between a pair of electrodes. The organic compound layer includes at least a light-emitting layer. Examples of layers (also referred to as functional layers) in the organic compound layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a structure in which light-emitting layers in light-emitting devices of different colors (here, blue (B), green (G), and red (R)) are separately formed or separately patterned may be referred to as a side-by-side (SBS) structure. The SBS structure can optimize materials and structures of light-emitting devices and thus can extend the freedom of choices of materials and structures, whereby the luminance and the reliability can be easily improved. In this specification and the like, a light-emitting device capable of emitting white light may be referred to as a white-light-emitting device. Note that a combination of white light-emitting devices with coloring layers (e.g., color filters) enables a full-color display apparatus.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases.

### Light-emitting device

Structures of light-emitting devices can be classified roughly into a single structure and a tandem structure. A light-emitting device having a single structure includes one light-emitting unit between a pair of electrodes. The light-emitting unit includes one or more light-emitting layers. To obtain white light emission with a single structure, two or more light-emitting layers are preferably selected such that emission of the light-emitting layers can produce white color. For example, in the case of two colors, when emission colors of a first light-emitting layer and a second light-emitting layer are complementary colors, the light-emitting device can be configured to emit white light as a whole. To obtain white light emission by using three or more light-emitting layers, the light-emitting device can be configured to emit white light as a whole by combining emission colors of the three or more light-emitting layers.

A light-emitting device having a tandem structure includes a plurality of light-emitting units between a pair of electrodes. Each light-emitting unit includes one or more light-emitting layers. When light-emitting layers that emit light of the same color are used in each light-emitting unit, luminance per predetermined current can be increased, and the light-emitting device can have higher reliability than that with a single structure. To obtain white light emission with a tandem structure, the light-emitting device is preferably configured to emit white light by combining light from light-emitting layers of a plurality of light-emitting units. Note that a combination of emission colors for obtaining white light emission is similar to that for a single structure. In the light-emitting device with a tandem structure, it is preferable that an intermediate layer such as a charge-generation layer be provided between the plurality of light-emitting units.

When a white-light-emitting device and a light-emitting device with an SBS structure are compared to each other, the latter can have lower power consumption than the former. Meanwhile, the white-light-emitting device is preferable in terms of lower manufacturing cost and higher manufacturing yield because the manufacturing process of the white-light-emitting device is simpler than that of the light-emitting device with the SBS structure.

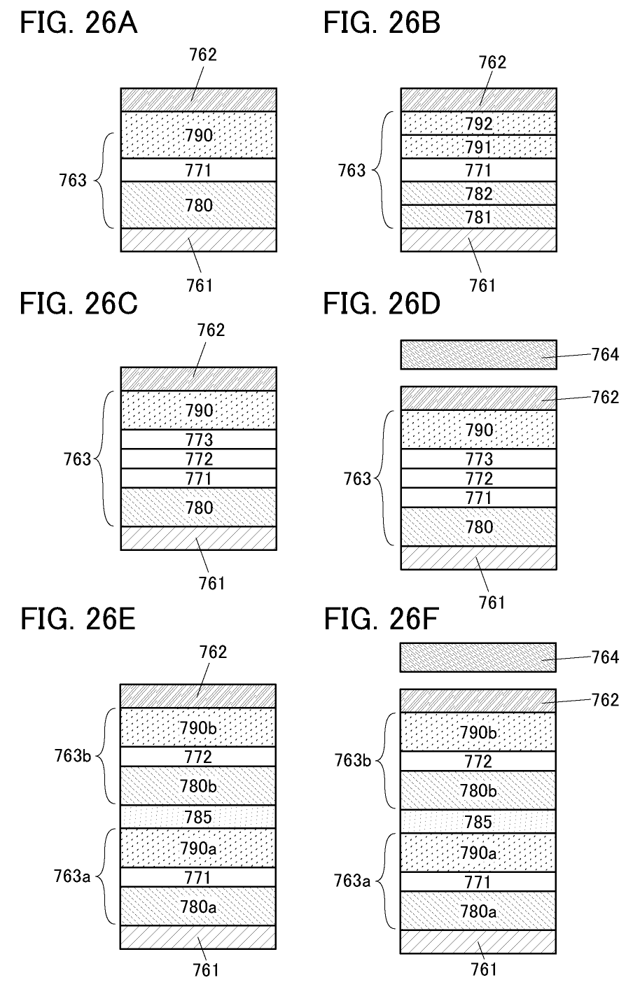

As illustrated in FIG. 26A, the light-emitting device includes an organic compound layer 763 between a pair of electrodes (a lower electrode 761 and an upper electrode 762). The organic compound layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (hole-injection layer), a layer containing a substance having a high hole-transport property (hole-transport layer), and a layer containing a substance having a high electron-blocking property (electron-blocking layer). Furthermore, the layer 790 includes one or more of a layer containing a substance having a high electron-injection property (electron-injection layer), a layer containing a substance having a high electron-transport property (electron-transport layer), and a layer containing a substance having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 26A is referred to as a single structure in this specification.

FIG. 26B is a modification example of the organic compound layer 763 included in the light-emitting device illustrated in FIG. 26A. Specifically, the light-emitting device illustrated in FIG. 26B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected into the light-emitting layer 771, and the efficiency of the recombination of carriers in the light-emitting layer 771 can be enhanced.

Note that structures in which a plurality of light-emitting layers (the light-emitting layer 771 and light-emitting layers 772 and 773) are provided between the layer 780 and the layer 790 as illustrated in FIGS. 26C and 26D are variations of a single structure. Although FIGS. 26C and 26D each illustrate an example in which three light-emitting layers are included, the number of light-emitting layers in a light-emitting device with a single structure may be two or four or more.

In addition, the light-emitting device with a single structure may include a buffer layer between two light-emitting layers.

A structure in which a plurality of light-emitting units (a light-emitting unit 763a and a light-emitting unit 763b) are connected in series through a charge-generation layer 785 (also referred to as an intermediate layer) as illustrated in FIGS. 26E and 26F is referred to as a tandem structure in this specification. The tandem structure can be referred to as a stack structure. The tandem structure enables a light-emitting device to emit light with high luminance. Furthermore, the amount of current needed for obtaining a predetermined luminance can be smaller in the tandem structure than in the single structure; thus, the tandem structure enables higher reliability.

Note that FIGS. 26D and 26F each illustrate an example in which the display apparatus includes a layer 764 overlapping with the light-emitting device. FIG. 26D is an example in which the layer 764 overlaps with the light-emitting device illustrated in FIG. 26C, and FIG. 26F illustrates an example in which the layer 764 overlaps with the light-emitting device illustrated in FIG. 26E. In FIGS. 26D and 26F, a conductive film that transmits visible light is used for the upper electrode 762 so that light is extracted from the upper electrode 762 side.

One or both of a color conversion layer and a color filter (coloring layer) can be used as the layer 764.

In FIGS. 26C and 26D, light-emitting substances that emit light of the same color or the same light-emitting substance may be used for the light-emitting layers 771, 772, and 773. For example, a light-emitting substance that emits blue light may be used for the light-emitting layers 771, 772, and 773. In a subpixel that exhibits blue light, blue light from the light-emitting device can be extracted as it is. In a subpixel that exhibits red light and a subpixel that exhibits green light, respective color conversion layers are provided as the layer 764 illustrated in FIG. 26D, whereby blue light emitted by light-emitting devices can be converted into light with a longer wavelength and thus red light or green light can be extracted. As the layer 764, both a color conversion layer and a coloring layer are preferably used. In some cases, part of light emitted from the light-emitting device is transmitted through the color conversion layer without being converted. When light passing through the color conversion layer is extracted through the coloring layer, light other than light of a desired color can be absorbed by the coloring layer, and color purity of light exhibited by a subpixel can be improved.

In FIGS. 26C and 26D, light-emitting substances that emit light of different colors may be used for the light-emitting layers 771, 772, and 773. White light emission can be achieved when the light-emitting layers 771, 772, and 773 are selected such that emission of the light-emitting layers can produce white color. The light-emitting device with a single structure preferably includes a light-emitting layer containing a light-emitting substance that emits blue light and a light-emitting layer containing a light-emitting substance that emits visible light with a longer wavelength than blue light, for example.

A color filter may be provided as the layer 764 illustrated in FIG. 26D. When white light passes through a color filter, light of a desired color can be obtained.

In the case where the light-emitting device with a single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be RGB or RBG from an anode side, for example. In that case, a buffer layer may be provided between R and G or between R and B.

In the case where the light-emitting device with a single structure includes two light-emitting layers, for example, a light-emitting layer containing a light-emitting substance that emits blue (B) light and a light-emitting layer containing a light-emitting substance that emits yellow (Y) light are preferably included. Such a structure may be referred to as a BY single structure.

A light-emitting device that emits white light preferably contains two or more kinds of light-emitting substances. In order to obtain white light, two or more light-emitting substances are preferably selected such that emission of the light-emitting substances can produce white color. For example, when emission colors of a first light-emitting layer and a second light-emitting layer are complementary colors, the light-emitting device can emit white light as a whole. To obtain white light emission by using three or more light-emitting layers, the light-emitting device can be configured to emit white light as a whole by combining emission colors of the three or more light-emitting layers.

In FIGS. 26C and 26D, the layers 780 and 790 may each have a stacked-layer structure of two or more layers as illustrated in FIG. 26B.

In FIGS. 26E and 26F, light-emitting substances that emit light of the same color, or moreover, the same light-emitting substance may be used for the light-emitting layers 771 and 772. For example, in light-emitting devices included in subpixels that exhibit light of different colors, a light-emitting substance that emits blue light can be used for each of the light-emitting layers 771 and 772. In a subpixel that exhibits blue light, blue light from the light-emitting device can be extracted as it is. In each of the subpixel that exhibits red light and the subpixel that exhibits green light, a color conversion layer is provided as the layer 764 illustrated in FIG. 26F for converting blue light from the light-emitting device into light with a longer wavelength, so that red light or green light can be extracted. As the layer 764, both a color conversion layer and a coloring layer are preferably used.

In FIGS. 26E and 26F, light-emitting substances that emit light of different colors may be used for the light-emitting layers 771 and 772. When the light-emitting layers 771 and 772 emit light of complementary colors, white light emission can be obtained. As the layer 764 illustrated in FIG. 26F, a color filter may be provided. When white light passes through a color filter, light of a desired color can be obtained.

Although FIGS. 26E and 26F each illustrate an example in which the light-emitting unit 763a includes one light-emitting layer 771 and the light-emitting unit 763b includes one light-emitting layer 772, one embodiment of the present invention is not limited thereto. Each of the light-emitting units 763a and 763b may include two or more light-emitting layers.

Although FIGS. 26E and 26F each illustrate an example of a light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In each of FIGS. 26E and 26F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layers 780a and 780b each include one or more of a hole-injection layer, a hole-transport layer, and an electron-blocking layer. Furthermore, the layers 790a and 790b each include one or more of an electron-injection layer, an electron-transport layer, and a hole-blocking layer. In the case where the lower electrode 761 is a cathode and the upper electrode 762 is an anode, the structures of the layers 780a and 790a are interchanged and the structures of the layers 780b and 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing the light-emitting device with a tandem structure, two light-emitting units are stacked with the charge-generation layer 785 therebetween. The charge-generation layer 785 has a function of injecting electrons into one of the two light-emitting units and injecting holes into the other when voltage is applied between the pair of electrodes.

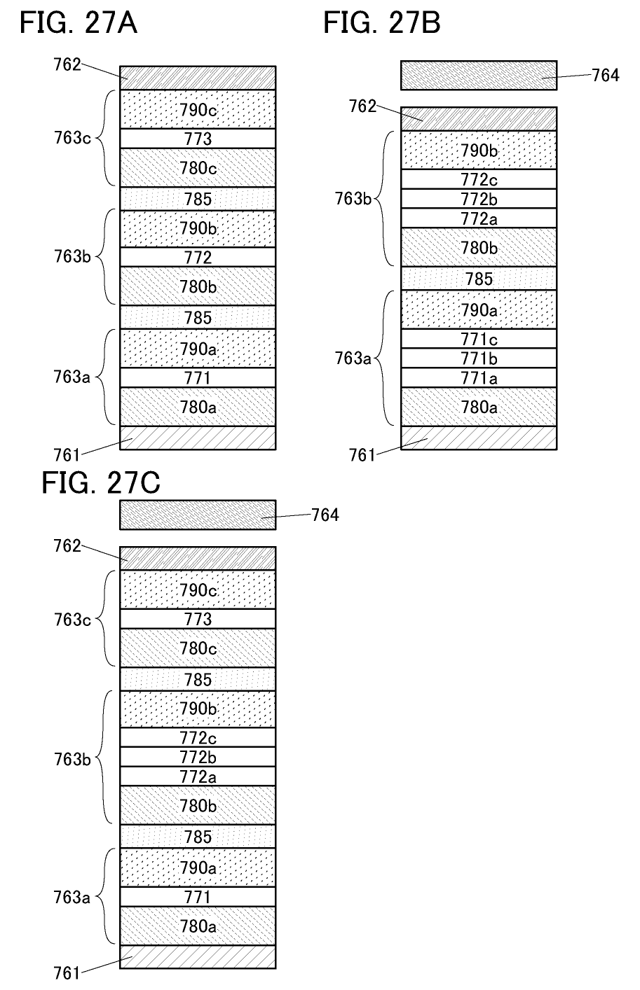

Examples of the light-emitting device with a tandem structure are structures illustrated in FIGS. 27A - 27C.

FIG. 27A illustrates a structure including three light-emitting units. In the structure illustrated in FIG. 27A, a plurality of light-emitting units (the light-emitting units 763a and 763b and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layers 780a and 780b, and the layer 790c can have a structure applicable to the layers 790a and 790b.

In FIG. 27A, the light-emitting layers 771, 772, and 773 can contain light-emitting substances that emit light of the same color. Specifically, the light-emitting layers 771, 772, and 773 can each contain a blue (B) light-emitting substance (i.e., a B/B/B three-unit tandem structure). Note that "b/a" means that a light-emitting unit containing a light-emitting substance that emits light of the color "b" is provided over a light-emitting unit containing a light-emitting substance that emits light of the color "a" with a charge-generation layer therebetween.

In FIG. 27A, light-emitting substances that emit light of different colors may be used for some or all of the light-emitting layers 771, 772, and 773. Examples of the combination of emission colors for the light-emitting layers 771, 772, and 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting device with a tandem structure may be employed in which light-emitting units each including a plurality of light-emitting layers are stacked as illustrated in FIG. 27B. FIG. 27B illustrates a structure in which two light-emitting units (the light-emitting units 763a and 763b) are connected in series through the charge-generation layer 785. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 27B, the light-emitting unit 763a is configured to emit white (W) light by selecting light-emitting substances for the light-emitting layers 771a, 771b, and 771c such that their emission colors are complementary colors. Furthermore, the light-emitting unit 763b is configured to emit white (W) light by selecting light-emitting substances for the light-emitting layers 772a, 772b, and 772c such that their emission colors can produce white color. That is, the structure illustrated in FIG. 27B is a two-unit tandem structure of W/W. Note that there is no particular limitation on the stacking order of the light-emitting substances. The practitioner can select the optimal stacking order as appropriate. Although not illustrated, a W/W/W three-unit tandem structure or a tandem structure with four or more units may be employed.

In the case of a light-emitting device with a tandem structure, any of the following structures may be employed, for example: a B/Y or Y/B two-unit tandem structure including a light-emitting unit that emits yellow (Y) light and a light-emitting unit that emits blue (B) light; a R⋅G/B or B/R⋅G two-unit tandem structure including a light-emitting unit that emits red (R) and green (G) light and a light-emitting unit that emits blue (B) light; a B/Y/B three-unit tandem structure including a light-emitting unit that emits blue (B) light, a light-emitting unit that emits yellow (Y) light, and a light-emitting unit that emits blue (B) light in this order; a B/YG/B three-unit tandem structure including a light-emitting unit that emits blue (B) light, a light-emitting unit that emits yellow-green (YG) light, and a light-emitting unit that emits blue (B) light in this order; and a B/G/B three-unit tandem structure including a light-emitting unit that emits blue (B) light, a light-emitting unit that emits green (G) light, and a light-emitting unit that emits blue (B) light in this order. Note that "a⋅b" means that one light-emitting unit contains a light-emitting substance that emits light of the color "a" and a light-emitting substance that emits light of the color "b".

As illustrated in FIG. 27C, a light-emitting unit including one light-emitting layer and a light-emitting unit including a plurality of light-emitting layers may be used in combination.

Specifically, in the structure illustrated in FIG. 27C, a plurality of light-emitting units (the light-emitting units 763a, 763b, and 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 27C can be, for example, a B/R⋅G⋅YG/B three-unit tandem structure in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film that transmits visible light is used for the electrode through which light is extracted, which is either the lower electrode 761 or the upper electrode 762. A conductive film that reflects visible light is preferably used for the electrode through which light is not extracted. In the case where the display apparatus includes a light-emitting device that emits infrared light, it is preferable that a conductive film that transmits visible light and infrared light be used for the electrode through which light is extracted, and a conductive film that reflects visible light and infrared light be used for the electrode through which light is not extracted.

A conductive film that transmits visible light may be used also for the electrode through which light is not extracted. In that case, the electrode is preferably provided between a reflective layer and the organic compound layer 763. In other words, light emitted from the organic compound layer 763 may be reflected by the reflective layer to be extracted from the display apparatus.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include an indium tin oxide (In-Sn oxide, also referred to as ITO), an In-Si-Sn oxide (also referred to as ITSO), an indium zinc oxide (In-Zn oxide), and an In-W-Zn oxide. Examples of the alloy include an alloy containing aluminum (aluminum alloy), such as an alloy of aluminum, nickel, and lanthanum (Al-Ni-La), and an alloy containing silver, such as an alloy of silver and magnesium (Ag-Mg) and an alloy of silver, palladium, and copper (Ag-Pd-Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a microcavity structure. Therefore, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40 %. For example, an electrode having a visible light (light with wavelengths greater than or equal to 400 nm and less than 750 nm) transmittance higher than or equal to 40 % is preferably used as the transparent electrode of the light-emitting device. The transflective electrode has a visible light reflectance higher than or equal to 10 % and lower than or equal to 95 %, preferably higher than or equal to 30 % and lower than or equal to 80 %. The reflective electrode has a visible light reflectance higher than or equal to 40 % and lower than or equal to 100 %, preferably higher than or equal to 70 % and lower than or equal to 100 %. These electrodes preferably have a resistivity lower than or equal to 1 × 10⁻ ² Ωcm.

The light-emitting device includes at least a light-emitting layer. In addition to the light-emitting layer, the light-emitting device may further include a layer containing any of a substance having a high hole-injection property, a substance having a high hole-transport property, a hole-blocking material, a substance having a high electron-transport property, an electron-blocking material, a substance having a high electron-injection property, a substance having a bipolar property (a substance with high electron- and hole-transport properties), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer contains one or more kinds of light-emitting substances. As the light-emitting substance, a substance whose emission color is blue, violet, bluish violet, green, yellowish green, yellow, orange, red, or the like is appropriately used. As the light-emitting substance, a substance that emits near-infrared light can also be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property which can be used for the hole-transport layer and will be described later. As the electron-transport material, it is possible to use a material with a high electron-transport property which can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (the phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

A hole-injection layer injects holes from an anode to a hole-transport layer and contains an organic acceptor material or a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, a radialene derivative, or a hexaazatriphenylene derivative can be used.

As the material with a high hole-injection property, a material that contains a hole-transport material and the above-described oxide of a metal belonging to Group 4 to Group 8 of the periodic table (typified by molybdenum oxide) may be used, for example.

The hole-transport layer transports holes, which are injected from the anode by the hole-injection layer, to the light-emitting layer. The hole-transport layer contains a hole-transport material. The hole-transport material preferably has a hole mobility higher than or equal to 1 × 10⁻ ⁶ cm²/Vs. Note that other substances can also be used as long as the substances have a hole-transport property higher than an electron-transport property. The hole-transport material is preferably a material with a high hole-transport property, such as a π-electron rich heteroaromatic compound (e.g., a carbazole derivative, a thiophene derivative, and a furan derivative) or an aromatic amine (a compound having an aromatic amine skeleton).

The electron-blocking layer is provided in contact with the light-emitting layer. The electron-blocking layer has a hole-transport property and contains a material that can block an electron. For example, the hole-transport layer functions as the electron-blocking layer when it has a lowest unoccupied molecular orbital (LUMO) level higher than the LUMO level of a material (at least a host material) contained in the light-emitting layer by greater than or equal to 0.3 eV. Furthermore, the hole-transport layer preferably has a LUMO level higher than the LUMO level of the material (at least the host material) contained in the light-emitting layer by greater than or equal to 0.5 eV, in terms of increasing the emission efficiency. Among the above-described hole-transport materials, a material with an electron-blocking property can be used for the electron-blocking layer.

Since the electron-blocking layer has a hole-transport property, the electron-blocking layer can also be referred to as a hole-transport layer. A hole-transport layer with an electron-blocking property can be referred to as an electron-blocking layer.

The electron-transport layer transports electrons, which are injected from the cathode by the electron-injection layer, to the light-emitting layer. The electron-transport layer contains an electron-transport material. The electron-transport material preferably has an electron mobility higher than or equal to 1 × 10⁻ ⁶ cm²/Vs. Note that other substances can also be used as long as the substances have an electron-transport property higher than a hole-transport property. The electron-transport material can be a material with a high electron-transport property, e.g., a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, a triazine derivative, and a π-electron deficient heteroaromatic compound such as a nitrogen-containing heteroaromatic compound.

The hole-blocking layer is provided in contact with the light-emitting layer. The hole-blocking layer has an electron-transport property and contains a material that can block a hole. In the case where the electron-transport layer in contact with the light-emitting layer functions as a hole-blocking layer, the electron-transport layer is preferably formed using a material having a lower highest occupied molecular orbital (HOMO) level than a material contained in the light-emitting layer by greater than or equal to 0.5 eV. Among the above-described electron-transport materials, a material with a hole-blocking property can be used for the hole-blocking layer.

Since the hole-blocking layer has an electron-transport property, the hole-blocking layer can also be referred to as an electron-transport layer. An electron-transport layer with a hole-blocking property can be referred to as a hole-blocking layer.

An electron-injection layer injects electrons from a cathode to an electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used. For the electron-transport material, any of the above materials of the electron-transport layer, for example, can be referred to.

The LUMO level of the material with a high electron-injection property preferably has a small difference (specifically, 0.5 eV or less) from the work function of a material for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFx, where x is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOx), or cesium carbonate, for example. The electron-injection layer may have a stacked-layer structure of two or more layers. An example of the stacked-layer structure is a structure in which lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the LUMO level of the organic compound having an unshared electron pair is preferably greater than or equal to -3.6 eV and less than or equal to -2.3 eV. In general, the HOMO level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2'-(1,3-phenylene)bis(9-phenyl-1,10-phenanthroline) (abbreviation: mPPhen2P), diquinoxalino[2,3-a:2',3'-c]phenazine (abbreviation: HATNA), 2,4,6-tris[3'-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (T _{g}) than BPhen and thus has high heat resistance.

The charge-generation layer may be either a p-type layer in which an electron acceptor (acceptor) is added to a hole-transport material or an electron-injection buffer layer in which an electron donor (donor) is added to an electron-transport material. Alternatively, both of these layers may be stacked. Furthermore, an electron-relay layer may be provided between the p-type layer and the electron-injection buffer layer. Note that forming an intermediate layer with the use of any of the above materials can inhibit an increase in driving voltage caused by the stack of the organic compound layers including light-emitting layers.

The charge-generation layer preferably includes a p-type layer. The p-type layer preferably contains an acceptor material. For example, the p-type layer preferably contains the above-described hole-transport material and acceptor material that can be used for the hole-injection layer. Other examples include oxides of metals belonging to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of a p-type layer or a stack of films including the respective materials may be used.

The charge-generation layer preferably includes a layer containing a material with a high electron-injection property. The layer can also be referred to as an electron-injection buffer layer or an n-type layer. The electron-injection buffer layer is preferably provided between the p-type layer and the electron-transport layer. With use of the electron-injection buffer layer, an injection barrier between the p-type layer and the electron-transport layer can be lowered; thus, electrons generated in the p-type layer can be easily injected into the electron-transport layer.

The electron-injection buffer layer preferably contains an alkali metal, an alkaline earth metal, a rare earth metal, a metal belonging to Group 2 or Group 13 of the periodic table, or an oxide or a carbonate thereof, and can contain a compound of an alkali metal or a compound of an alkaline earth metal, for example. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (Li₂O)). For the electron-injection buffer layer, cesium (Cs), magnesium (Mg), calcium (Ca), ytterbium (Yb), indium (In), lithium oxide (Li₂O), cesium carbonate, or the like can be suitably used. Alternatively, an organic compound such as tetrathianaphthacene may be used. Alternatively, the above-described material that can be used for the electron-injection layer can be favorably used for the electron-injection buffer layer.

The charge-generation layer preferably includes a layer containing a material with a high electron-transport property. The layer can also be referred to as an electron-relay layer. The electron-relay layer is preferably provided between the p-type layer and the electron-injection buffer layer. In the case where the charge-generation layer does not include an electron-injection buffer layer, the electron-relay layer is preferably provided between the p-type layer and the electron-transport layer. The electron-relay layer has a function of preventing an interaction between the p-type layer and the electron-injection buffer layer (or the electron-transport layer) and transferring electrons smoothly.

For the electron-relay layer, a phthalocyanine-based material such as copper(II) phthalocyanine (abbreviation: CuPc), or a metal complex having a metal-oxygen bond and an aromatic ligand is preferably used.

Note that the p-type layer, the electron-injection buffer layer, and the electron-relay layer cannot be clearly distinguished from one another on the basis of the cross-sectional shape or properties in some cases.

When the charge-generation layer is provided between two light-emitting units to be stacked, an increase in driving voltage can be inhibited.

At least part of this embodiment can be implemented as appropriate in combination with any of the other embodiments described in this specification.

### Embodiment 5

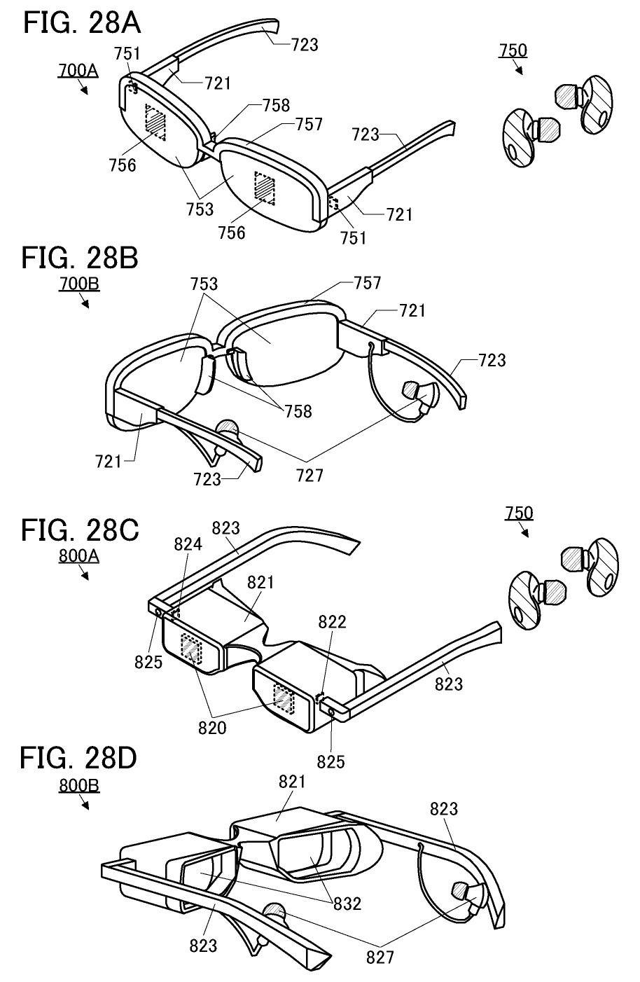

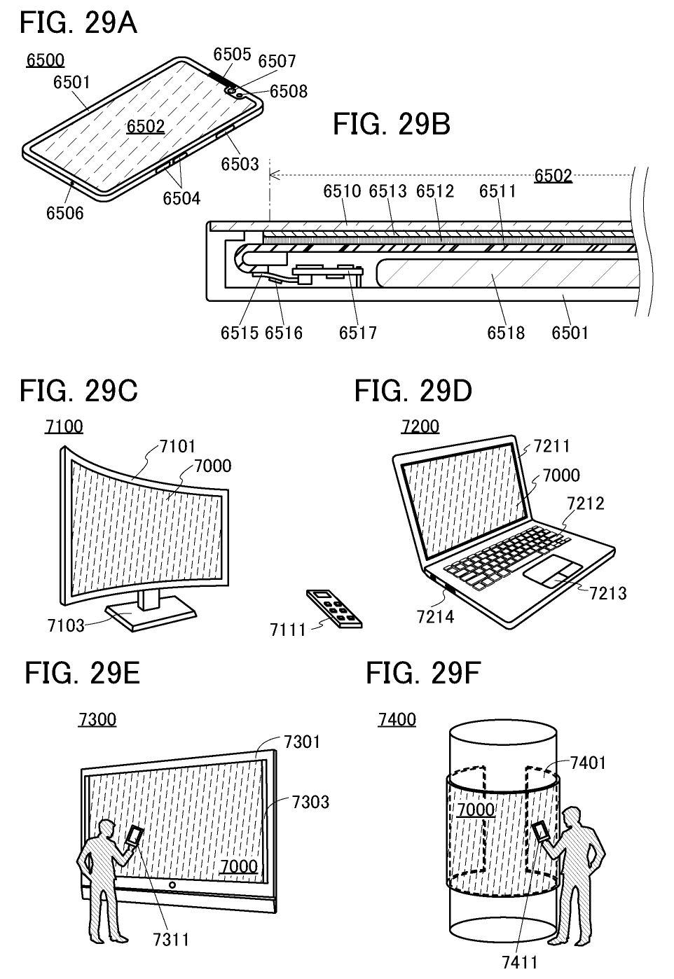

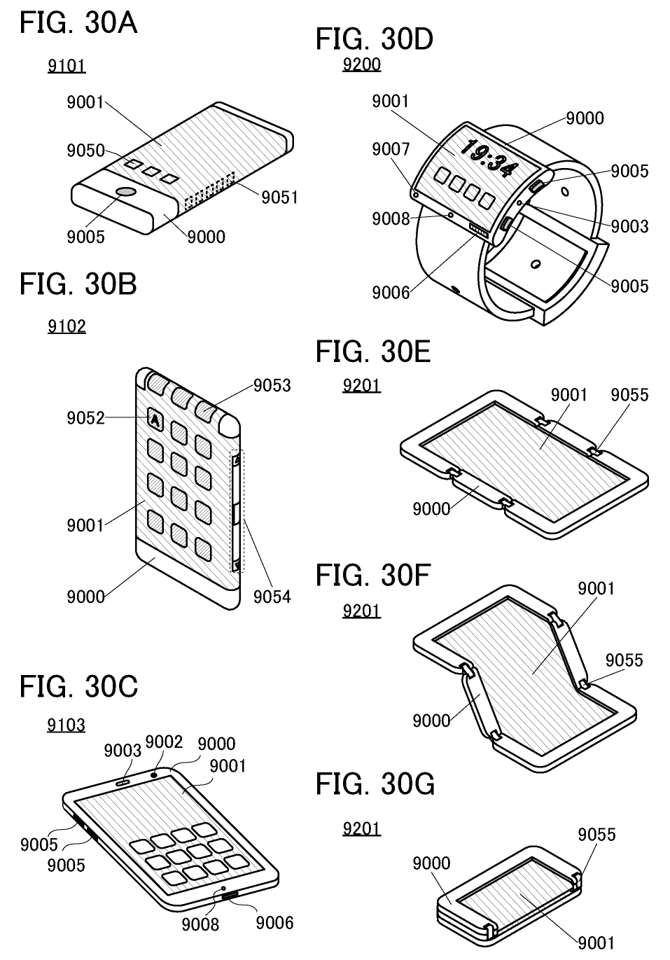

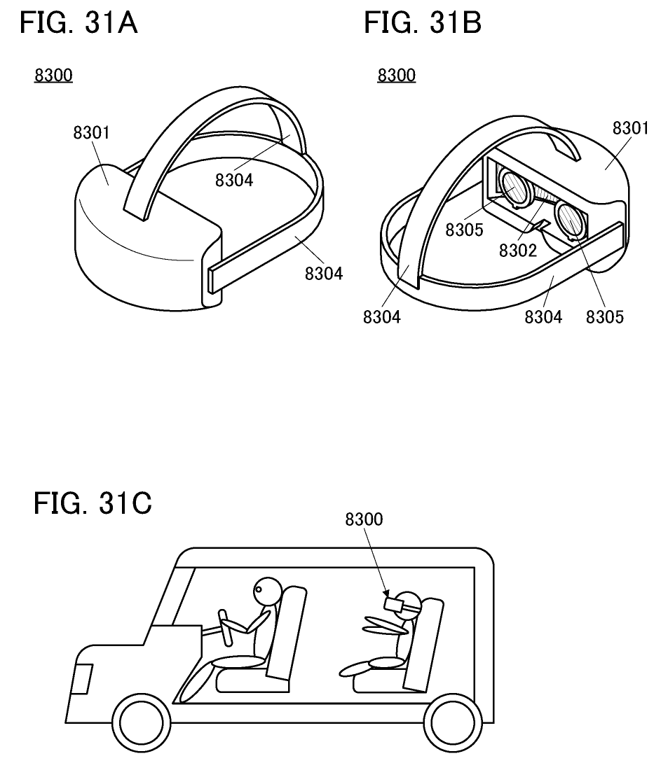

In this embodiment, electronic appliances of one embodiment of the present invention will be described with reference to FIGS. 28A - 28D, FIGS. 29A - 29F, FIGS. 30A - 30G, and FIGS. 31A - 31C.

Electronic appliances in this embodiment each include the display panel (display apparatus) of one embodiment of the present invention in a display portion. The display panel of one embodiment of the present invention can be easily increased in resolution and definition and can achieve high display quality. Thus, the display panel of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television apparatus, desktop and laptop personal computers, a monitor of a computer and the like, digital signage, and a large game machine like a pachinko machine.

In particular, the display panel of one embodiment of the present invention can have high pixel density, and thus can be favorably used for an electronic appliance having a relatively small display portion. Examples of such an electronic appliance include watch-type and bracelet-type information terminals (wearable devices) and wearable devices capable of being worn on a head, such as a VR device like a head-mounted display, a glasses-type AR device, and a mixed reality (MR) device.

The definition of the display panel of one embodiment of the present invention is preferably as high as HD (number of pixels: 1280 × 720), FHD (number of pixels: 1920 × 1080), WQHD (number of pixels: 2560 × 1440), WQXGA (number of pixels: 2560 × 1600), 4K (number of pixels: 3840 × 2160), or 8K (number of pixels: 7680 × 4320). In particular, a definition of 4K, 8K, or higher is preferable. The pixel density (also referred to as resolution) of the display panel of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display panel having one or both of such high definition and high pixel density can further increase realistic sensation, sense of depth, and the like. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic appliance in this embodiment may include a sensor (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays).

The electronic appliance in this embodiment can have a variety of functions. For example, the electronic appliance can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices capable of being worn on a head are described with reference to FIGS. 28A - 28D. The wearable devices have one or both of a function of displaying AR content and a function of displaying VR content. Note that these wearable devices may have a function of displaying substitutional reality (SR) or MR content, in addition to AR and VR content. The electronic appliance having a function of displaying content of at least one of AR, VR, SR, MR, and the like enables the user to feel a higher level of immersion.

An electronic appliance 700A illustrated in FIG. 28A and an electronic appliance 700B illustrated in FIG. 28B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be used for the display panels 751. Thus, the electronic appliances are capable of performing display with ultrahigh pixel density.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are capable of AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic appliances 700A and 700B are each provided with a battery, which can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic appliance 800A illustrated in FIG. 28C and an electronic appliance 800B illustrated in FIG. 28D each include a pair of display portions 820, a housing 821, a communication portion 822, a pair of wearing portions 823, a control portion 824, a pair of image capturing portions 825, and a pair of lenses 832.

The display panel of one embodiment of the present invention can be used in the display portions 820. Thus, the electronic appliances are capable of performing display with ultrahigh pixel density. Such electronic appliances provide a high sense of immersion to the user.

The display portions 820 are positioned inside the housing 821 so as to be seen through the lenses 832. When the pair of display portions 820 display different images, three-dimensional display using parallax can be performed.

The electronic appliances 800A and 800B can be regarded as electronic appliances for VR. The user who wears the electronic appliance 800A or the electronic appliance 800B can see images displayed on the display portions 820 through the lenses 832.

The electronic appliances 800A and 800B each preferably include a mechanism for adjusting the lateral positions of the lenses 832 and the display portions 820 so that the lenses 832 and the display portions 820 are positioned optimally in accordance with the positions of the user's eyes. Moreover, the electronic appliances 800A and 800B each preferably include a mechanism for adjusting focus by changing the distance between the lenses 832 and the display portions 820.

The electronic appliance 800A or the electronic appliance 800B can be mounted on the user's head with the wearing portions 823. FIG. 28C and the like illustrate examples where the wearing portion 823 has a shape like a temple of glasses; however, one embodiment of the present invention is not limited thereto. The wearing portion 823 can have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is shown here, a range sensor (hereinafter also referred to as a sensing portion) capable of measuring a distance to an object may be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic appliance 800A.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A in FIG. 28A has a function of transmitting information to the earphones 750 with the wireless communication function. As another example, the electronic appliance 800A in FIG. 28C has a function of transmitting information to the earphones 750 with the wireless communication function.

The electronic appliance may include an earphone portion. The electronic appliance 700B illustrated in FIG. 28B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic appliance 800B illustrated in FIG. 28D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

An electronic appliance 6500 illustrated in FIG. 29A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display panel of one embodiment of the present invention can be used in the display portion 6502.

FIG. 29B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used as the display panel 6511. Thus, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be obtained.

FIG. 29C illustrates an example of a television apparatus. In a television apparatus 7100, a display portion 7000 is incorporated in a housing 7101. Here, the housing 7101 is supported by a stand 7103.

Operation of the television apparatus 7100 illustrated in FIG. 29C can be performed with an operation switch provided in the housing 7101 and a separate remote control 7111. Alternatively, the display portion 7000 may include a touch sensor, and the television apparatus 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television apparatus 7100 includes a receiver, a modem, and the like. A general television broadcast can be received with the receiver. When the television apparatus is connected to a communication network by wire or wirelessly via the modem, one-way (from a transmitter to a receiver) or two-way (between a transmitter and a receiver or between receivers, for example) information communication can be performed.

FIG. 29D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

FIGS. 29E and 29F illustrate examples of digital signage.

Digital signage 7300 illustrated in FIG. 29E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 29F illustrates digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 29E and 29F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The display panel of one embodiment of the present invention can be used in the display portion 7000 illustrated in each of FIGS. 29C to 29F.

Electronic appliances illustrated in FIGS. 30A - 30G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 30A - 30G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium. Note that the functions of the electronic appliances are not limited thereto, and the electronic appliances can have a variety of functions. The electronic appliances may include a plurality of display portions. The electronic appliances may be provided with a camera or the like and have a function of capturing a still image or a moving image and storing the captured image in a storage medium (an external storage medium or a storage medium incorporated in the camera), a function of displaying the captured image on the display portion, and the like.

The electronic appliances illustrated in FIGS. 30A - 30G are described in detail below.

FIG. 30A is a perspective view of a portable information terminal 9101. The portable information terminal 9101 can be used as a smartphone, for example. The portable information terminal 9101 may include the speaker 9003, the connection terminal 9006, the sensor 9007, and the like. The portable information terminal 9101 can display text and image information on its plurality of surfaces. FIG. 30A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 30B is a perspective view of a portable information terminal 9102. The portable information terminal 9102 has a function of displaying information on three or more surfaces of the display portion 9001. In the example illustrated here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 30C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 30D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 30E - 30G are perspective views of a foldable portable information terminal 9201. FIG. 30E is a perspective view illustrating the portable information terminal 9201 that is opened. FIG. 30G is a perspective view illustrating the portable information terminal 9201 that is folded. FIG. 30F is a perspective view illustrating the portable information terminal 9201 that is shifted from one of the states in FIGS. 30E and 30G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

FIGS. 31A and 31B are external views of a head-mounted display 8300. The head-mounted display 8300 includes a housing 8301, a display portion 8302, a band-like fixing member 8304, and a pair of lenses 8305.

A user can see display on the display portion 8302 through the lenses 8305. The display portion 8302 is preferably curved because the user can feel a high realistic sensation. When another image displayed in another region of the display portion 8302 is viewed through the lenses 8305, three-dimensional display using parallax or the like can be performed. Note that the number of the display portions 8302 is not limited to one; two display portions 8302 may be provided for user's respective eyes.

The display apparatus of one embodiment of the present invention can be used for the display portion 8302. The display apparatus of one embodiment of the present invention can have an extremely high pixel density. Thus, a pixel is not easily seen by the user even when the user sees display that is magnified by the use of the lenses 8305. In other words, an image with a strong sense of reality can be seen by the user with use of the display portion 8302.

The head-mounted display 8300 preferably has a head tracking function and an eye tracking function. Accordingly, an image displayed can be moved in accordance with the movement of the user and the line of sight of the user. Thus, a highly immersive image can be provided to the user. For example, as illustrated in FIG. 31C, a passenger in the rear seat of a car can wear the head-mounted display 8300. In that case, moving an image in synchronization with the shaking of the car body and not fixing the line of sight, for example, can reduce car sickness as compared with the case where the passenger sees an image with a smartphone, a tablet terminal, or the like.

At least part of this embodiment can be implemented as appropriate in combination with any of the other embodiments described in this specification.

This application is based on Japanese Patent Application Serial No. 2025-078996 filed with Japan Patent Office on May 9, 2025 and Japanese Patent Application Serial No. 2025-133780 filed with Japan Patent Office on August 8, 2025, the entire contents of which are hereby incorporated by reference.

What is claimed is:

1. A display apparatus comprising:
a first light-emitting device, a second light-emitting device, a partition, and a first insulating layer over an insulating surface,
the first light-emitting device comprising:
a first pixel electrode in contact with the insulating surface;
a first organic compound layer over the first pixel electrode; and
a first upper electrode over the first organic compound layer,
the second light-emitting device comprising:
a second pixel electrode in contact with the insulating surface;
a second organic compound layer over the second pixel electrode; and
a second upper electrode over the second organic compound layer,
wherein the first insulating layer is between the first pixel electrode and the second pixel electrode and covers an end portion of each of the first pixel electrode and the second pixel electrode,
wherein the partition is over the first insulating layer,
wherein a width of an upper portion of the partition is larger than a width of a lower portion of the partition in a cross-sectional view, and
wherein a material of the first organic compound layer and a material of the second organic compound layer are present at side surfaces of the partition.

2. A display apparatus comprising:
a first light-emitting device, a second light-emitting device, a partition, and a first insulating layer over an insulating surface,
the first light-emitting device comprising:
a first pixel electrode in contact with the insulating surface;
a first organic compound layer over the first pixel electrode; and
a first upper electrode over the first organic compound layer,
the second light-emitting device comprising:
a second pixel electrode in contact with the insulating surface;
a second organic compound layer over the second pixel electrode; and
a second upper electrode over the second organic compound layer,
wherein the first insulating layer is between the first pixel electrode and the second pixel electrode and covers an end portion of each of the first pixel electrode and the second pixel electrode,
wherein the partition is over the first insulating layer, and
wherein a material of the first organic compound layer and a material of the second organic compound layer are present at side surfaces of the partition.

3. The display apparatus according to claim 1,
wherein the first upper electrode is electrically connected to the partition.

4. The display apparatus according to claim 1,
wherein the first upper electrode and the second upper electrode have a light-transmitting property.

5. The display apparatus according to claim 1,
wherein the first organic compound layer comprises a first layer comprising a substance having an electron-accepting property over the first pixel electrode and a second layer comprising a light-emitting substance over the first layer,
wherein the second organic compound layer comprises a third layer comprising a substance having an electron-accepting property over the second pixel electrode and a fourth layer comprising a light-emitting substance over the third layer,
wherein the second layer covers an end portion of the first layer,
wherein the first upper electrode covers the second layer,
wherein the fourth layer covers an end portion of the third layer, and
wherein the second upper electrode covers the fourth layer.

6. The display apparatus according to claim 1,
wherein the partition comprises molybdenum.

7. The display apparatus according to claim 2,
the partition further comprising:
a first conductive layer over and in contact with the first insulating layer;
a second insulating layer over and in contact with the first conductive layer; and
a third insulating layer over and in contact with the second insulating layer,
wherein a width of the third insulating layer is larger than a width of the second insulating layer in a cross-sectional view.

8. The display apparatus according to claim 2,
the partition further comprising:
a fourth insulating layer over and in contact with the first insulating layer; and
a second conductive layer over and in contact with the fourth insulating layer,
wherein a width of a top surface of the second conductive layer is larger than a width of the fourth insulating layer at an interface between the fourth insulating layer and the second conductive layer in a cross-sectional view.

9. The display apparatus according to claim 2,
wherein the partition further comprises a third conductive layer in contact with the first insulating layer, and
wherein a width of a bottom surface of the third conductive layer is smaller than a width of a top surface of the third conductive layer in a cross-sectional view.

10. The display apparatus according to claim 2,
wherein the first upper electrode is electrically connected to the partition.

11. The display apparatus according to claim 2,
wherein the first upper electrode and the second upper electrode have a light-transmitting property.

12. The display apparatus according to claim 2,
wherein the first organic compound layer comprises a first layer comprising a substance having an electron-accepting property over the first pixel electrode and a second layer comprising a light-emitting substance over the first layer,
wherein the second organic compound layer comprises a third layer comprising a substance having an electron-accepting property over the second pixel electrode and a fourth layer comprising a light-emitting substance over the third layer,
wherein the second layer covers an end portion of the first layer,
wherein the first upper electrode covers the second layer,
wherein the fourth layer covers an end portion of the third layer, and
wherein the second upper electrode covers the fourth layer.

13. The display apparatus according to claim 2,
wherein the partition comprises molybdenum.

14. The display apparatus according to claim 5,
wherein the first layer and the third layer comprise any of an oxide of a metal belonging to Group 4 to Group 8 of a periodic table, a quinodimethane derivative, a chloranil derivative, and a hexaazatriphenylene derivative, and
wherein the light-emitting substance of the second layer is different from the light-emitting substance of the fourth layer.

15. The display apparatus according to claim 7,
wherein the first conductive layer comprises molybdenum,
wherein the second insulating layer comprises silicon and one or more selected from oxygen and nitrogen,
wherein the third insulating layer comprises silicon and one or more selected from oxygen and nitrogen, and
wherein a composition of the second insulating layer is different from a composition of the third insulating layer.

16. The display apparatus according to claim 8,
wherein the first organic compound layer comprises a first layer comprising a substance having an electron-accepting property over the first pixel electrode and a second layer comprising a light-emitting substance over the first layer,
wherein the second organic compound layer comprises a third layer comprising a substance having an electron-accepting property over the second pixel electrode and a fourth layer comprising a light-emitting substance over the third layer,
wherein the second layer covers an end portion of the first layer and is in contact with a side surface of the fourth insulating layer, and
wherein the fourth layer covers an end portion of the third layer and is in contact with a side surface of the fourth insulating layer.

17. The display apparatus according to claim 12,
wherein the first layer and the third layer comprise any of an oxide of a metal belonging to Group 4 to Group 8 of a periodic table, a quinodimethane derivative, a chloranil derivative, and a hexaazatriphenylene derivative, and
wherein the light-emitting substance of the second layer is different from the light-emitting substance of the fourth layer.
